(19) United States
(12) Patent Application Publication
(10) Pub. No.: US 2023/0282661 A1
(43) Pub. Date: Sep. 7, 2023

(54) PACKAGE AND MANUFACTURING METHOD THEREOF

(71) Applicant: SONY SEMICONDUCTOR SOLUTIONS CORPORATION, KANAGAWA (JP)

(72) Inventors: YOSUKE NITTA, KANAGAWA (JP); NOBUTOSHI FUJII, KANAGAWA (JP); SUGURU SAITO, KANAGAWA (JP); YOICHI OOTSUKA, KANAGAWA (JP)

(21) Appl. No.: 18/040,112

(22) PCT Filed: Aug. 13, 2021
(86) PCT No.: PCT/JP2021/029800

§ 371 Date: Jan. 31, 2023

(30) Foreign Application Priority Data
Aug. 27, 2020 (JP) 2020-143938

(51) Int. Cl. H01L 27/146

(52) U.S. Cl. CPC H01L 27/14623; H01L 27/14685; H01L 27/14627; H01L 27/14636; H01L 27/14618; H01L 27/14632; H01L 27/14687

(57) ABSTRACT

A contact of a glass substrate with an on-chip lens is suppressed while suppressing occurrence of flare. A package includes a flattening film covering an on-chip lens formed on a light incidence side of a substrate having an element formed thereon, a transparent substrate formed on the light incidence side of the flattening film, a hollow portion formed in a region overlapping the on-chip lens when seen in a plan view with respect to at least one of between the flattening film and the transparent substrate and inside the transparent substrate, and a through-hole making the hollow portion communicate with the outside.

### TECHNICAL FIELD

The present disclosure relates to a solid-state imaging element, other packages, and manufacturing methods thereof.

### BACKGROUND ART

For example, as disclosed in PTL 1, a solid-state imaging element has an element substrate provided with an on-chip lens on a light incidence surface of a pixel on which photoelectric conversion is performed, and a transparent substrate is attached to the element substrate to seal the on-chip lens. Further, in the related art, there is known a chip size package which is provided with a rewiring layer on the rear surface of a device (on the rear surface side of an element substrate) in order to miniaturize a solid-state imaging element.

In the solid-state imaging element disclosed in PTL 1, a hollow portion is provided between the on-chip lens and the transparent substrate. Further, the hollow portion communicates with the outside of the element by means of a through-hole penetrating the transparent substrate in the thickness direction.

In addition, PTL 1 discloses a structure in which flare is reduced, and moisture is less likely to be trapped inside the hollow portion by including the hollow portion and the through-hole.

Further, PTL 1 describes that, when the solid-state imaging element is manufactured, a rewiring is formed on the rear surface side of the element substrate after the hollow portion is formed between the element substrate and the transparent substrate.

### CITATION LIST

### Patent Literature

### PTL 1

JP 2006-108285A

### SUMMARY

### Technical Problem

From the viewpoint of miniaturizing a solid-state imaging element, it is preferable to reduce the thickness of an element substrate and a glass substrate.

However, in a case where a hollow portion is formed between the element substrate and the glass substrate as disclosed in PTL 1, the glass substrate and the like are more likely to be bent as the glass substrate and the like become thinner.

For this reason, when rewiring formation processing is performed on the element substrate after the hollow portion is formed, there is a possibility that the glass substrate will come into contact with an on-chip lens. In addition, this contact is more likely to occur as the thickness of the hollow portion decreases.

The present disclosure has been made focusing on such points, and an object thereof is to suppress contact of the glass substrate with the on-chip lens while suppressing the occurrence of flares.

### Solution to Problem

A package according to an embodiment of the present disclosure includes a flattening film covering an on-chip lens formed on a light incidence side of a substrate having an element formed thereon, a transparent substrate formed on the light incidence side of the flattening film, a hollow portion formed in a region overlapping the on-chip lens when seen in a plan view with respect to at least one of between the flattening film and the transparent substrate and inside the transparent substrate, and a through-hole making the hollow portion communicate with the outside.

Further, a package manufacturing method according to an embodiment of the present disclosure includes forming a flattening film covering an on-chip lens formed on a light incidence side of a substrate having an element formed thereon, laminating a transparent substrate on the light incidence side of the flattening film via a sacrificial layer and an adhesive layer disposed on an outer circumference of the sacrificial layer, forming a through-hole making the sacrificial layer communicate with the outside, and etching the sacrificial layer through the through-hole to form a hollow portion after the transparent substrate is laminated.

### BRIEF DESCRIPTION OF DRAWINGS

FIG. 1A is a cross-sectional view illustrating a solid-state imaging element according to a first mode.

FIG. 1B is a schematic diagram illustrating a region on an upper surface of a substrate on which an element is formed, and positions of through-holes.

FIG. 2A is a cross-sectional view illustrating another solid-state imaging element according to the first mode.

FIG. 2B is a diagram illustrating a sealing member in the other solid-state imaging element according to the first mode.

FIG. 3 is a cross-sectional view illustrating a solid-state imaging element according to a second mode.

FIG. 4 is a cross-sectional view illustrating a solid-state imaging element according to a third mode.

FIG. 5 is a cross-sectional view illustrating a solid-state imaging element according to a fourth mode.

FIG. 6 is a cross-sectional view illustrating a solid-state imaging element according to a fifth mode.

FIG. 7 is a cross-sectional view illustrating a solid-state imaging element according to a sixth mode.

FIG. 8 is a cross-sectional view illustrating a solid-state imaging element according to a seventh mode.

FIG. 9 is a cross-sectional view illustrating a solid-state imaging element according to an eighth mode.

FIG. 10 is a cross-sectional view illustrating a solid-state imaging element according to a ninth mode.

FIG. 11 is a bottom view illustrating a concave portion and a support portion according to a tenth mode.

FIG. 12A is a cross-sectional view along line a-a in FIG. 11 and illustrating a solid-state imaging element according to the tenth mode.

FIG. 12B is a cross-sectional view along line b-b in FIG. 11 and illustrating the solid-state imaging element according to the tenth mode.

FIG. 13 is a bottom view illustrating a concave portion and a support portion in another example according to the tenth mode.

FIG. 14 is a bottom view illustrating a concave portion and a support portion according to an eleventh mode.

FIG. 15A is a cross-sectional view along line a-a in FIG. 11 and illustrating a solid-state imaging element according to the eleventh mode.

FIG. 15B is a cross-sectional view along line b-b in FIG. 11 and illustrating the solid-state imaging element according to the eleventh mode.

FIG. 16 is a bottom view illustrating a concave portion and a support portion in another example according to the eleventh mode.

FIG. 17 is a cross-sectional view illustrating a solid-state imaging element according to a twelfth mode.

FIG. 18A is a bottom view illustrating formation positions of through-holes according to the twelfth mode.

FIG. 18B is a bottom view illustrating another example of formation positions of through-holes according to the twelfth mode.

FIG. 18C is a bottom view illustrating another example of formation positions of through-holes according to the twelfth mode;

FIG. 19 is a bottom view illustrating a concave portion and a support portion according to a thirteenth mode.

FIG. 20A is a cross-sectional view along line a-a in FIG. 19 and illustrating a solid-state imaging element according to the thirteenth mode.

FIG. 20B is a cross-sectional view along line b-b in FIG. 19 and illustrating the solid-state imaging element according to the thirteenth mode.

FIG. 21 is a bottom view illustrating a concave portion and a support portion in another example according to the thirteenth mode.

FIG. 22 is a bottom view illustrating a concave portion and a support portion according to a fourteenth mode.

FIG. 23A is a cross-sectional view along line a-a in FIG. 22 and illustrating a solid-state imaging element according to the fourteenth mode.

FIG. 23B is a cross-sectional view along line b-b in FIG. 22 and illustrating the solid-state imaging element according to the fourteenth mode.

FIG. 24 is a cross-sectional view illustrating a solid-state imaging element according to a fifteenth mode.

FIG. 25A is a plan view illustrating an example of formation positions of through-holes.

FIG. 25B is a plan view illustrating an example of formation positions of through-holes.

FIG. 25C is a plan view illustrating an example of formation positions of through-holes.

FIG. 25D is a plan view illustrating an example of formation positions of through-holes.

FIG. 25E is a plan view illustrating an example of formation positions of through-holes.

FIG. 25F is a plan view illustrating an example of formation positions of through-holes.

FIG. 25G is a plan view illustrating an example of formation positions of through-holes.

FIG. 25H is a plan view illustrating an example of formation positions of through-holes.

FIG. 25I is a plan view illustrating an example of formation positions of through-holes.

FIG. 25J is a plan view illustrating an example of formation positions of through-holes.

FIG. 25K is a plan view illustrating an example of formation positions of through-holes.

FIG. 25L is a plan view illustrating an example of formation positions of through-holes.

FIG. 26A is a plan view illustrating an example of formation positions of through-holes.

FIG. 26B is a plan view illustrating an example of formation positions of through-holes.

FIG. 26C is a plan view illustrating an example of formation positions of through-holes.

FIG. 26D is a plan view illustrating an example of formation positions of through-holes.

FIG. 26E is a plan view illustrating an example of formation positions of through-holes.

FIG. 26F is a plan view illustrating an example of formation positions of through-holes.

FIG. 26G is a plan view illustrating an example of formation positions of through-holes.

FIG. 26H is a plan view illustrating an example of formation positions of through-holes.

FIG. 27A is a plan view illustrating an example of a cross-sectional shape of a through-hole.

FIG. 27B is a plan view illustrating an example of a cross-sectional shape of a through-hole.

FIG. 27C is a plan view illustrating an example of a cross-sectional shape of a through-hole.

FIG. 27D is a plan view illustrating an example of a cross-sectional shape of a through-hole.

FIG. 27E is a plan view illustrating an example of a cross-sectional shape of a through-hole.

FIG. 27F is a plan view illustrating an example of a cross-sectional shape of a through-hole.

FIG. 28A is a plan view illustrating an example of formation positions of through-holes.

FIG. 28B is a plan view illustrating an example of formation positions of through-holes.

FIG. 28C is a plan view illustrating an example of formation positions of through-holes.

FIG. 28D is a plan view illustrating an example of formation positions of through-holes.

FIG. 29A is a plan view illustrating an example of a cross-sectional shape of a through-hole.

FIG. 29B is a plan view illustrating an example of a cross-sectional shape of a through-hole.

FIG. 29C is a plan view illustrating an example of a cross-sectional shape of a through-hole.

FIG. 29D is a plan view illustrating an example of a cross-sectional shape of a through-hole.

FIG. 29E is a plan view illustrating an example of a cross-sectional shape of a through-hole.

FIG. 30A is a cross-sectional view illustrating an example of closing by a sealing member.

FIG. 30B is a cross-sectional view illustrating an example of closing by a sealing member.

FIG. 30C is a cross-sectional view illustrating an example of closing by a sealing member.

FIG. 31A is a diagram illustrating formation of a transparent substrate in a first example.

FIG. 31B is a diagram illustrating formation of the transparent substrate in the first example.

FIG. 31C is a diagram illustrating formation of the transparent substrate in the first example.

FIG. 32A is a diagram illustrating a first manufacturing method.

FIG. 32B is a diagram illustrating the first manufacturing method.

FIG. 32C is a diagram illustrating the first manufacturing method.

FIG. 32D is a diagram illustrating the first manufacturing method.

FIG. 33A is a diagram illustrating formation of a transparent substrate in a second example.

FIG. 33B is a diagram illustrating formation of the transparent substrate in the second example.

FIG. 34A is a diagram illustrating a second manufacturing method.

FIG. 34B is a diagram illustrating the second manufacturing method.

FIG. 34C is a diagram illustrating the second manufacturing method.

FIG. 35A is a diagram illustrating formation of a transparent substrate in a third example.

FIG. 35B is a diagram illustrating formation of the transparent substrate in the third example.

FIG. 36A is a diagram illustrating a third manufacturing method.

FIG. 36B is a diagram illustrating the third manufacturing method.

FIG. 36C is a diagram illustrating the third manufacturing method.

FIG. 37A is a diagram illustrating formation of a transparent substrate in a fourth example.

FIG. 37B is a diagram illustrating formation of the transparent substrate in the fourth example.

FIG. 38A is a diagram illustrating a fourth manufacturing method.

FIG. 38B is a diagram illustrating the fourth manufacturing method.

FIG. 38C is a diagram illustrating the fourth manufacturing method.

FIG. 39 is a diagram illustrating formation of a transparent substrate in a fifth example.

FIG. 40A is a diagram illustrating a fifth manufacturing method.

FIG. 40B is a diagram illustrating the fifth manufacturing method.

FIG. 40C is a diagram illustrating the fifth manufacturing method.

FIG. 40D is a diagram illustrating the fifth manufacturing method.

FIG. 40E is a diagram illustrating the fifth manufacturing method.

FIG. 41A is a diagram illustrating a sixth manufacturing method.

FIG. 41B is a diagram illustrating the sixth manufacturing method.

FIG. 41C is a diagram illustrating the sixth manufacturing method.

FIG. 41D is a diagram illustrating the sixth manufacturing method.

FIG. 41E is a diagram illustrating the sixth manufacturing method.

FIG. 42A is a diagram illustrating a seventh manufacturing method.

FIG. 42B is a diagram illustrating the seventh manufacturing method.

FIG. 42C is a diagram illustrating the seventh manufacturing method.

FIG. 42D is a diagram illustrating the seventh manufacturing method.

FIG. 42E is a diagram illustrating the seventh manufacturing method.

FIG. 42F is a diagram illustrating the seventh manufacturing method.

FIG. 43A is a diagram illustrating an eighth manufacturing method.

FIG. 43B is a diagram illustrating the eighth manufacturing method.

FIG. 43C is a diagram illustrating the eighth manufacturing method.

FIG. 43D is a diagram illustrating the eighth manufacturing method.

FIG. 43E is a diagram illustrating the eighth manufacturing method.

FIG. 44A is a diagram illustrating formation of a transparent substrate in a sixth example.

FIG. 44B is a diagram illustrating formation of the transparent substrate in the sixth example.

FIG. 44C is a diagram illustrating formation of the transparent substrate in the sixth example.

FIG. 45A is a diagram illustrating a ninth manufacturing method.

FIG. 45B is a diagram illustrating the ninth manufacturing method.

FIG. 45C is a diagram illustrating the ninth manufacturing method.

FIG. 45D is a diagram illustrating the ninth manufacturing method.

FIG. 46A is a diagram illustrating formation of a transparent substrate in a seventh example.

FIG. 46B is a diagram illustrating formation of the transparent substrate in the seventh example.

FIG. 46C is a diagram illustrating formation of the transparent substrate in the seventh example.

FIG. 47A is a diagram illustrating a tenth manufacturing method.

FIG. 47B is a diagram illustrating the tenth manufacturing method.

FIG. 47C is a diagram illustrating the tenth manufacturing method.

FIG. 48A is a diagram illustrating an eleventh manufacturing method.

FIG. 48B is a diagram illustrating the eleventh manufacturing method.

FIG. 48C is a diagram illustrating the eleventh manufacturing method.

FIG. 48D is a diagram illustrating the eleventh manufacturing method.

FIG. 49A is a diagram illustrating a twelfth manufacturing method.

FIG. 49B is a diagram illustrating the twelfth manufacturing method.

FIG. 49C is a diagram illustrating the twelfth manufacturing method.

FIG. 49D is a diagram illustrating the twelfth manufacturing method.

FIG. 50A is a diagram illustrating a thirteenth manufacturing method.

FIG. 50B is a diagram illustrating the thirteenth manufacturing method.

FIG. 50C is a diagram illustrating the thirteenth manufacturing method.

FIG. 50D is a diagram illustrating the thirteenth manufacturing method.

FIG. 50E is a diagram illustrating the thirteenth manufacturing method.

FIG. 50F is a diagram illustrating the thirteenth manufacturing method.

FIG. 50G is a diagram illustrating the thirteenth manufacturing method.

FIG. 50H is a diagram illustrating the thirteenth manufacturing method.

FIG. 50I is a diagram illustrating the thirteenth manufacturing method.

FIG. 50J is a diagram illustrating the thirteenth manufacturing method.

FIG. 50K is a diagram illustrating the thirteenth manufacturing method.

FIG. 50L is a diagram illustrating the thirteenth manufacturing method.

FIG. 50M is a diagram illustrating the thirteenth manufacturing method.

FIG. 51A is a diagram illustrating a fourteenth manufacturing method.

FIG. 51B is a diagram illustrating the fourteenth manufacturing method.

FIG. 51C is a diagram illustrating the fourteenth manufacturing method.

FIG. 51D is a diagram illustrating the fourteenth manufacturing method.

FIG. 51E is a diagram illustrating the fourteenth manufacturing method.

FIG. 51F is a diagram illustrating the fourteenth manufacturing method.

FIG. 51G is a diagram illustrating the fourteenth manufacturing method.

FIG. 52A is a diagram illustrating a fifteenth manufacturing method.

FIG. 52B is a diagram illustrating the fifteenth manufacturing method.

FIG. 52C is a diagram illustrating the fifteenth manufacturing method.

FIG. 52D is a diagram illustrating the fifteenth manufacturing method.

FIG. 52E is a diagram illustrating the fifteenth manufacturing method.

FIG. 52F is a diagram illustrating the fifteenth manufacturing method.

FIG. 53A is a diagram illustrating a sixteenth manufacturing method.

FIG. 53B is a diagram illustrating the sixteenth manufacturing method.

FIG. 53C is a diagram illustrating the sixteenth manufacturing method.

FIG. 53D is a diagram illustrating the sixteenth manufacturing method.

FIG. 54A is a diagram illustrating a seventeenth manufacturing method.

FIG. 54B is a diagram illustrating the seventeenth manufacturing method.

FIG. 54C is a diagram illustrating the seventeenth manufacturing method.

FIG. 54D is a diagram illustrating the seventeenth manufacturing method.

FIG. 55A is a diagram illustrating an eighteenth manufacturing method.

FIG. 55B is a diagram illustrating the eighteenth manufacturing method.

FIG. 55C is a diagram illustrating the eighteenth manufacturing method.

FIG. 56A is a diagram illustrating a nineteenth manufacturing method.

FIG. 56B is a diagram illustrating the nineteenth manufacturing method.

FIG. 56C is a diagram illustrating the nineteenth manufacturing method.

FIG. 57A is a diagram illustrating a twentieth manufacturing method.

FIG. 57B is a diagram illustrating the twentieth manufacturing method.

### DESCRIPTION OF EMBODIMENTS

Next, an embodiment of the present disclosure will be described with reference to the accompanying drawings.

Here, the drawings are schematic and relationships between thicknesses and plan view dimensions of components, ratios of components, and the like differ from those in reality. In addition, the following embodiment exemplifies configurations for embodying the technical ideas of the present disclosure, and the technical ideas of the present disclosure are not meant to specify that shapes, structures, and the like of component parts are those described below. The technical ideas of the present disclosure can be variously modified within the technical scope described in the claims.

In addition, the same components are denoted by the same reference numerals and signs.

In the following description, a solid-state imaging element is taken as an example of a package.

[Configuration]

(First Mode)

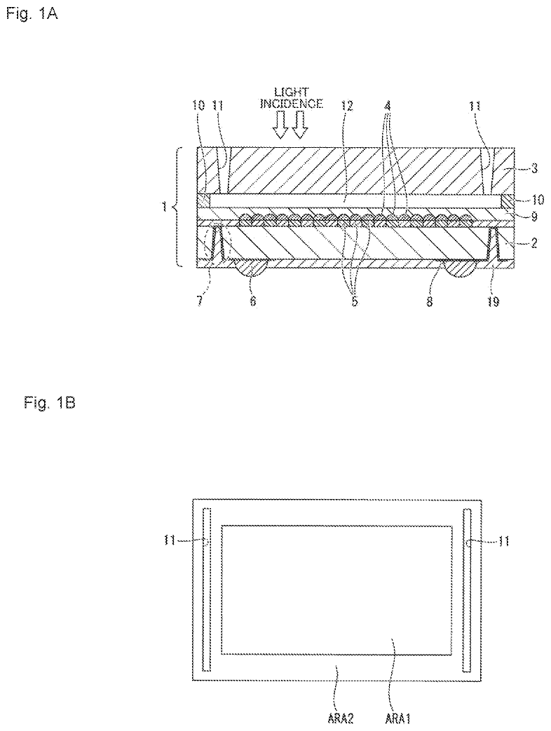

A solid-state imaging element according to a first mode includes a substrate 2 having the element formed thereon and a transparent substrate 3, as illustrated in FIG. 1A.

<Substrate 2 on which Element is Formed>

In the substrate 2 having the element formed thereon, an effective pixel region ARA1 is set on one surface (an upper surface in FIG. 1A, hereinafter simply referred to as an upper surface) as illustrated in FIG. 1B which is a conceptual diagram. Note that, in the present specification, a region on the outer circumference of the effective pixel region ARA1 is referred to as an outer circumferential region ARA2.

In the substrate 2 having the element formed thereon, a plurality of on-chip lenses 4 are disposed in a two-dimensional array corresponding to photoelectric conversion elements, not illustrated in the drawing, which are disposed in a two-dimensional array in the effective pixel region ARA1. Color filters 5 are disposed below the on-chip lenses 4.

Further, RDL/solder balls 6 and other wirings are formed on the rear surface side of the substrate 2 having the element formed thereon. The solder balls 6 and through electrodes 7 are illustrated in FIG. 1A. In FIG. 1A, reference numeral 8 denotes a rewiring layer, and reference numeral 19 denotes a solder mask. The wirings on the rear surface side are not limited to this structure, and other known wiring structures can be adopted.

### <Flattening Film 9>

A flattening film 9 is formed on the upper surface of the substrate 2 having the element formed thereon. The flattening film 9 is a layer that covers the on-chip lenses 4 formed on the substrate 2 having the element formed thereon and flattens the upper surface of the substrate 2 having the element formed thereon.

The flattening film 9 is formed of a translucent resin material. For example, as the material of the flattening film 9, an ultraviolet curable resin, a heat curable resin, or a combination of these curing reaction mechanism combined type sealing resin is used. Examples of such resins include acrylic-based, styrene-based, and silicone-based resins. In such resins, fluorine may be appropriately contained, or hollow silica or the like may be dispersed and mixed.

### <Transparent Substrate 3>

The transparent substrate 3 is a sealing material that seals the upper surface of the substrate 2 having the element formed thereon.

The transparent substrate 3 of the present mode is constituted by, for example, a glass substrate. The transparent substrate 3 may be formed of a light transmissive material.

Through-holes 11 are formed in the transparent substrate 3. As illustrated in FIG. 1B, the through-hole 11 is disposed at a position capable of facing the outer circumferential region ARA2 of the substrate 2 having the element formed thereon when seen in a plan view.

Here, in the present specification, the term “plan view” refers to a view in a direction along the thickness direction of the transparent substrate 3 (upward or downward in FIG. 1A).

The through-hole 11 in the present mode extends in the thickness direction of the transparent substrate 3, for example, as illustrated in FIG. 1A. The through-hole 11 in the present mode has a slit-like opening shape, as illustrated in FIG. 1B.

As illustrated in FIG. 1A, a transparent base material is laminated on the flattening film 9 by being attached to the flattening film 9 via an adhesive layer 10. The adhesive layer 10 is disposed on the outer circumferential side of the through-hole 11 at a position capable of facing the outer circumferential region ARA2 of the substrate 2 having the element formed thereon when seen in a plan view.

The through-hole 11 is an opening for making the hollow portion 12 communicate with the outside.

### <Hollow Portion 12>

The hollow portion 12 of the present mode is constituted by an air layer (cavity), as illustrated in FIG. 1A. The air layer is formed between the flattening film 9 and the transparent substrate 3, and is constituted by a hollow sealed by the flattening film 9, the transparent substrate 3, and the adhesive layer 10 on the outer circumference. That is, the hollow portion 12 of the present mode is constituted by the hollow on the inner circumferential side of the adhesive layer 10.

The hollow portion 12 is formed in a region overlapping the entire on-chip lens 4 when seen in a plan view. In the present mode, the hollow portion 12 is formed to include the effective pixel region ARA1 and to overlap a portion of the outer circumferential region ARA2 when seen in a plan view. A portion of the outer circumferential region ARA2 includes formation regions of the through-holes 11 when seen in a plan view.

### <Sealing Member 13>

The solid-state imaging element 1 of the first mode may include sealing members 13 that close the through-holes 11 as illustrated in FIG. 2A. The sealing member 13 seals the through-hole 11 as illustrated in FIGS. 2A and 2B. That is, the sealing member 13 is a member that closes the through-hole 11.

The same applies to other modes.

As the material of the sealing member 13, for example, an ultraviolet curable resin, a heat curable resin, or a combination of these curing reaction mechanism combined type sealing resin is used. Examples of such resins include epoxy-based, acrylic-based, and silicone-based resins, and modified resins of these resins.

It is preferable that a black pigment be added to the resin material constituting the sealing member 13. Examples of black pigment include carbon black, titanium black, iron oxides, composite oxides of copper and chromium, composite oxides of copper, chromium and zinc, and the like.

However, the pigment added to the sealing member 13 is not limited to a black pigment, and other pigments that can block light may be used.

(Second Mode)

A solid-state imaging element 1 according to a second mode will be described with reference to the accompanying drawings.

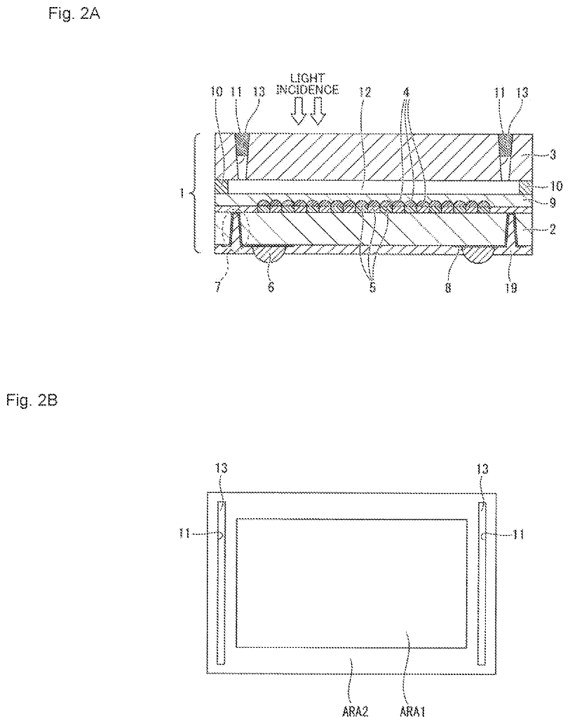

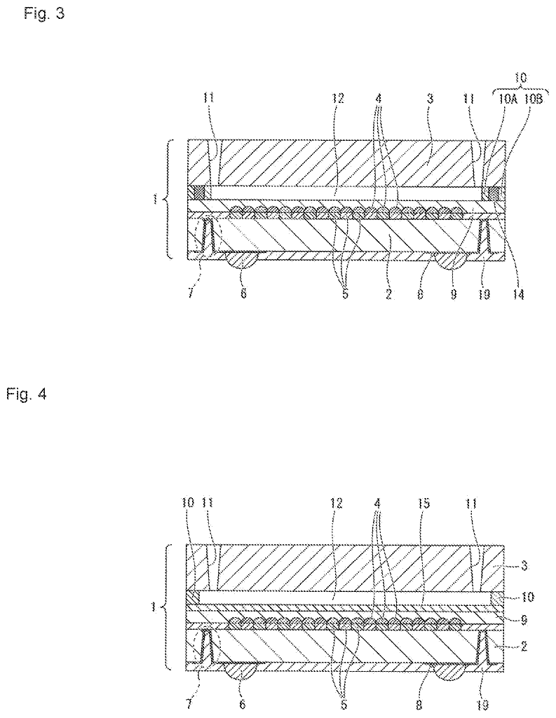

As illustrated in FIG. 3, a basic configuration of the present mode is the same as that of the first mode, but differs from that of the first mode in that spacers 14 are embedded in an adhesive layer 10. The other configurations are the same as those in the first mode.

### <Spacer 14>

The spacer 14 is formed on a lower surface of a transparent substrate 3 at a position capable of facing an outer circumferential region ARA2 and protrudes toward a flattening film 9 from the lower surface of the transparent substrate 3. The spacer 14 of the present mode is formed at a position where the spacer 14 can be embedded in an adhesive layer 10.

The spacer 14 may be formed to surround the entire outer circumference of a hollow portion 12, or may be formed partially in the circumferential direction.

The spacers 14 of the present mode are provided only at the positions of sealing resin layers positioned on the outer sides of left and right through-holes 11 when seen in a plan view. Further, in the present mode, as illustrated in FIG. 3, the spacer 14 is formed such that the sealing resin of the adhesive layer 10 adheres to the entire circumference of the side surface of the spacer 14. That is, as illustrated in FIG. 3, the adhesive layer 10 has a portion 10A on the inner circumferential side of the spacer 14 and a portion 10B on the outer circumferential side of the spacer 14.

For example, the spacer 14 is formed of the same material as the transparent substrate 3 integrally with the transparent substrate 3. The spacer 14 may be formed of a material different from that of the transparent substrate 3. For example, the spacer 14 may be configured to contain the same material as that of a sacrificial layer for forming the hollow portion 12. The spacer 14 is a member that secures a distance between the transparent substrate 3 and the flattening film 9 (an upper surface of the substrate 2 having the element formed thereon).

The sealing resin of the adhesive layer 10 may or may not be disposed on a lower end surface of the spacer 14.

### <Sealing Member 13>

The solid-state imaging element 1 of the second mode may include a sealing member 13 that closes a through-hole 11, as in the first mode. The configuration of the sealing member 13 is the same as that in the first mode.

(Third Mode)

A solid-state imaging element 1 according to a third mode will be described with reference to the accompanying drawings.

As illustrated in FIG. 4, a basic configuration of the present mode is the same as that of the first mode, but differs from the first mode in that an adhesive layer 15 is provided on a flattening film 9. The other configurations are the same as those in the first mode.

### <Adhesive Layer 15>

As illustrated in FIG. 4, the adhesive layer 15 is formed on the flattening film 9. It is preferable that the adhesive layer 15 be formed of a resin material having a lower refractive index than that of the flattening film 9.

Note that a hollow portion 12 and an adhesive layer 10 are formed on the adhesive layer 15.

### <Sealing Member 13>

The solid-state imaging element 1 of the third mode may have a sealing member 13 that closes the through-hole 11, as in the first mode. The configuration of the sealing member 13 is the same as that in the first mode.

(Fourth mode)

A solid-state imaging element 1 according to a fourth mode will be described with reference to the accompanying drawings.

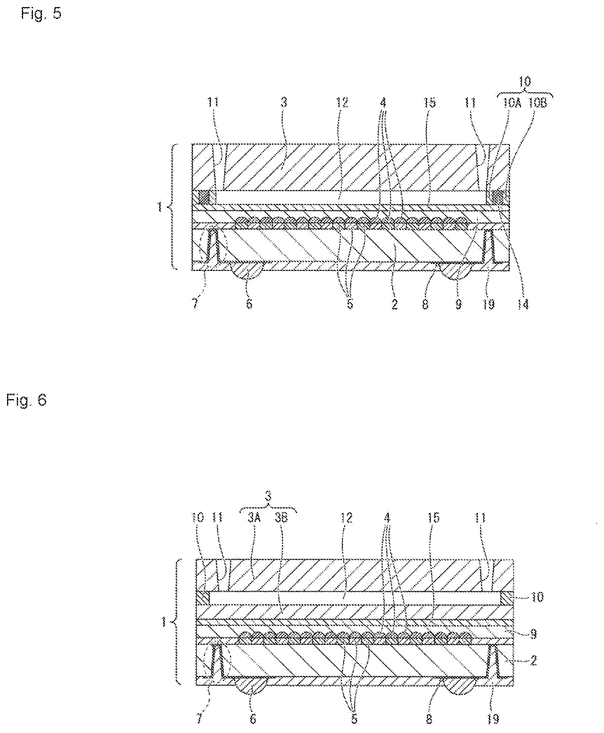

As illustrated in FIG. 5, a basic configuration of the present mode is the same as that of the third mode, but differs from that of the third mode in that spacers 14 are provided in an adhesive layer 10. The other configurations are the same as those in the third mode. For this reason, the description of components other than the spacer 14 is omitted.

### <Spacer 14>

The spacer 14 is formed on a lower surface of a transparent substrate 3 at a position capable of facing an outer circumferential region ARA2 and protrudes toward the adhesive layer 10 from the lower surface of the transparent substrate 3. The spacer 14 of the present mode is formed at a position where the spacer 14 can be embedded in the adhesive layer 10.

The spacer 14 may be formed to surround the entire outer circumference of a hollow portion 12, but may be formed partially along the circumferential direction.

The spacer 14 of the present mode are provided only at the positions of the adhesive layers 10 positioned outside left and right through-holes 11 when seen in a plan view. Further, in the present mode, as illustrated in FIG. 5, the spacer 14 is formed such that the sealing resin of the adhesive layer 10 adheres to the entire circumference of the side surface of the spacer 14. That is, as illustrated in FIG. 5, the adhesive layer 10 has a portion 10A on the inner circumferential side of the spacer 14 and a portion 10B on the outer circumferential side of the spacer 14.

For example, the spacer 14 is formed of the same material as the transparent substrate 3 integrally with the transparent substrate 3. The spacer 14 may be formed of a material different from that of the transparent substrate 3. For example, the spacer 14 may be configured to contain the same material as that of a sacrificial layer for forming the hollow portion 12. The spacer 14 is a member that secures a distance between the transparent substrate 3 and the flattening film 9 (an upper surface of the substrate 2 having the element formed thereon).

The sealing resin of the adhesive layer 10 may or may not be disposed on a lower end surface of the spacer 14.

### <Sealing Member 13>

The solid-state imaging element 1 of the fourth mode may include a sealing member 13 that closes a through-hole 11, as in the first mode. The configuration of the sealing member 13 is the same as that in the first mode.

(Fifth Mode)

A solid-state imaging element 1 according to a fifth mode will be described with reference to the accompanying drawings.

The present mode differs from the third mode in that a hollow portion 12 is formed in a transparent substrate 3 as illustrated in FIG. 6.

The solid-state imaging element of the fifth mode includes a substrate 2 having the element formed thereon and a transparent substrate 3, as illustrated in FIG. 6.

### <Substrate 2 Having Element Formed Thereon>

A plurality of on-chip lenses 4 are disposed in a two-dimensional array on the upper surface of the substrate 2 having the element formed thereon. Further, RDL/solder balls 6 and other wirings are formed on the rear surface side of the substrate 2 having the element formed thereon. The solder balls 6 and the through electrodes 7 are illustrated in FIG. 1A.

### <Flattening Film 9>

A flattening film 9 is formed on the upper surface of the substrate 2 having the element formed thereon. The flattening film 9 is a layer that covers the on-chip lenses 4 formed on the substrate 2 having the element formed thereon and flattens the upper surface of the substrate 2 having the element formed thereon.

### <Adhesive Layer 15>

As illustrated in FIG. 6, an adhesive layer 15 is formed on the flattening film 9. It is preferable that the adhesive layer 15 be formed of a resin material having a lower refractive index than that of the flattening film 9.

Note that a hollow portion 12 and an adhesive layer 10 are formed on the adhesive layer 15.

### <Transparent Substrate 3>

The transparent substrate 3 of the present mode includes two glass substrates, and the two glass substrates are laminated on each other via the adhesive layer 10.

A through-hole 11 is formed in an upper glass substrate 3A. As illustrated in FIG. 6, the through-hole 11 is disposed at a position capable of facing an outer circumferential region ARA2 of the substrate 2 having the element formed thereon when seen in a plan view. The through-hole 11 extends in the thickness direction of the transparent substrate 3. The through-hole 11 of the present mode has, for example, a slit-like opening shape, as in the first mode.

In the present mode, the through-hole 11 is not formed in a lower glass substrate 3B.

The hollow portion 12 is sealed between the two glass substrates. The hollow portion 12 is constituted by a cavity sealed with the two glass substrates and the adhesive layer 10 on the outer circumference. That is, the hollow portion 12 of the present mode is constituted by a hollow on the inner circumferential side of the adhesive layer 10.

The hollow portion 12 is formed in a region overlapping an entire on-chip lens 4 when seen in a plan view. In the present mode, the hollow portion 12 is formed to include an effective pixel region ARA1 and to overlap a portion of the outer circumferential region ARA2 when seen in a plan view. A portion of the outer circumferential region ARA2 includes formation regions of the through-holes 11 when seen in a plan view. Thereby, the hollow portion 12 can communicate with the outside through the through-hole 11.

Here, in the above description, a case where the transparent substrate 3 is constituted by two glass substrates is exemplified. The transparent substrate 3 may have a configuration in which three or more glass substrates are laminated. In addition, the hollow portion 12 may be formed between any glass substrates.

Further, as in the first to fourth modes, the hollow portion 12 may also be separately formed between the transparent substrate 3 and the flattening film 9.

In addition, the lower surfaces of the plurality of lower glass substrates 3B of the transparent substrate 3 are laminated on the adhesive layer 15.

In this configuration, the adhesive layer 15 and the lower glass substrate 3B are interposed between the flattening film 9 and the hollow portion 12.

### <Sealing Member 13>

The solid-state imaging element 1 of the fifth mode may include a sealing member 13 that closes the through-hole 11, as in the first mode. The configuration of the sealing member 13 is the same as that in the first mode.

(Sixth Mode)

A solid-state imaging element 1 according to a sixth mode will be described with reference to the accompanying drawings.

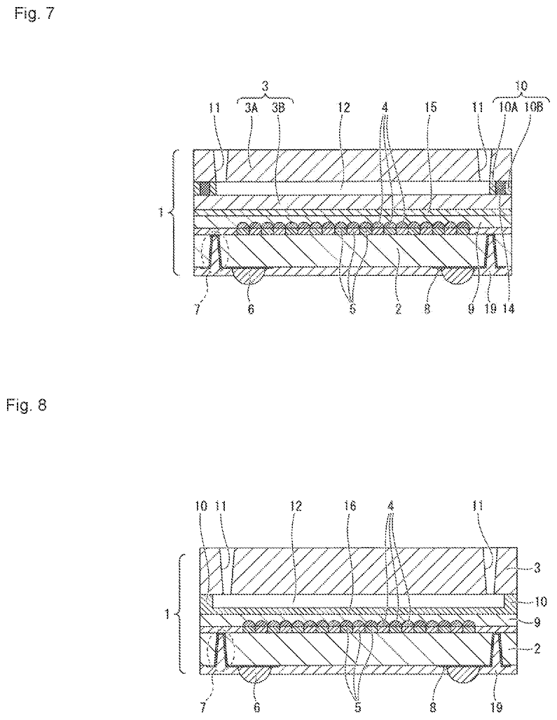

As illustrated in FIG. 7, a basic configuration of the present mode is the same as that of the fifth mode, but differs from that of the fifth mode in that spacers 14 are embedded in an adhesive layer 10. The other configurations are the same as those in the fifth mode. For this reason, the description of components other than the spacer 14 is omitted.

### <Spacer 14>

The spacer 14 is formed on the lower surface of an upper glass substrate 3A at a position capable of facing an outer circumferential region ARA2, and protrudes toward a lower glass substrate 3B from the lower surface of the upper glass substrate 3A. The spacer 14 of the present mode is formed at a position where the spacer 14 can be embedded in an adhesive layer 10.

The spacer 14 may be formed to surround the entire outer circumference of a hollow portion 12, but may be formed partially along the circumferential direction.

The spacer 14 of the present mode are provided only at the positions of the adhesive layers 10 positioned outside left and right through-holes 11 when seen in a plan view. Further, in the present mode, as illustrated in FIG. 7, the spacer 14 is formed such that the sealing resin of the adhesive layer 10 adheres to the entire circumference of the side surface of the spacer 14. That is, as illustrated in FIG. 7, the adhesive layer 10 has a portion 10A on the inner circumferential side of the spacer 14 and a portion 10B on the outer circumferential side of the spacer 14.

For example, the spacer 14 is formed of the same material as a transparent substrate 3 integrally with the transparent substrate 3. The spacer 14 may be formed of a material different from that of the transparent substrate 3. For example, the spacer 14 may be configured to contain the same material as that of a sacrificial layer for forming the hollow portion 12. The spacer 14 is a member that secures a distance between the transparent substrate 3 and the flattening film 9 (an upper surface of the substrate 2 having the element formed thereon).

The sealing resin of the adhesive layer 10 may or may not be disposed on a lower end surface of the spacer 14.

### <Sealing Member 13>

The solid-state imaging element 1 of the sixth mode may include a sealing member 13 that closes a through-hole 11, as in the first mode. The configuration of the sealing member 13 is the same as that in the first mode.

(Seventh Mode)

A solid-state imaging element 1 according to a seventh mode will be described with reference to the accompanying drawings.

As illustrated in FIG. 8, a basic configuration of the present mode is the same as that of the first mode, but differs from that of the first mode in that an adhesive layer 10 is also formed on a flattening film 9. The other configurations are the same as those in the first mode. For this reason, description of other configurations is omitted.

That is, in the seventh mode, the adhesive layer 10 formed on the upper surface of the flattening film 9 is constituted by a portion (a portion denoted by reference numeral 16 in FIG. 8) also formed in an effective pixel region ARA1 and a portion formed in an outer circumferential region ARA2 and having a large thickness of the adhesive layer 10.

In the seventh mode, a hollow portion 12 is constituted by a space surrounded by a transparent substrate 3, an adhesive layer 16 on the bottom side, and an adhesive layer 10 constituting a wall portion rising in the outer circumferential region ARA2.

As in the sixth mode, spacers 14 may be embedded in the adhesive layer 10 positioned in the outer circumferential region ARA2.

### <Sealing Member 13>

The solid-state imaging element 1 of the seventh mode may include a sealing member 13 that closes a through-hole 11, as in the first mode. The configuration of the sealing member 13 is the same as that in the first mode.

(Eighth Mode)

A solid-state imaging element 1 according to an eighth mode will be described with reference to the accompanying drawings.

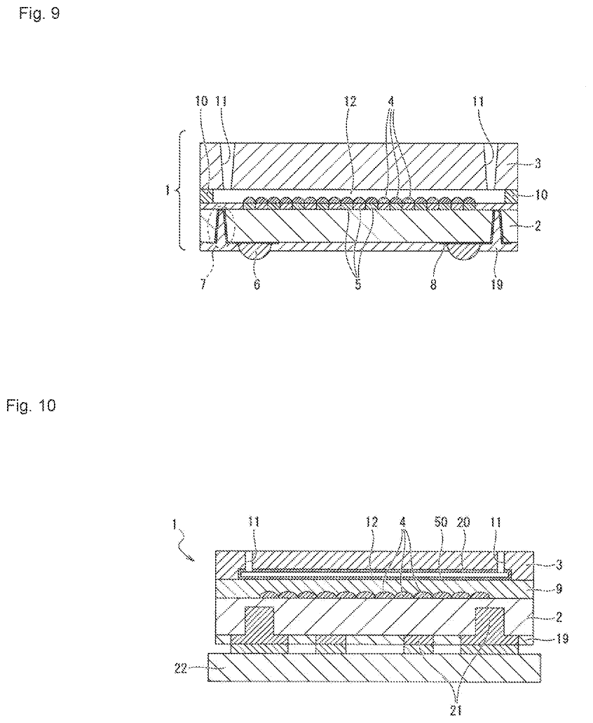

As illustrated in FIG. 9, a basic configuration of the eighth mode is the same as that of the first mode, but differs from the first mode in that a flattening film 9 is not provided. The other configurations are the same as those in the first mode.

That is, in the eighth mode, the flattening film 9 is not provided on a substrate 2 having the element formed thereon. Further, in the eighth mode, a structure is adopted in which a transparent substrate 3 is laminated by being attached to the upper surface of the substrate 2 having the element formed thereon directly or via an adhesive layer 10.

A hollow portion 12 of the present mode is constituted by a cavity surrounded by the upper surface of the substrate 2 having the element formed thereon, the lower surface of the transparent substrate 3, and the adhesive layer 10 on the outer circumference.

### <Sealing Member 13>

The solid-state imaging element 1 of the eighth mode may include a sealing member 13 that closes a through-hole 11, as in the first mode. The configuration of the sealing member 13 is the same as that in the first mode.

(Ninth Mode)

A solid-state imaging element according to a ninth mode will be described with reference to the accompanying drawings.

The solid-state imaging element of the ninth mode includes a substrate 2 having the element formed thereon and a transparent substrate 3, as illustrated in FIG. 10. In FIG. 10, reference numeral 19 denotes a solder mask, and reference numeral 22 denotes a mounting substrate connected to a wiring on a rear surface side.

### <Substrate 2 Having Element Formed Thereon>

In the substrate 2 having the element formed thereon, a plurality of on-chip lenses 4 are disposed in a two-dimensional array corresponding to photoelectric conversion elements, not illustrated in the drawing, which are disposed in a two-dimensional array in an effective pixel region ARA1.

Further, RDL/solder balls 6 and other wirings are formed on the rear surface side of the substrate 2 having the element formed thereon.

### <Flattening Film 9>

A flattening film 9 is formed on the upper surface of the substrate 2 having the element formed thereon. The flattening film 9 is a layer that covers the on-chip lenses 4 formed on the substrate 2 having the element formed thereon and flattens the upper surface of the substrate 2 having the element formed thereon.

### <Transparent Substrate 3>

The transparent substrate 3 is a sealing material that seals the upper surface of the substrate 2 having the element formed thereon.

The transparent substrate 3 of the present mode is constituted by a glass substrate. The transparent substrate 3 may be formed of a light transmissive material.

### <Hollow Portion 12>

A concave portion is formed on the lower surface of the transparent substrate 3.

A cavity surrounded by the concave portion and the flattening film 9 constitutes a hollow portion 12.

The hollow portion 12 is formed in a region overlapping an entire on-chip lens 4 when seen in a plan view. In the present mode, the hollow portion 12 is formed to include the effective pixel region ARA1 and to overlap a portion of an outer circumferential region ARA2 when seen in a plan view. A portion of the outer circumferential region ARA2 includes formation regions of the through-holes 11 when seen in a plan view.

The lower surface of the outer circumference of the transparent substrate 3 is bonded to the upper surface of the flattening film 9 via an adhesive which is not illustrated in the drawing.

### <Through-Hole 11>

Further, a through-hole 11 that makes the hollow portion 12 communicate with the outside is formed in the transparent substrate 3. The through-hole 11 is disposed at a position capable of facing the outer circumferential region ARA2 of the substrate 2 having the element formed thereon when seen in a plan view.

The through-hole 11 extends in the thickness direction of the transparent substrate 3, for example, as illustrated in FIG. 10.

### <Adhesive Layer 10>

The outer circumferential region ARA2 (a position on the outer circumferential side of a concave portion 41) of the transparent substrate 3 is bonded onto the flattening film 9 via the adhesive layer 10 (not illustrated), and thus the transparent substrate 3 is laminated on the substrate 2 having the element formed thereon.

### <Low-Refraction Film>

In addition, low-refraction films 20 and 50 are formed on at least upper and lower surfaces among surfaces (upper and lower surfaces and side surfaces) forming the hollow portion 12.

The low-refraction films 20 and 50 may be omitted.

### <Sealing Member 13>

The solid-state imaging element 1 of the ninth mode may include a sealing member 13 that closes the through-hole 11, as in the first mode. The configuration of the sealing member 13 is the same as that in the first mode.

(Tenth Mode)

A solid-state imaging element according to a tenth mode will be described with reference to the accompanying drawings.

A basic configuration of the solid-state imaging element of the tenth mode is the same as that of the ninth mode, as illustrated in FIGS. 12A and 12B. However, the solid-state imaging element of the tenth mode differs from that of the ninth mode in that a support portion 24 is provided in a hollow portion 12. That is, the components of the solid-state imaging element of the tenth mode are the same as those of the solid-state imaging element of the ninth mode except for the hollow portion 12.

### <Hollow Portion 12>

A concave portion is formed on the lower surface of a transparent substrate 3. A cavity surrounded by the concave portion and a flattening film 9 constitutes the hollow portion 12.

### <Support Portion 24>

In the tenth mode, a columnar or wall-like support portion 24 protruding in the thickness direction of the transparent substrate 3 is formed integrally with the transparent substrate 3 in the concave portion. That is, the support portion 24 is formed of the same material as that of the transparent substrate 3.

In the present mode, as illustrated in FIG. 11, a case where a concave portion 41 is divided into a plurality of rooms by the support portion 24 is exemplified. Communication portions 3Aa that make a central room communicate with peripheral rooms are formed in a portion of the support portion 24.

It is preferable that lower end surfaces of a plurality of support portions 24 be flush with a lower end surface of the outer circumferential portion of the transparent substrate 3.

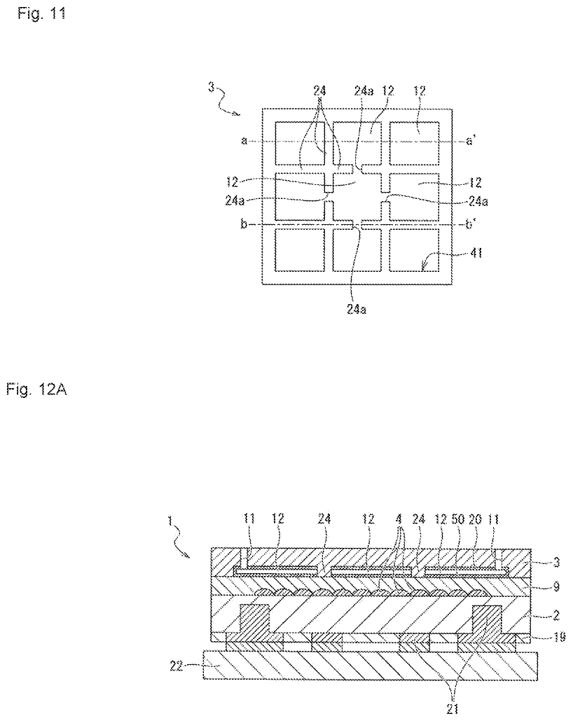

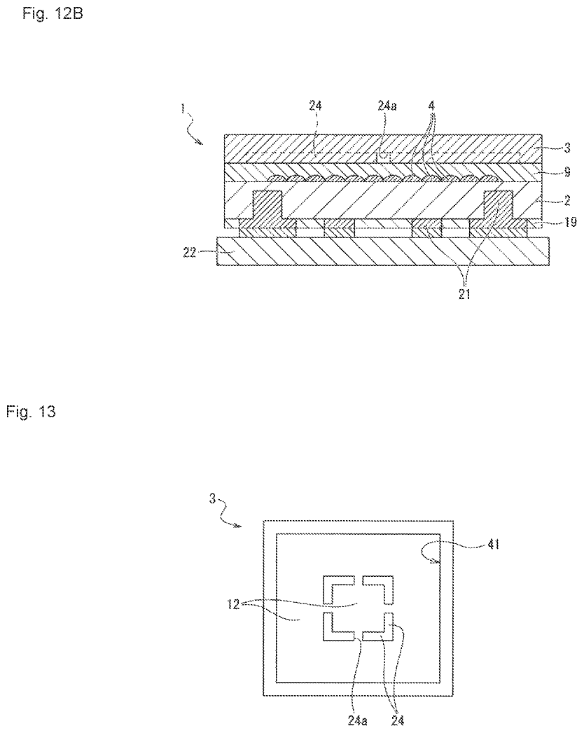

In addition, the arrangement of the support portions 24 is not particularly limited, and for example, the arrangement as illustrated in FIG. 13 may be used.

In addition, when the support portion 24 is one or more columnar or wall-like structures that connect the lower surface of the transparent substrate 3 and the flattening film 9 in the hollow portion 12, the shape, number, and arrangement of the support portions 24 are not particularly limited. In FIGS. 11 and 13, the wall-like support portions 24 are formed to be continuous with each other, but the plurality of support portions 24 may be independent of each other. The support portion 24 may protrude toward the flattening film 9 from the lower surface of the transparent substrate 3.

Note that, in FIG. 13, the support portions 24 are disposed to form a room in a central portion, but the support portions 24 may be disposed to form, for example, a rectangular column in the central portion.

The support portions 24 may be provided in other forms.

### <Through-Hole 11>

In addition, through-holes 11 are formed in the transparent substrate 3. As illustrated in FIG. 12A, the through-hole 11 is disposed at a position capable of facing the outer circumferential region ARA2 of the substrate 2 having the element formed thereon when seen in a plan view. The through-hole 11 extends in the thickness direction of the transparent substrate 3.

Even when the concave portion 41 is divided into a plurality of rooms by the support portion 24, the number and arrangement positions of the through-holes 11 are set such that the through-holes 11 communicate with any one of the rooms. In the example of FIG. 11, since eight rooms on the outer circumference are independent of each other, eight through-holes 11 are disposed to communicate with the rooms.

The other configurations are the same as those in the ninth mode.

(Eleventh Mode)

A solid-state imaging element according to an eleventh mode will be described with reference to the accompanying drawings.

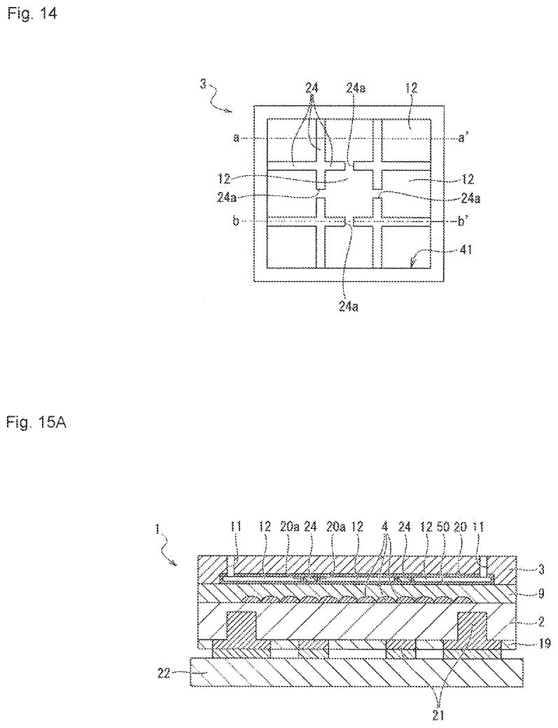

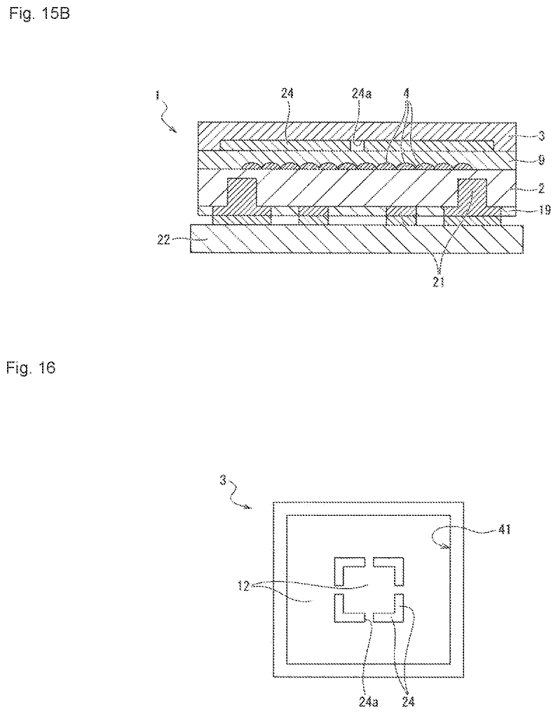

As illustrated in FIGS. 14, 15A, and 15B, a basic configuration of the eleventh mode is the same as that of the tenth mode. Other configurations in the eleventh mode are the same as those in the tenth mode except that the material of the support portion 24 is different.

### <Support Portion 24>

In the present mode, as illustrated in FIG. 14, the support portions 24 are disposed in the hollow portion 12, as in the tenth mode. However, in the present mode, the support portion 24 is formed of a resin material different from that of the transparent substrate 3. The support portion 24 is formed of a light transmissive resin material. The support portion 24 is formed of, for example, the same resin material as that of a sacrificial layer, which will be described later.

A low-refraction film 20a is formed on the surface of the support portion 24 as illustrated in FIG. 15A. For this reason, when the sacrificial layer is etched through the through-holes 11 and removed, the sacrificial layer constituting the support portion 24 can remain in the hollow portion 12. However, the support portion 24 may be formed of a material other than the sacrificial layer, the material being a resin material that is not removed when the sacrificial layer is etched.

The other configurations in the eleventh mode are the same as those in the tenth mode.

Note that the arrangement of the support portions 24 is not particularly limited, and, for example, the arrangement as illustrated in FIG. 16 may be used.

(Twelfth Mode)

A solid-state imaging element according to a twelfth mode will be described with reference to the accompanying drawings.

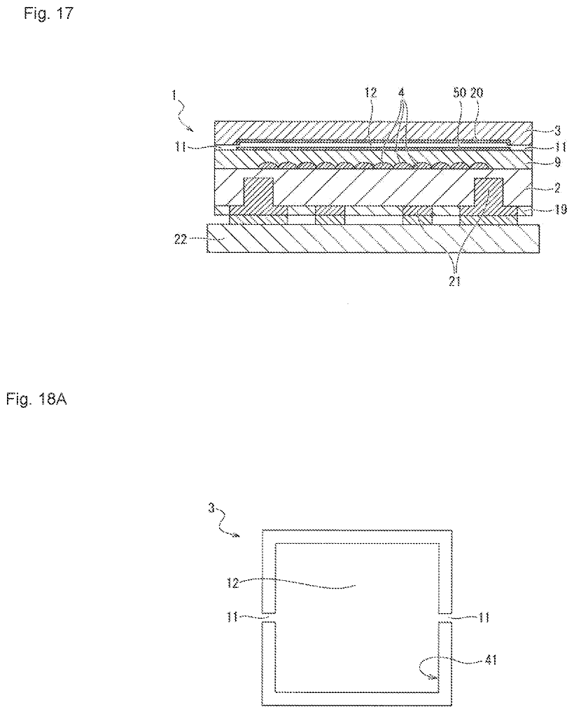

As illustrated in FIG. 17, a basic configuration of the twelfth mode is the same as that of the ninth mode. The twelfth mode has the same configuration as that of the ninth mode except that through-holes 11 are formed at different positions.

### <Through-Hole 11>

In the twelfth mode, as illustrated in FIG. 17, the through-holes 11 are formed to be opened in a side wall of a transparent substrate 3. That is, the through-holes 11 are formed to extend from the side surface of a concave portion 41 formed in the transparent substrate 3 in a direction intersecting a plate thickness direction of the transparent substrate 3 (an orthogonal direction in the present example). The through-hole 11 may be formed at any position as long as the through-hole 11 can face an outer circumferential region ARA2 of a substrate 2 having the element formed thereon when seen in a plan view.

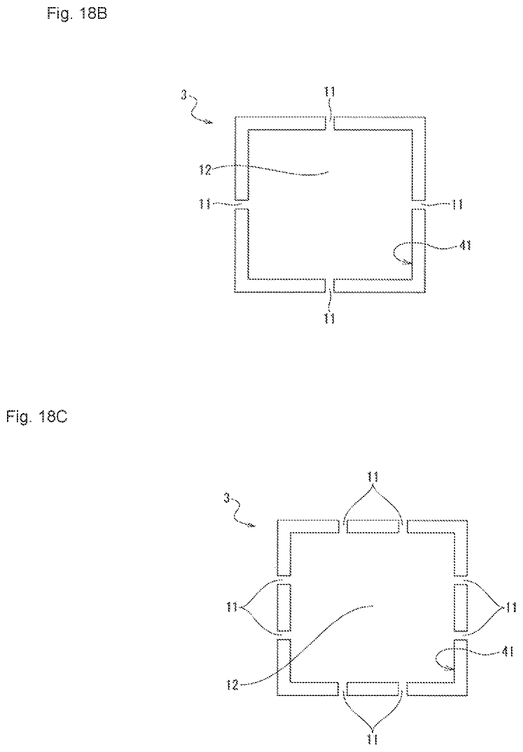

Examples of the formation position of the through-hole 11 are illustrated in FIGS. 18A, 18B, and 18C. The example of FIG. 18A is an example in which the through-holes 11 are formed on two sides of the transparent substrate 3 that face each other on the right and left sides. The example of FIG. 18B is an example in which the through-holes 11 are formed in four sides of the transparent substrate 3 respectively. The example of FIG. 18C is an example in which a plurality of through-holes 11 are formed in each side.

Here, in the example of FIG. 17, a configuration in which the through-holes 11 are formed in groove shapes at a lower end of the transparent substrate, and the lower surfaces of the through-holes 11 are formed by a flattening film 9 is illustrated. However, the through-hole 11 may have a shape that penetrates the side portion of the transparent substrate (see FIG. 29A and the like) or may extend laterally to penetrate the flattening film 9.

The other configurations in the twelfth mode are the same as those in the ninth mode.

(Thirteenth Mode)

A solid-state imaging element according to a thirteenth mode will be described with reference to the accompanying drawings.

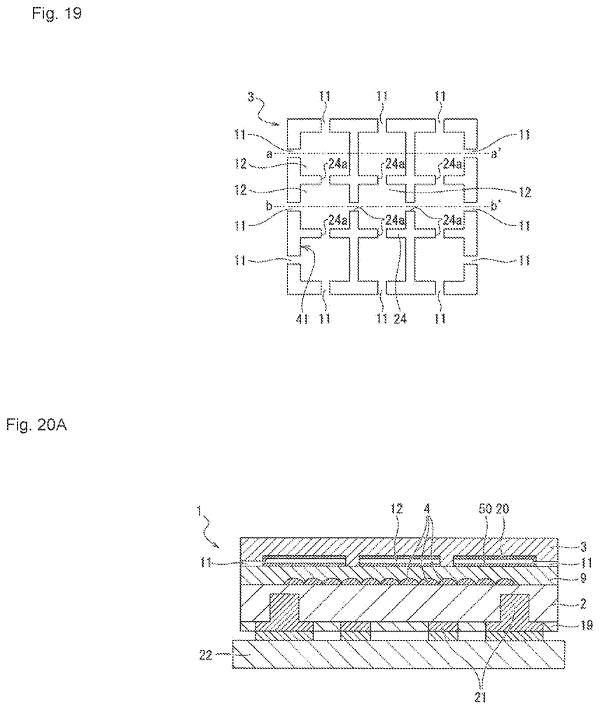

As illustrated in FIGS. 20A, 20B, and 19, a basic configuration of the thirteenth mode is the same as that of the tenth mode. The twelfth mode has the same configuration as that of the tenth mode except that the formation positions of through-holes 11 and support portions 24 are different.

### <Through-Hole 11>

In the twelfth mode, as illustrated in FIG. 20A, the through-holes 11 are formed to be opened in a side wall of a transparent substrate 3. That is, the through-holes 11 are formed to extend from the side surface of a concave portion 41 formed in the transparent substrate 3 in a direction intersecting a plate thickness direction of the transparent substrate 3 (an orthogonal direction in the present example).

The through-hole 11 may be formed at any position as long as the through-hole 11 can face an outer circumferential region ARA2 of a substrate 2 having the element formed thereon when seen in a plan view.

### <Support Portion 24>

The arrangement of the support portions 24 is the same as that in the tenth mode, as illustrated in FIG. 19. However, since the through-holes 11 are provided in the side wall, communication passages 24a for communication with the through-holes 11 are formed in the support portions 24.

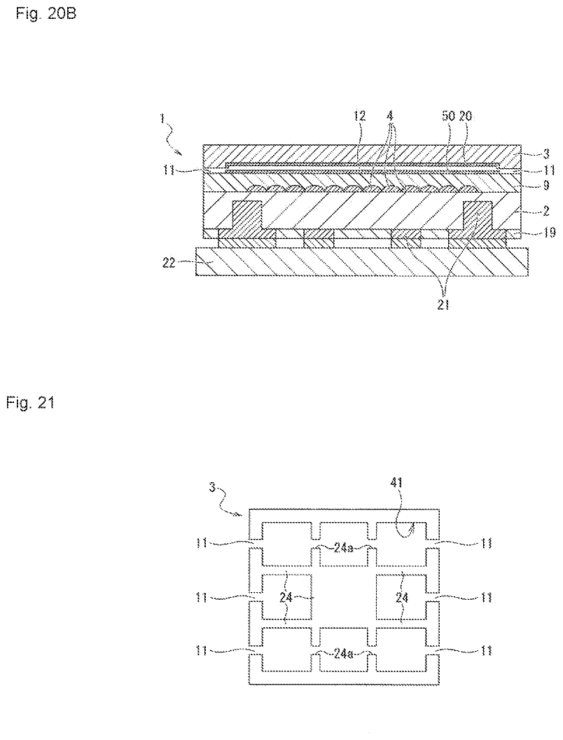

Another example of the arrangement of the support portions 24 is illustrated in FIG. 21. In the present example, a columnar support portion 24 is provided at a central portion of the concave portion 41.

The other configurations in the twelfth mode are the same as those in the tenth mode.

(Fourteenth Mode)

A solid-state imaging element according to a fourteenth mode will be described with reference to the accompanying drawings.

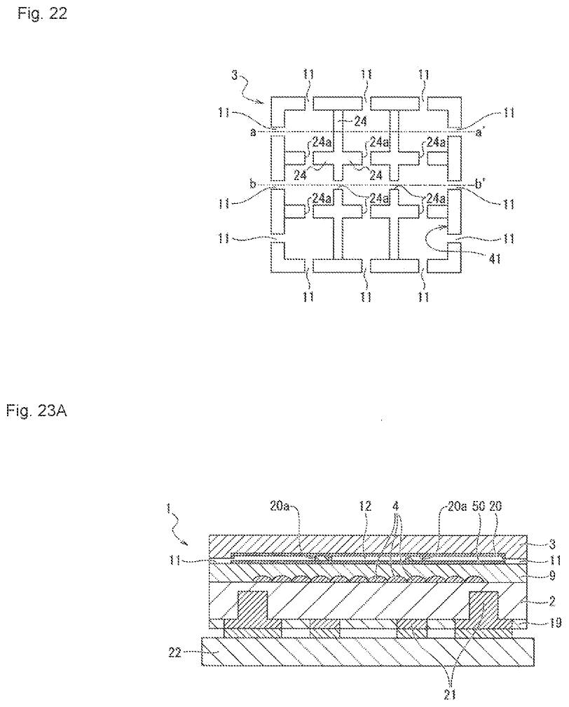

As illustrated in FIGS. 22, 23A, and 23B, a basic configuration of the fourteenth mode is the same as that of the thirteenth mode. The fourteenth mode has the same configuration as that of the thirteenth mode except that the material of a support portion 24 is different.

### <Support Portion 24>

In the present mode, a support portion 24 is formed of a resin material different from that of a transparent substrate 3. However, the support portion 24 is formed of a light transmissive resin material. The support portion 24 is formed of, for example, the same resin material as that of a sacrificial layer to be described later.

A low-refraction film 20a is formed on the surface of the support portion 24. For this reason, even when the sacrificial layer is removed by etching through through-holes 11, the sacrificial layer constituting the support portion 24 can remain.

The other configurations in the fourteenth mode are the same as those in the thirteenth mode.

(Fifteenth Mode)

A solid-state imaging element according to a fifteenth mode will be described with reference to the accompanying drawings.

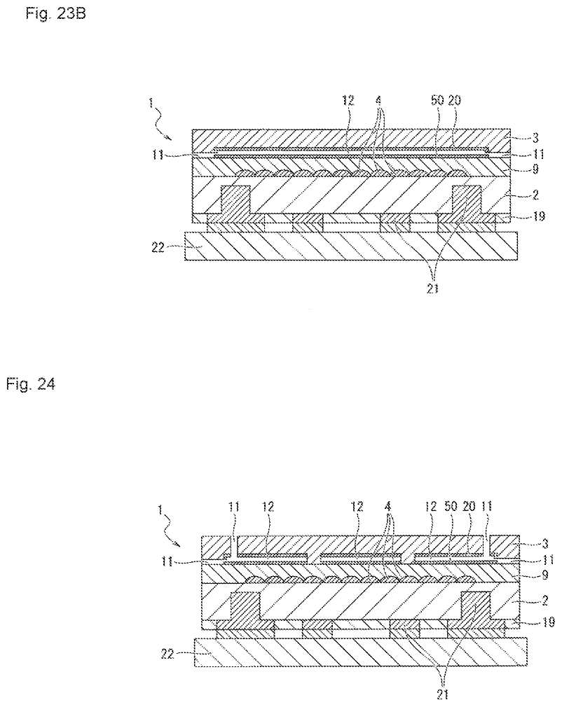

As illustrated in FIG. 24, a basic configuration of the fifteenth mode is the same as that of the thirteenth mode. The fifteenth mode has the same configuration as that of the thirteenth mode except that the through-holes 11 are formed at different positions.

### <Through-Hole 11>

In the fifteenth mode, as illustrated in FIG. 24, the through-holes 11 are formed in both glass side walls and a transparent substrate 3 in the thickness direction. Note that the support portion 24 may be omitted. In addition, the support portion 24 may be formed of a material different from that of the transparent substrate 3.

The other configurations in the fifteenth mode are the same as those in the thirteenth mode.

(Through-Hole 11)

A supplementary description of the through-hole 11 will be given.

The through-hole 11 may not be formed to extend in the thickness direction as long as it is formed in an outer circumferential region ARA2 when seen in a plan view.

In addition, the through-hole 11 may be provided in the transparent substrate 3 or may be formed at a position where an adhesive layer 10 is provided between the transparent substrate 3 and a flattening film 9 formed on a substrate 2 having the element formed thereon. Note that it is preferable that the adhesive layer 10 provided on the flattening film 9 be provided in the outer circumferential region ARA2 excluding an effective pixel region ARA1.

The through-hole 11 may have a cross-section having a slit shape or may have a cross-section having a hole shape such as a circular shape or a rectangular shape. That is, as long as the through-hole 11 is formed in the outer circumferential region ARA2, there is no limitation on the cross-section of the opening of the through-hole 11.

Next, examples of positions of the through-holes 11 are described.

In the above description, a case where the slit-like through-holes 11 are formed on both right and left sides has been exemplified.

### <Example of Arrangement of Slit-Like Through-Holes 11>

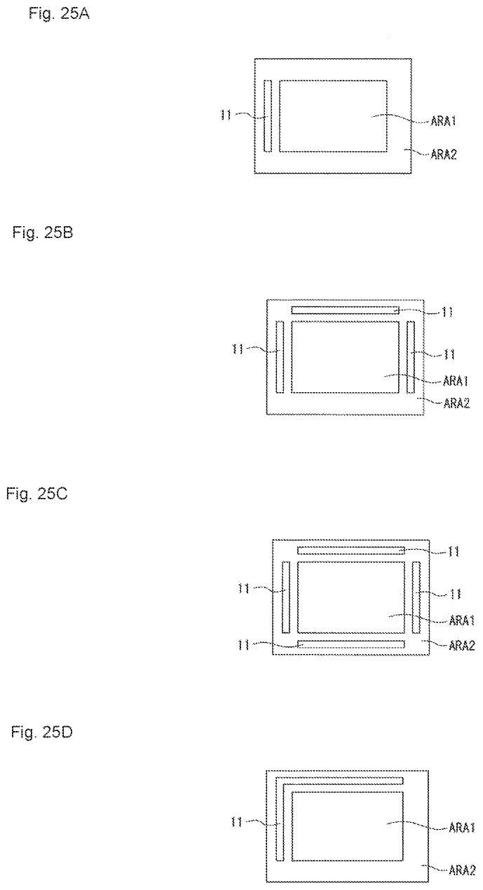

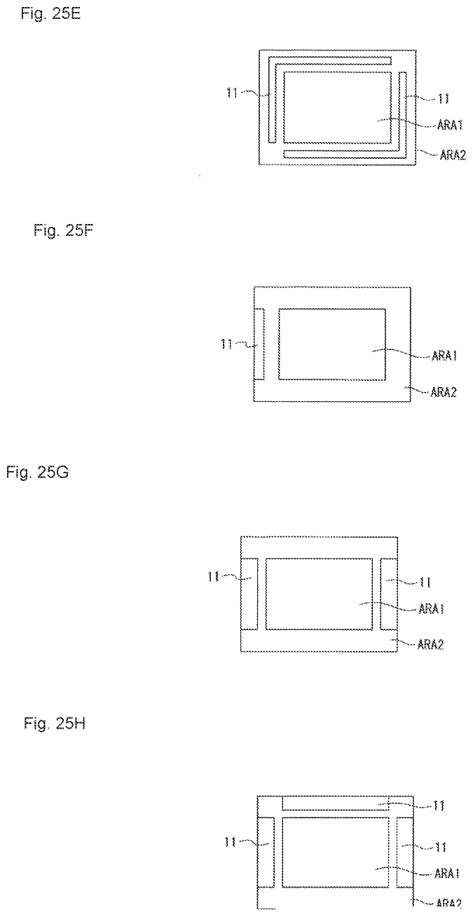

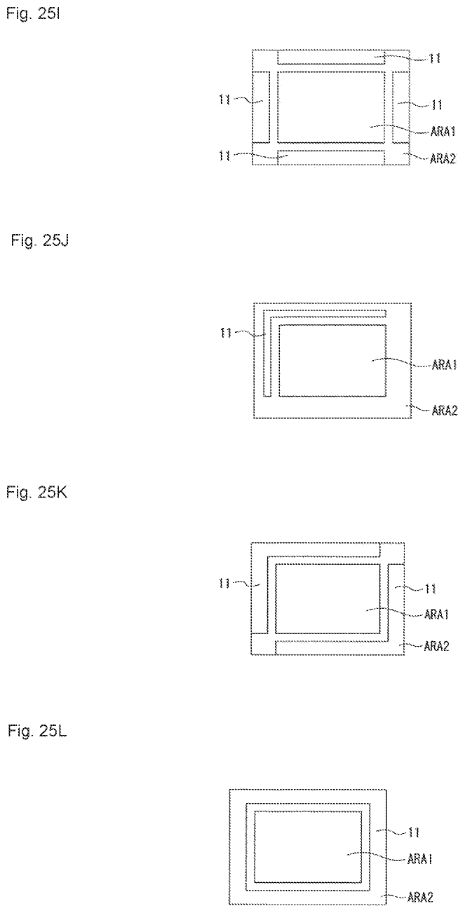

FIG. 25A illustrates a case where the slit-like through-hole 11 is opened in the plate thickness direction and formed in one side among the four sides of the outer circumferential region ARA2.

FIG. 25B illustrates a case where the slit-like through-holes 11 are opened in the plate thickness direction and formed in three side among the four sides of the outer circumferential region ARA2.

FIG. 25C illustrates a case where the slit-like through-holes 11 are opened in the plate thickness direction and formed in all of the four sides of the outer circumferential region ARA2.

FIG. 25D illustrates a case where the slit-like through-holes 11 are opened in the plate thickness direction and formed in an L-shape across two adjacent sides of the outer circumferential region ARA2.

FIG. 25E illustrates a case where two sets of slit-like through-holes 11 are opened in the plate thickness direction and formed in an L-shape across two adjacent sides of the outer circumferential region ARA2.

FIG. 25F illustrates a case where the slit-like through-hole 11 is opened in the side surface and formed in one side among the four sides of the outer circumferential region ARA2.

FIG. 25G illustrates a case where the slit-like through-holes 11 are opened in the side surfaces and formed in two sides among the four sides of the outer circumferential region ARA2.

FIG. 25H illustrates a case where the slit-like through-holes 11 are opened in the side surfaces and formed in three sides among the four sides of the outer circumferential region ARA2.

FIG. 25I illustrates a case where the slit-like through-holes 11 are opened in the side surfaces and formed in all of the four sides of the outer circumferential region ARA2.

FIG. 25J illustrates a case where the slit-like through-hole 11 is opened in the side surface and formed in an L shape across two adjacent sides of the outer circumferential region ARA2.

FIG. 25K illustrates a case where two sets of slit-like through-holes 11 are opened in the side surfaces and formed in an L shape across two adjacent sides of the outer circumferential region ARA2.

FIG. 25L illustrates a case where the slit-like through-hole 11 is opened in the side surface and formed along the entire circumference of the side surface.

<Example of Arrangement of Through-Holes 11 Constituted by Holes with Circular or Rectangular Cross-Sections>

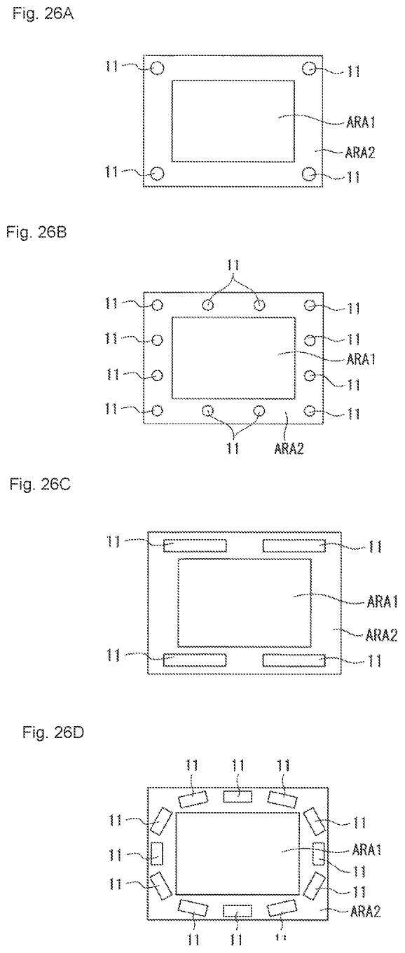

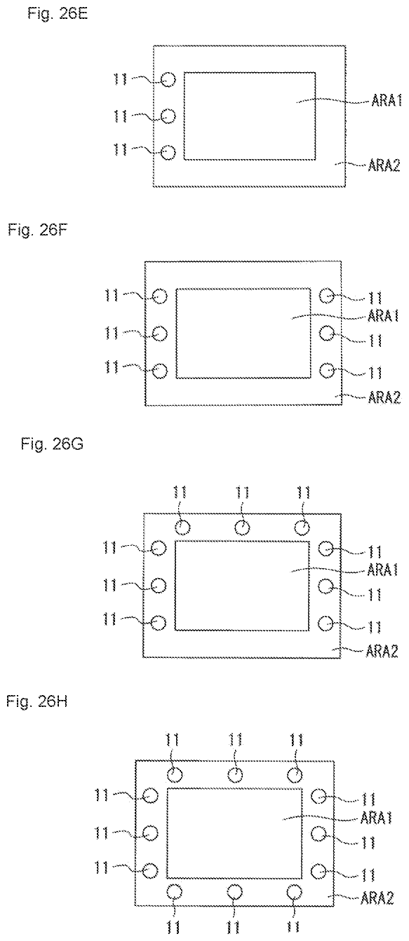

FIG. 26A illustrates a case where the through-holes 11 are opened in the plate thickness direction and formed at four corners of the outer circumferential region ARA2.

FIG. 26B illustrates a case where the through-holes 11 are opened in the plate thickness direction and formed at four corners and in four sides of the outer circumferential region ARA2.

FIG. 26C illustrates a case where rectangular through-holes 11 are opened in the plate thickness direction and formed in two corresponding sides of the four sides of the outer circumferential region ARA2 with the long sides thereof facing each side.

FIG. 26D illustrates a case where rectangular through-holes 11 are opened in the plate thickness direction and formed along the outer circumferential region ARA2 so as to surround a pixel region.

FIG. 26E illustrates a case where a plurality of through-holes 11 are opened in the plate thickness direction and formed along one of the four sides among the four sides of the outer circumferential region ARA2.

FIG. 26F illustrates a case where a plurality of through-holes 11 are opened in the plate thickness direction and formed in two opposing sides of the four sides of the outer circumferential region ARA2.

FIG. 26G illustrates a case where a plurality of through-holes 11 are opened in the plate thickness direction and formed along three side among the four sides of the outer circumferential region ARA2.

FIG. 26H illustrates a case where a plurality of through-holes 11 are opened in the plate thickness direction and formed along all of the four sides of the outer circumferential region ARA2.

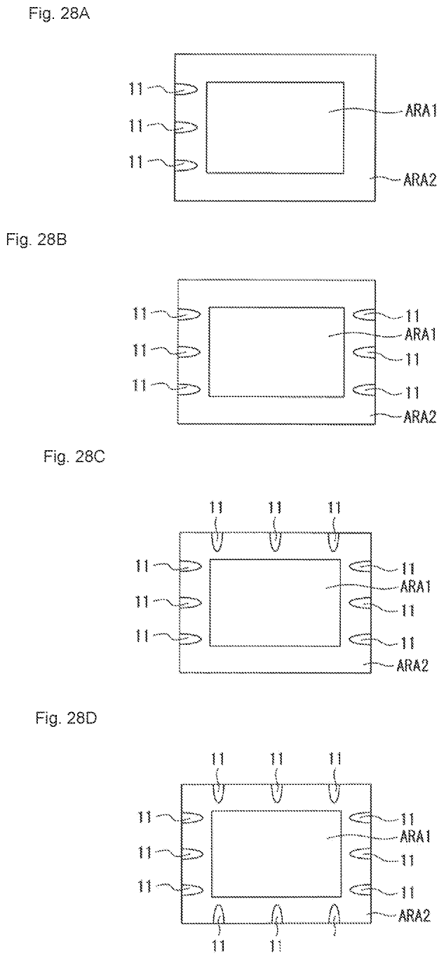

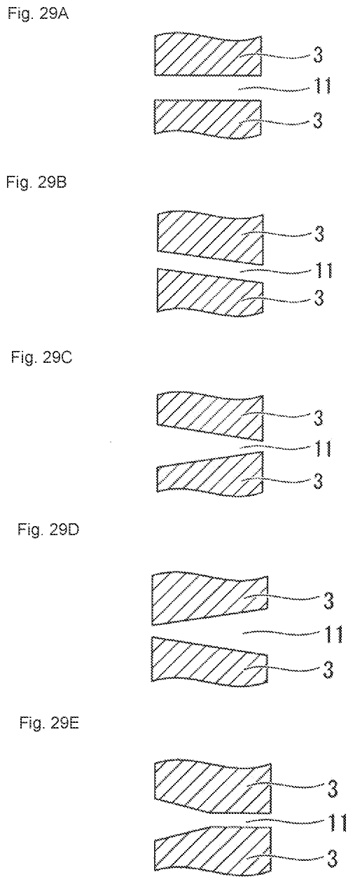

FIG. 28A illustrates a case where a plurality of through-holes 11 are opened in the side surfaces and formed along one side among the four sides of the outer circumferential region ARA2.

FIG. 28B illustrates a case where a plurality of through-holes 11 are opened in the side surfaces and formed in two opposing sides among the four sides of the outer circumferential region ARA2 that face each other.

FIG. 28C illustrates a case where a plurality of through-holes 11 are opened in the side surfaces and formed along three sides among the four sides of the outer circumferential region ARA2.

FIG. 28D illustrates a case where a plurality of through-holes 11 are opened in the side surfaces and formed along all of the four sides of the outer circumferential region ARA2.

<Example of cross-section of through-hole 11>

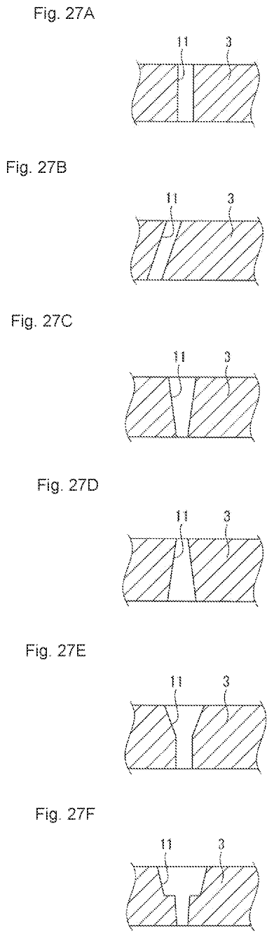

Cross-sectional shapes of the through-holes 11 extending in the plate thickness direction can be illustrated in FIGS. 27A to 27F.

FIG. 27A illustrates a case where the through-hole 11 is formed in the thickness direction, and the cross-sectional area of the opening is fixed in the axial direction.

FIG. 27B illustrates a case where the through-hole 11 is formed obliquely with respect to the thickness direction, and the cross-sectional area of the opening is fixed in the axial direction.

FIG. 27C illustrates a case where the through-hole 11 is formed in the thickness direction, and the cross-sectional area of the opening decreases downward along the axial direction.

FIG. 27D illustrates a case where the through-hole 11 is formed in the thickness direction, and the cross-sectional area of the opening increases downward along the axial direction.

FIG. 27E illustrates a case where the through-hole 11 is formed in the thickness direction, and the cross-sectional area of the opening only on the upper surface side increases downward along the axial direction.

FIG. 27F illustrates a case where the through-hole 11 is formed in the thickness direction, and the cross-sectional area of the opening only on the upper surface side is expanded in a trapezoidal shape.

The cross-sectional shape of the through-hole 11 when the through-hole 11 is formed in the side wall can be exemplified in FIGS. 29A to 29E.

FIG. 29A illustrates a case where the through-hole 11 is formed in a direction orthogonal to the thickness direction, and the cross-sectional area of the opening is fixed in the axial direction.

FIG. 29B illustrates a case where the through-hole 11 is formed to be inclined from a direction orthogonal to the thickness direction, and the cross-sectional area of the opening is fixed in the axial direction.

FIG. 29C illustrates a case where the through-hole 11 is formed in a direction orthogonal to the thickness direction, and the cross-sectional area of the opening decreases inward along the axial direction.

FIG. 29D illustrates a case where the through-hole 11 is formed in a direction orthogonal to the thickness direction, and the cross-sectional area of the opening increases inward along the axial direction.

FIG. 29E illustrates a case where the through-hole 11 is formed in the thickness direction, and the cross-sectional area of the opening increases only on the hollow portion 12 side.

(Sealing Member 13)

A supplementary description of the sealing member 13 will be given.

The configuration of the sealing member 13 is not limited as long as the sealing member 13 can close the through-hole 11. That is, the shape of the sealing member 13 being embedded is not particularly limited as long as the through-hole 11 is embedded and closed. For example, the upper surface of the sealing member 13 may be the same as the upper surface of the transparent substrate 3, or the upper surface of the sealing member 13 may protrude in a convex shape with respect to the upper surface of the transparent substrate 3 or may be recessed.

Note that, when a black pigment is added to the sealing member 13, flare is suppressed, and thus the image quality of the solid-state imaging element 1 is improved.

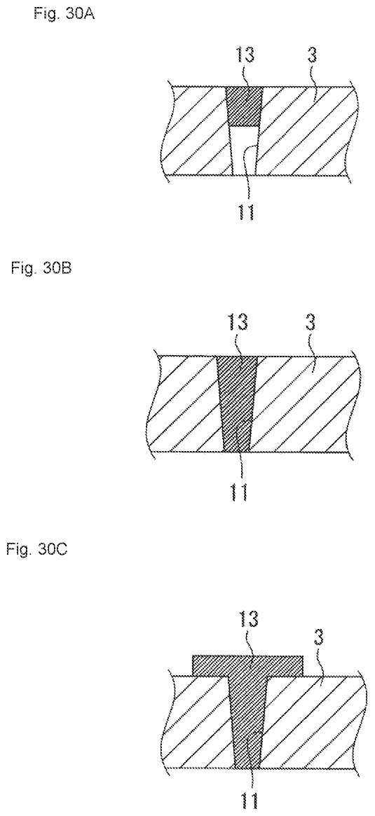

The sealing member 13 may close only a portion of the through-hole 11 in the axial direction as illustrated in FIG. 30A, or may be provided to close the entire through-hole 11 in the axial direction as illustrated in FIG. 30B. In addition, the sealing member 13 may have a portion protruding from the through-hole 11 as illustrated in FIG. 30C, or may be more recessed than the opening end of the through-hole 11.

[Manufacturing Method]

Next, a method of manufacturing the solid-state imaging element 1 based on the present disclosure will be described with reference to the accompanying drawings.

(First Manufacturing Method)

A first manufacturing method will be described.

### <Formation of Transparent Substrate 3>

A first example of a method of forming the transparent substrate 3 will be described.

The size of the transparent substrate 3 is, for example, the size of a wafer.

The transparent substrate 3 is constituted by, for example, a glass substrate.

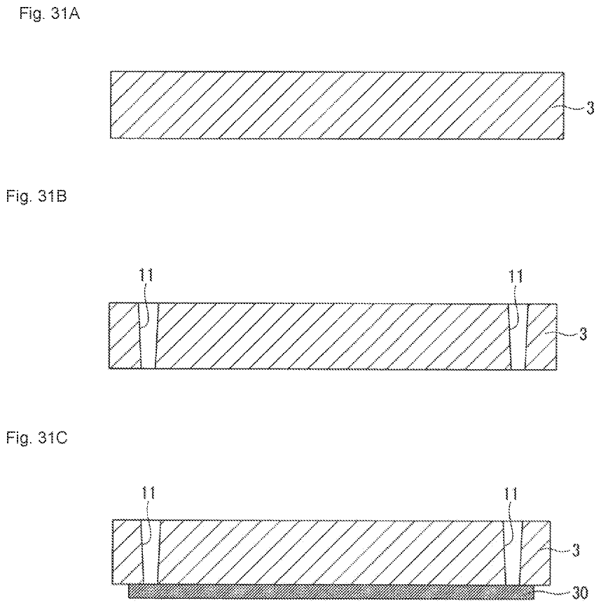

In the first example, first, processing for forming the through-holes 11 in the thickness direction is performed on the transparent substrate 3 illustrated in FIG. 31A, as illustrated in FIG. 31B. As described above, the through-hole 11 is formed at a position capable of facing the outer circumferential region ARA2 and is opened in the thickness direction of the transparent substrate 3. The cross-sectional shape of the opening of the through-hole 11 and the number of the through-holes 11 are not particularly limited.

The processing for forming the through-holes 11 is executed by, for example, dry etching, wet etching, laser processing, or the like.

Next, as illustrated in FIG. 31C, the sacrificial layer is formed on the lower surface of the transparent substrate 3 in which the through-holes 11 are formed. The sacrificial layer is formed in a region including a position capable of facing the entire effective pixel region ARA1 and the lower surface of the transparent substrate 3 in which the through-holes 11 are formed. However, the formation of the sacrificial layer is performed such that a portion provided with the adhesive layer 10 remains at the position of the entire circumference on the outer circumference side of the formation position of the sacrificial layer on the lower surface of the transparent substrate 3.

The sacrificial layer is formed, for example, by first attaching a silicon substrate to the lower surface of the transparent substrate 3 using anodic bonding or the like. Thereafter, unnecessary portions in the attached silicon substrate are removed by etching to form the sacrificial layer. The unnecessary portion is a portion provided with the adhesive layer 10 on the outer circumferential side of the position facing the bottom of the through-hole 11.

Examples of the material of the sacrificial layer include monocrystalline silicon, polycrystalline silicon, amorphous silicon, a silicon nitride film, and the like.

### <Formation of Flattening Film 9>

The flattening film 9 may be formed before, after, or at the same time as the transparent substrate 3 is formed.

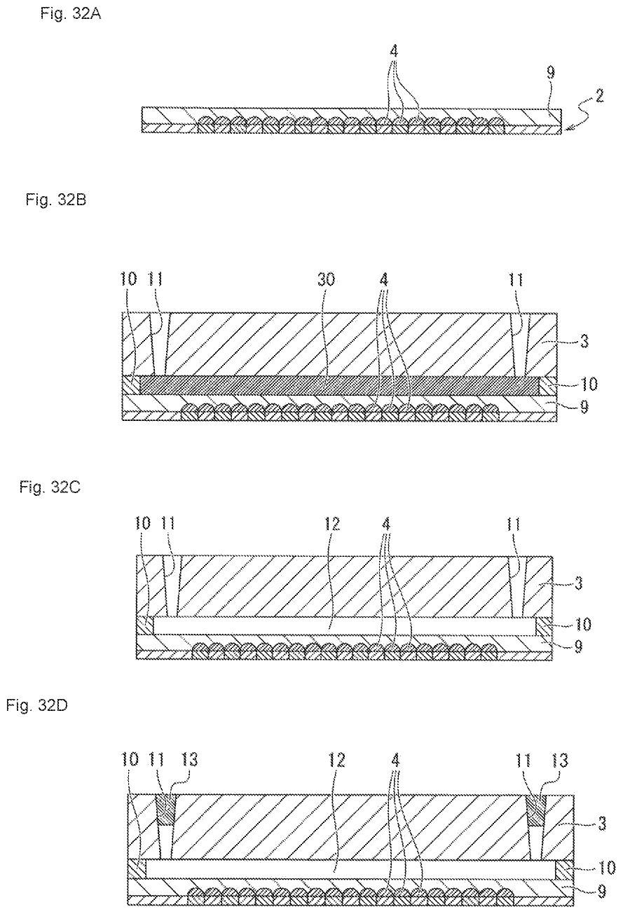

The flattening film 9 is formed on the upper surface (a mesh on the light incidence surface side) of the substrate 2 having the element formed thereon so as to completely cover the on-chip lens 4 illustrated in FIG. 32A.

The substrate 2 having the element formed thereon in this state is the substrate 2 on which the element of the solid-state imaging element 1 (a CCD, a CMOS, surface irradiation type, or the like) is formed. The substrate 2 having the element formed thereon at the forming the flattening film 9 is in a state where, for example, components up to the on-chip lens 4 (microlens) are formed on the light incidence surface side of the substrate 2 having the element formed thereon, and wiring on the rear surface side has not been performed.

As the material of the flattening film 9, for example, an ultraviolet curable resin, a heat curable resin, or a combination of these curing reaction mechanism combined type sealing resin is used. Examples of such resins include acrylic-based, styrene-based, and silicone-based resins. In such resins, fluorine may be appropriately contained, or hollow silica or the like may be dispersed and mixed.

### <Attachment of Transparent Substrate 3>

As illustrated in FIG. 32B, the transparent substrate 3 formed as described above is attached and laminated on the flattening film 9. Regarding the attachment of the transparent substrate 3, the adhesive layer 10 is formed in the outer circumferential portion of the sacrificial layer, and the transparent substrate 3 is attached onto the flattening film 9 by the adhesive layer 10. Note that the adhesive layer 10 may be formed on the upper side of the flattening film 9 and subjected to attachment processing, or may be formed on the transparent substrate 3 side and subjected to attachment processing. Thereby, the adhesive layer 10 is disposed along the entire circumference of the sacrificial layer in the outer circumferential direction.

As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Formation of Rewiring>

After the transparent substrate 3 is attached, RDL, solder balls 6, and rewiring processing (wiring processing on the rear surface side) such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 32C. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

Here, for example, when isotropic plasma etching or the like is adopted for the etching of the sacrificial layer, it is possible to perform etching based on a high selection ratio of 1000 or more such as SiO₂, resins, Al, TiN, SiC, and the like.

In the present manufacturing method, the side wall of the hollow portion 12 is formed by the adhesive layer 10, but the sacrificial layer can be easily removed by etching by using a resin for the adhesive layer 10.

### <Formation of Sealing Member 13>

The sealing member 13 may be or may not be formed.

When the sealing member 13 is formed, the through-hole 11 is closed and sealed with the sealing member 13 as illustrated in FIG. 32D.

As the material of the sealing member 13, for example, an ultraviolet curable resin, a heat curable resin, or a combination of these curing reaction mechanism combined type sealing resin is used. Examples of such resins include epoxy-based, acrylic-based, silicone-based resins, and modified resins thereof.

For example, the solid-state imaging element 1 according to the first mode can be manufactured by the first manufacturing method.

(Second Manufacturing Method)

A second manufacturing method will be described with reference to the accompanying drawings.

### <Formation of Transparent Substrate 3>

A second example of a method of forming the transparent substrate 3 will be described.

Unlike the first example, in the second example, the through-holes 11 are formed after the sacrificial layer is formed.

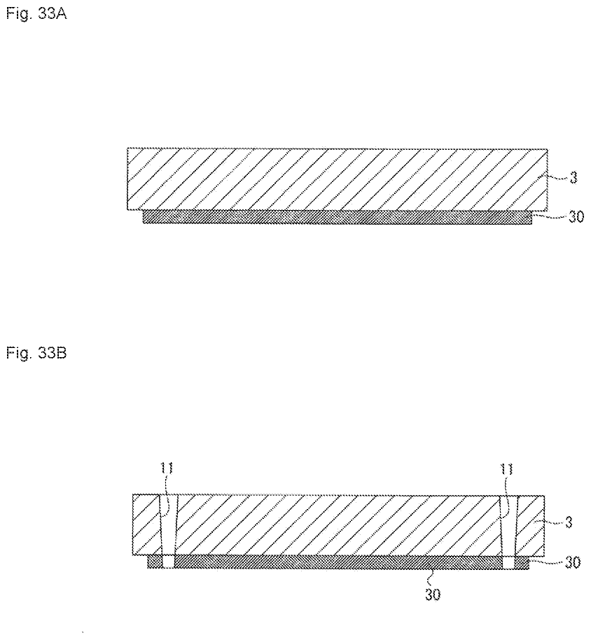

That is, in the second example, first, the sacrificial layer is formed on the lower surface of the transparent substrate 3 before the through-holes 11 are formed, as illustrated in FIG. 33A. The sacrificial layer is formed in a region including a position capable of facing the entire effective pixel region ARA1 and the lower surface of the transparent substrate 3 in which the through-holes 11 are formed. However, the sacrificial layer is formed such that a portion provided with the adhesive layer 10 remains at the position of the entire circumference on the outer circumference side of the sacrificial layer on the lower surface of the transparent substrate 3.

The sacrificial layer is formed, for example, by first performing film formation on the lower surface of the transparent substrate 3 using polycrystalline silicon, amorphous silicon, silicon nitride, or the like by a CVD method or the like. Alternatively, a silicon substrate is attached onto the lower surface of the transparent substrate 3 by using anodic bonding or the like. Thereafter, unnecessary portions of the formed sacrificial layer are removed by etching to form the sacrificial layer. The unnecessary portion is a portion provided with the adhesive layer 10 on the outer circumferential side of the position which is the bottom of the through-hole 11.

Examples of the material of the silicon substrate include monocrystalline silicon, polycrystalline silicon, amorphous silicon, a silicon nitride film, and the like.

Next, processing for forming the through-holes 11 from above in the thickness direction is performed on the transparent substrate 3 having the sacrificial layer formed thereon, as illustrated in FIG. 33B. As described above, the through-hole 11 is formed at a position facing the outer circumferential region ARA2 and is opened in the thickness direction of the transparent substrate 3. At this time, the through-holes 11 are opened to penetrate the sacrificial layer as well, as illustrated in FIG. 33B.

The cross-sectional shape of the opening of the through-hole 11 and the number of the through-holes 11 are not particularly limited.

The processing for forming the through-holes 11 is executed by, for example, dry etching, wet etching, laser processing, or the like.

### <Formation of Flattening Film 9>

The flattening film 9 is formed on the upper surface of the substrate 2 having the element formed thereon. The flattening film 9 may be formed before, after, or at the same time as the transparent substrate 3 is formed.

### <Attachment of Transparent Substrate 3>

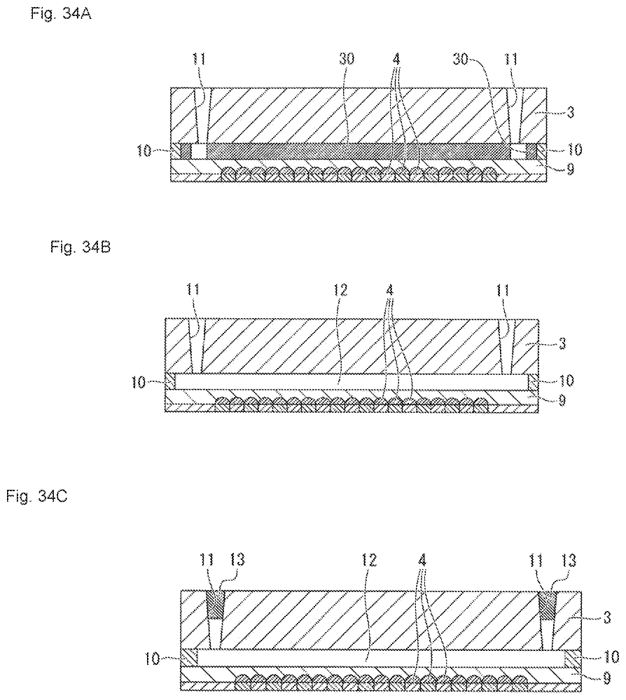

As illustrated in FIG. 34A, the transparent substrate 3 formed as described above is attached and laminated on the flattening film 9. Regarding the attachment of the transparent substrate 3, the adhesive layer 10 is formed in the outer circumferential portion of the sacrificial layer, and the transparent substrate 3 is attached onto the flattening film 9 by the adhesive layer 10. Note that the adhesive layer 10 may be formed on the upper side of the flattening film 9 and subjected to attachment processing, or may be formed on the transparent substrate 3 side and subjected to attachment processing. Thereby, the adhesive layer 10 is disposed along the entire circumference of the sacrificial layer in the outer circumferential direction.

As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 34B. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13 as illustrated in FIG. 34C.

For example, the solid-state imaging element 1 according to the first mode can be manufactured by the second manufacturing method.

(Third Manufacturing Method)

A third manufacturing method will be described with reference to the accompanying drawings.

### <Formation of Transparent Substrate 3>

A third example of a method of forming the transparent substrate 3 will be described.

Similarly to the second example, in the third example, the through-holes 11 are formed after the sacrificial layer is formed. Further, in the third example, the spacer 14 is formed at the lower end of the transparent substrate 3.

That is, in the third example, first, the sacrificial layer is formed on the lower surface of the transparent substrate 3 before the through-holes 11 are formed, as illustrated in FIG. 35A. The sacrificial layer is formed in a region including a position capable of facing the entire effective pixel region ARA1, the lower surface of the transparent substrate 3 in which the through-holes 11 are formed, and a portion of the part in which the adhesive layer 10 is formed. In the third example, a portion 14 of the sacrificial layer formed in the outer circumferential region ARA2 provided with the adhesive layer 10 is formed such that a portion (a portion which is the spacer 14) provided with the adhesive layer 10 remains on the inner and outer circumferential sides thereof. The portion of the sacrificial layer on the outer circumferential side may be formed along the entire circumference in the circumferential direction along the outer circumferential region ARA2, may be formed on both right and left side portions, or may be intermittently formed along the circumferential direction.

The sacrificial layer is formed, for example, by first attaching a silicon substrate to the lower surface of the transparent substrate 3 using anodic bonding or the like. Thereafter, unnecessary portions in the formed sacrificial layer are removed by etching to form the sacrificial layer. The unnecessary portion is a portion provided with the adhesive layer 10 on the outer circumferential side of the position which is the bottom of the through-hole 11.

Examples of the material of the silicon substrate include monocrystalline silicon, polycrystalline silicon, amorphous silicon, a silicon nitride film, and the like.

Next, processing for forming the through-holes 11 in the thickness direction is performed on the transparent substrate 3 having the sacrificial layer formed thereon, as illustrated in FIG. 35B. As described above, the through-hole 11 is formed at a position capable of facing the outer circumferential region ARA2 and is opened in the thickness direction of the transparent substrate 3. At this time, the through-holes 11 are opened to penetrate the sacrificial layer as well.

The cross-sectional shape of the opening of the through-hole 11 and the number of the through-holes 11 are not particularly limited.

The processing for forming the through-holes 11 is executed by, for example, dry etching, wet etching, laser processing, or the like.

In the third example, a portion between the formed through-hole 11 and the portion 14 of the sacrificial layer positioned on the outer circumferential side thereof is exposed on the lower surface of the transparent substrate 3.

### <Formation of Flattening Film 9>

The flattening film 9 may be formed before, after, or at the same time as the transparent substrate 3 is formed.

The flattening film 9 is formed on the upper surface (a mesh on the light incidence surface side) of the substrate 2 having the element formed thereon so as to completely cover the on-chip lens 4.

### <Attachment of Transparent Substrate 3>

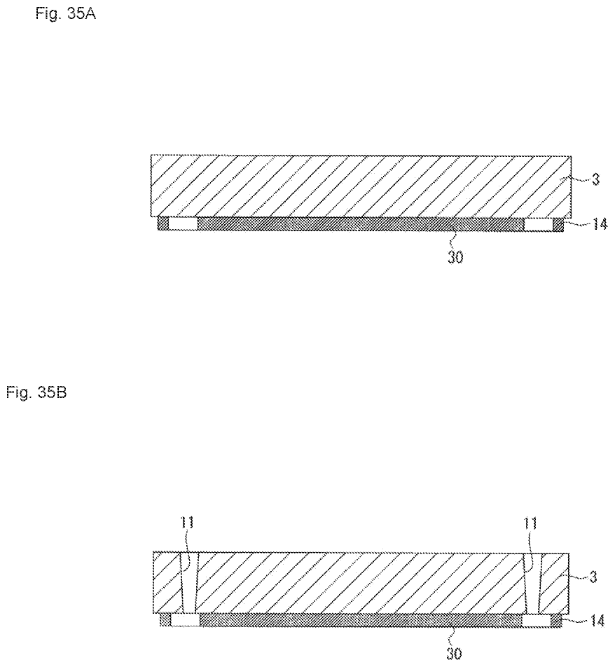

As illustrated in FIG. 36A, the transparent substrate 3 formed as described above is attached and laminated on the flattening film 9. Regarding the attachment of the transparent substrate 3, the adhesive layer 10 is formed in the outer circumferential portion of the sacrificial layer, and the transparent substrate 3 is attached onto the flattening film 9 by the adhesive layer 10. Note that the adhesive layer 10 may be formed on the upper side of the flattening film 9 and subjected to attachment processing, or may be formed on the transparent substrate 3 side and subjected to attachment processing. Thereby, the adhesive layer 10 is disposed along the entire circumference of the sacrificial layer in the outer circumferential direction.

As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

At this time, the portion 14 of the sacrificial layer which is positioned on the outer circumferential side is embedded in the adhesive layer 10 to configure the spacer 14. In addition, the adhesive layer 10 is present at a position on the inner circumferential side of the portion 14 of the sacrificial layer which is positioned on the outer circumferential side and on the outer circumferential side of the position of the bottom of the through-hole 11.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 36B. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 36C.

For example, the solid-state imaging element 1 according to the second mode can be manufactured by the third manufacturing method.

(Fourth Manufacturing Method)

A fourth manufacturing method will be described with reference to the accompanying drawings.

### <Formation of Transparent Substrate 3>

A fourth example of a method of forming the transparent substrate 3 will be described.

Similarly to the second example, in the fourth example, the through-holes 11 are formed after the sacrificial layer is formed. Further, in the fourth example, the spacer 14 is formed at the lower end of the transparent substrate 3.

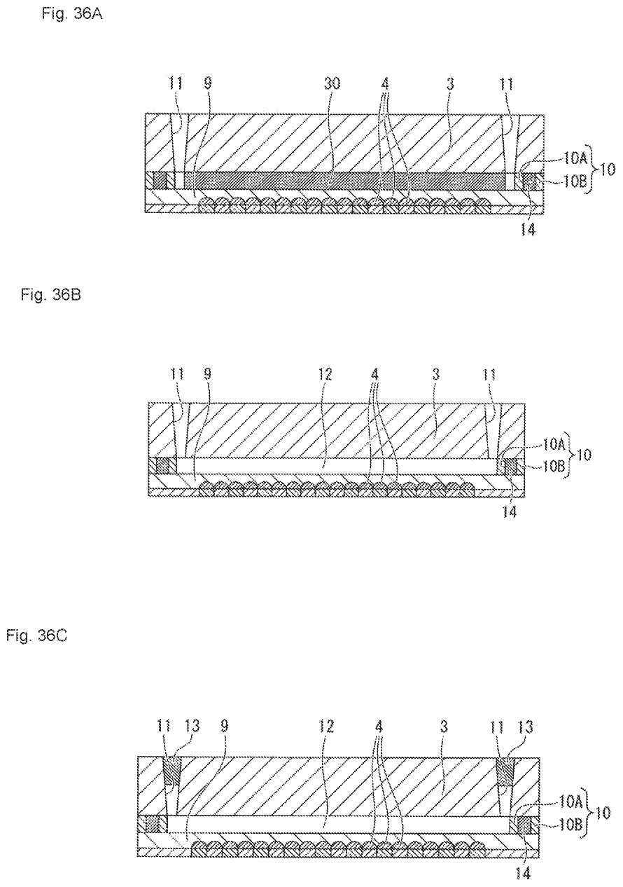

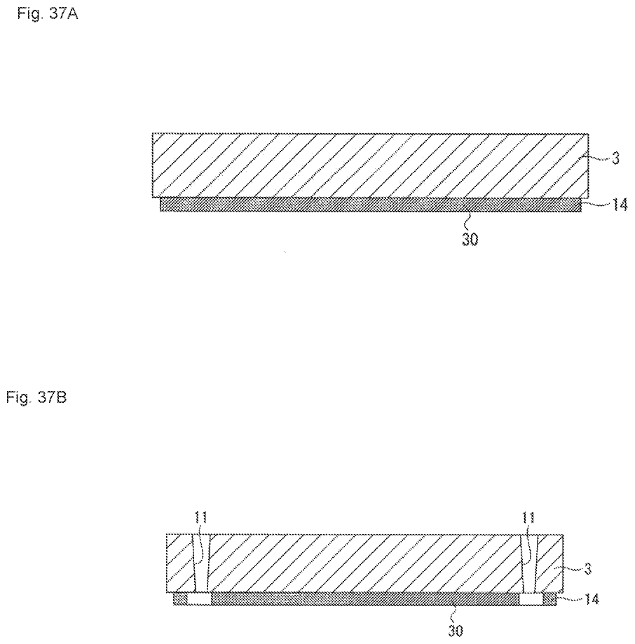

That is, in the fourth example, first, the sacrificial layer is formed on the lower surface of the transparent substrate 3 before the through-holes 11 are formed, as illustrated in FIG. 37A. The sacrificial layer is formed in a region including a position capable of facing the entire effective pixel region ARA1, the lower surface of the transparent substrate 3 in which the through-holes 11 are formed, and a portion of the part in which the adhesive layer 10 is formed. In the fourth example, a portion (a portion serving as the spacer 14) of the sacrificial layer formed in the outer circumferential region ARA2 provided with the adhesive layer 10 is formed such that a portion provided with the adhesive layer 10 remains on the inner and outer circumferential sides thereof. The portion of the sacrificial layer on the outer circumferential side may be formed along the entire circumference in the circumferential direction along the outer circumferential region ARA2, may be formed on both right and left side portions, or may be intermittently formed along the circumferential direction.

The sacrificial layer is formed, for example, by first performing film formation on the lower surface of the transparent substrate 3 using polycrystalline silicon, amorphous silicon, silicon nitride, or the like by a CVD method or the like.

Thereafter, unnecessary portions of the formed sacrificial layer are removed by etching to form the sacrificial layer. The unnecessary portion is a portion provided with the adhesive layer 10 on the outer circumferential side of the position which is the bottom of the through-hole 11.

Next, processing for forming the through-holes 11 in the thickness direction is performed on the transparent substrate 3 having the sacrificial layer formed thereon, as illustrated in FIG. 37. As described above, the through-hole 11 is formed at a position facing the outer circumferential region ARA2 and is opened in the thickness direction of the transparent substrate 3. At this time, the through-holes 11 are opened to penetrate the sacrificial layer as well.

The cross-sectional shape of the opening of the through-hole 11 and the number of the through-holes 11 are not particularly limited.

The processing for forming the through-holes 11 is executed by, for example, dry etching, wet etching, laser processing, or the like.

In the fourth example, a portion between the formed through-hole 11 and the sacrificial layer positioned on the outer circumferential side is exposed on the lower surface of the transparent substrate 3.

### <Formation of Flattening Film 9>

The flattening film 9 may be formed before, after, or at the same time as the transparent substrate 3 is formed.

The flattening film 9 is formed on the upper surface (a mesh on the light incidence surface side) of the substrate 2 having the element formed thereon so as to completely cover the on-chip lens 4.

### <Attachment of Transparent Substrate 3>

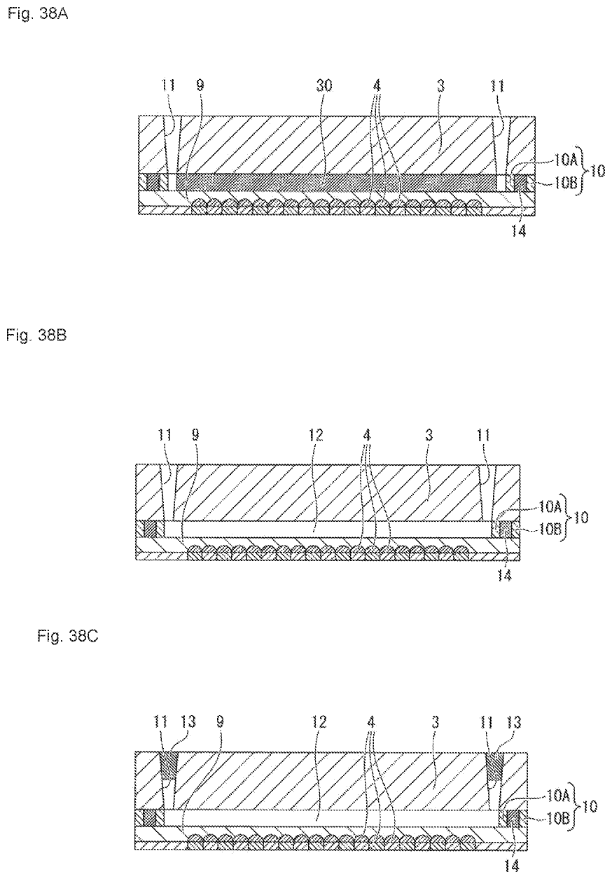

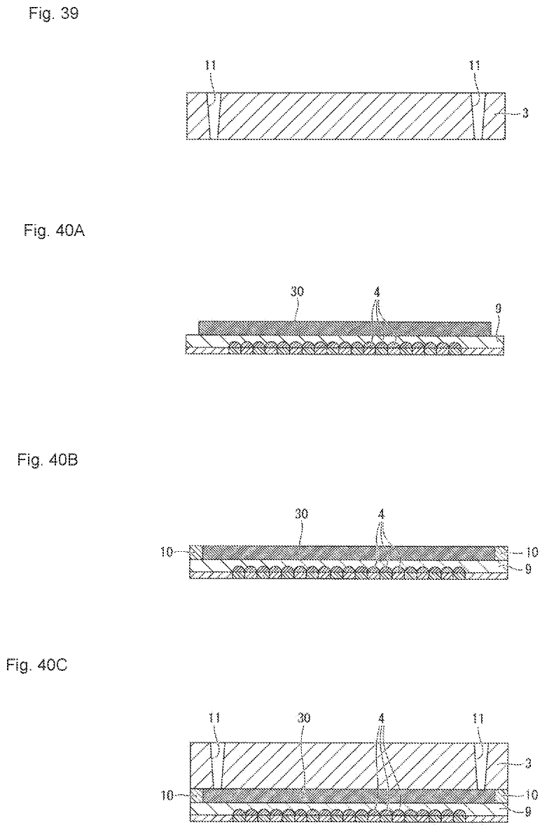

As illustrated in FIG. 38A, the transparent substrate 3 formed as described above is attached and laminated on the flattening film 9. Regarding the attachment of the transparent substrate 3, the adhesive layer 10 is formed in the outer circumferential portion of the sacrificial layer, and the transparent substrate 3 is attached onto the flattening film 9 by the adhesive layer 10. Note that the adhesive layer 10 may be formed on the upper side of the flattening film 9 and subjected to attachment processing, or may be formed on the transparent substrate 3 side and subjected to attachment processing. Thereby, the adhesive layer 10 is disposed along the entire circumference of the sacrificial layer in the outer circumferential direction.

As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

At this time, the portion of the sacrificial layer which is positioned on the outer circumferential side is embedded in the adhesive layer 10 to configure the spacer 14. In addition, the adhesive layer 10 is present at a position on the inner circumferential side of the portion of the sacrificial layer which is positioned on the outer circumferential side and on the outer circumferential side of the position of the bottom of the through-hole 11.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 38B. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 38C.

For example, the solid-state imaging element 1 according to the second mode can be manufactured by the fourth manufacturing method.

(Fifth Manufacturing Method)

A fifth manufacturing method will be described with reference to the accompanying drawings.

### <Formation of Transparent Substrate 3>

A fifth example of a method of forming the transparent substrate 3 will be described.

In the fifth example, the through-holes 11 are formed in the transparent substrate 3, but a sacrificial layer is not formed.

That is, in the fifth example, processing for forming the through-holes 11 in the thickness direction is performed as illustrated in FIG. 39. As described above, the through-hole 11 is formed at a position facing the outer circumferential region ARA2 and is opened in the thickness direction of the transparent substrate 3.

The cross-sectional shape of the opening of the through-hole 11 and the number of the through-holes 11 are not particularly limited.

The processing for forming the through-holes 11 is executed by, for example, dry etching, wet etching, laser processing, or the like.

### <Formation of Flattening Film 9>

The flattening film 9 may be formed before, after, or at the same time as the transparent substrate 3 is formed.

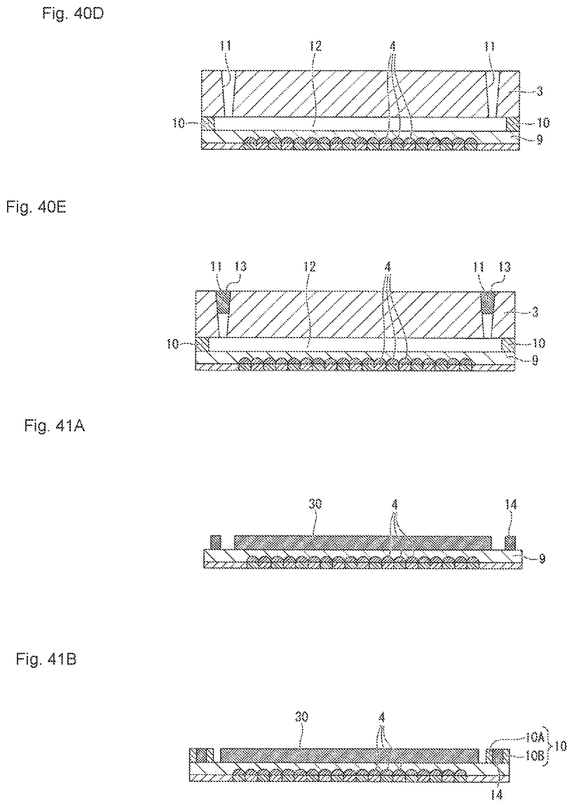

As illustrated in FIG. 40A, the flattening film 9 is formed on the upper surface (a mesh on the light incidence surface side) of the substrate 2 having the element formed thereon so as to completely cover the on-chip lens 4.

### <Formation of Sacrificial Layer>

The sacrificial layer is formed on the flattening film 9 as illustrated in FIG. 40A.

The sacrificial layer is formed in a region including the entire effective pixel region ARA1 and a position capable of facing the bottom of the through-hole 11. However, the sacrificial layer is formed such that a portion provided with the adhesive layer 10 remains at the position of the entire circumference on the outer circumference side of the sacrificial layer.

The sacrificial layer is formed, for example, by first performing film formation on the lower surface of the transparent substrate 3 using polycrystalline silicon, amorphous silicon, silicon nitride, or the like by a CVD method or the like. Alternatively, a silicon substrate is attached onto the lower surface of the transparent substrate 3 by using anodic bonding or the like. Thereafter, unnecessary portions of the formed sacrificial layer are removed by etching to form the sacrificial layer. The unnecessary portion is a portion provided with the adhesive layer 10 on the outer circumferential side of the position facing the bottom of the through-hole 11.

Examples of the material of the silicon substrate include monocrystalline silicon, polycrystalline silicon, amorphous silicon, a silicon nitride film, and the like.

### <Formation of Adhesive Layer 10>

As illustrated in FIG. 40B, the adhesive layer 10 is formed on the entire outer circumference of the sacrificial layer on the upper surface of the flattening film 9. In FIG. 40B, the adhesive layer 10 is formed to be higher than the sacrificial layer to earn a crushing margin.

As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Attachment of Transparent Substrate 3>

Next, as illustrated in FIG. 40C, the transparent substrate 3 formed as described above is laminated and attached onto the sacrificial layer and the adhesive layer 10.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 40D. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 40E.

For example, the solid-state imaging element 1 according to the third mode can be manufactured by the fifth manufacturing method.

(Sixth Manufacturing Method)

A sixth manufacturing method will be described with reference to the accompanying drawings.

### <Formation of Transparent Substrate 3>

Since a method of forming the transparent substrate 3 in the present example is the same as that in the fifth example, the description thereof will be omitted (see FIG. 39).

### <Formation of Flattening Film 9>

The flattening film 9 may be formed before, after, or at the same time as the transparent substrate 3 is formed.

The flattening film 9 is formed on the upper surface (a mesh on the light incidence surface side) of the substrate 2 having the element formed thereon so as to completely cover the on-chip lens 4.

### <Formation of Sacrificial Layer>

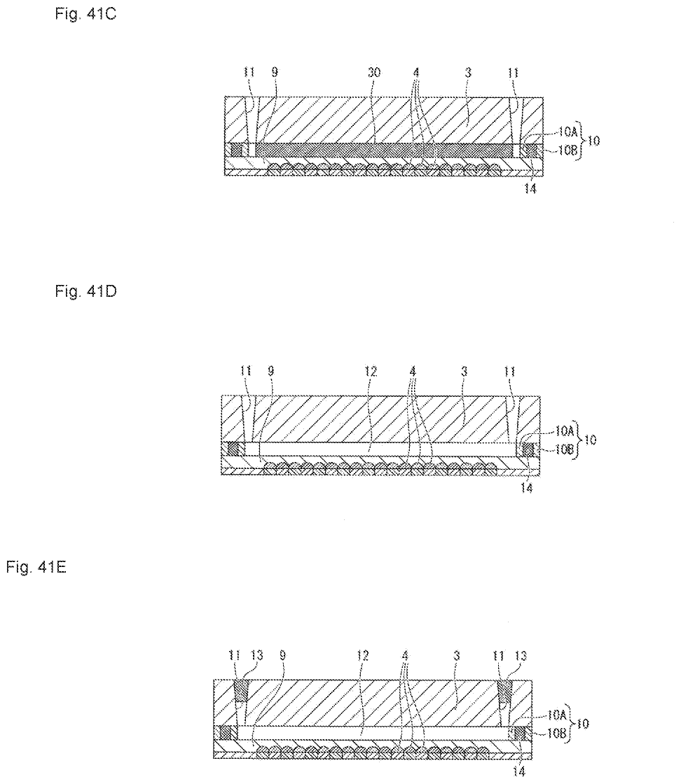

The sacrificial layer is formed on the flattening film 9 as illustrated in FIG. 41A. The sacrificial layer is formed in a region including the entire effective pixel region ARA1, a position capable of facing the bottom of the through-hole 11, and a portion of the part in which the adhesive layer 10 is formed. A portion 14 of the sacrificial layer formed in the outer circumferential region ARA2 provided with the adhesive layer 10 is formed such that a portion provided with the adhesive layer 10 remains on the inner and outer circumferential sides thereof. The portion of the sacrificial layer on the outer circumferential side may be formed along the entire circumference in the circumferential direction along the outer circumferential region ARA2, may be formed on both right and left side portions, or may be intermittently formed along the circumferential direction.

The sacrificial layer is formed, for example, by first performing film formation on the lower surface of the transparent substrate 3 using polycrystalline silicon, amorphous silicon, silicon nitride, or the like by a CVD method or the like. Alternatively, a silicon substrate is attached to the lower surface of the transparent substrate 3 using anodic bonding or the like. Thereafter, unnecessary portions of the formed sacrificial layer are removed by etching to form the sacrificial layer. The unnecessary portion is a portion provided with the adhesive layer 10 on the outer circumferential side of the position facing the bottom of the through-hole 11.

Examples of the material of the silicon substrate include monocrystalline silicon, polycrystalline silicon, amorphous silicon, a silicon nitride film, and the like.

### <Formation of Adhesive Layer 10>

As illustrated in FIG. 41B, the adhesive layer 10 is formed on the entire outer circumference of the sacrificial layer on the upper surface of the flattening film 9.

At this time, the portion of the sacrificial layer which is positioned on the outer circumferential side is embedded in the adhesive layer 10 to configure the spacer 14. In addition, an adhesive layer 10A is present at a position on the inner circumferential side of the portion of the sacrificial layer which is positioned on the outer circumferential side and on the outer circumferential side of a position capable of facing the position of the bottom of the through-hole 11. Further, an adhesive layer 10B is also present on the outer circumferential side of the portion of the sacrificial layer portion.

As the material of the adhesive layer 10, for example, an ultraviolet curable type, heat curable type, or curing reaction mechanism combined type sealing resin may be used. Examples of the sealing resin include epoxy-based, acrylic-based, silicone-based sealing resins, or modified resins thereof.

### <Attachment of Transparent Substrate 3>

Next, as illustrated in FIG. 41C, the transparent substrate 3 formed as described above is laminated and attached onto the sacrificial layer and the adhesive layer 10.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 41D. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 41E.

For example, the solid-state imaging element 1 according to the fourth mode can be manufactured by the sixth manufacturing method.

(Seventh Manufacturing Method)

A seventh manufacturing method will be described with reference to the accompanying drawings.

### <Formation of Transparent Substrate 3>

Since a method of forming the transparent substrate 3 is the same as that in the fifth example, the description thereof will be omitted (see FIG. 39).

### <Formation of Flattening Film 9>

The flattening film 9 may be formed before, after, or at the same time as the transparent substrate 3 is formed.

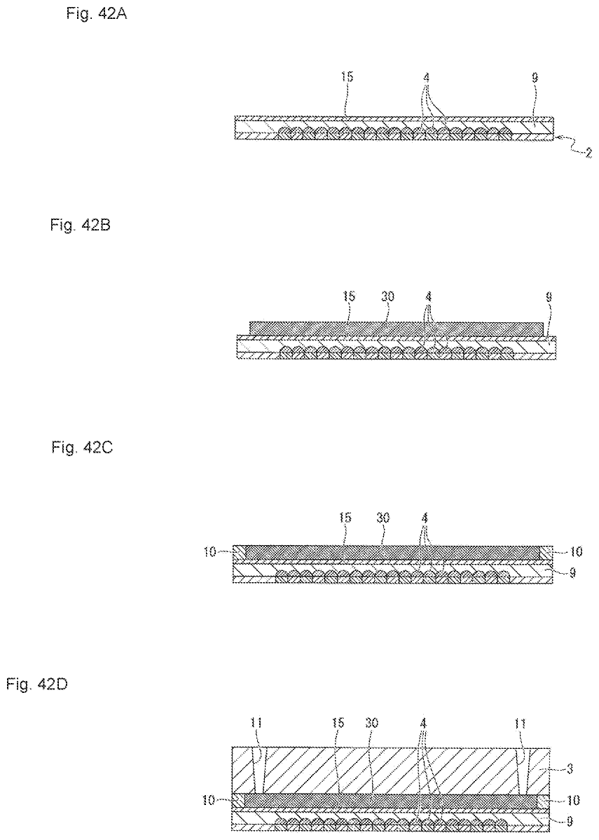

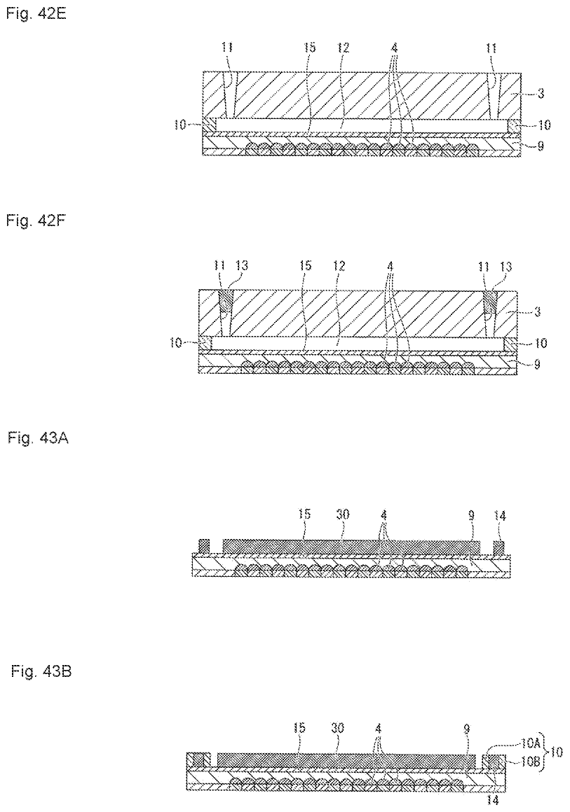

As illustrated in FIG. 42A, the flattening film 9 is formed on the upper surface (a mesh on the light incidence surface side) of the substrate 2 having the element formed thereon so as to completely cover the on-chip lens 4.

### <Formation of Adhesive Layer 15>

In addition, as illustrated in FIG. 42A, the adhesive layer 15 is formed on the flattening film 9. It is preferable that the adhesive layer 15 be formed of a resin material having a refractive index lower than the refractive index of the flattening film 9.

In the present mode, the adhesive layer 15 is formed using a resin adhesive. As the resin adhesive, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Formation of Sacrificial Layer>

The sacrificial layer is formed on the adhesive layer 15 as illustrated in FIG. 42B. The sacrificial layer is formed in a region including the entire effective pixel region ARA1 and a position capable of facing the bottom of the through-hole 11. However, the sacrificial layer is formed such that a portion provided with the adhesive layer 10 remains at the position of the entire circumference on the outer circumference side of the sacrificial layer.

The sacrificial layer is formed, for example, by first performing film formation on the lower surface of the transparent substrate 3 using polycrystalline silicon, amorphous silicon, silicon nitride, or the like by a CVD method or the like.

Alternatively, a silicon substrate is attached onto the lower surface of the transparent substrate 3 by using anodic bonding or the like. Thereafter, unnecessary portions of the formed sacrificial layer are removed by etching to form the sacrificial layer. The unnecessary portion is a portion provided with the adhesive layer 10 on the outer circumferential side of the position facing the bottom of the through-hole 11.

Examples of the material of the silicon substrate include monocrystalline silicon, polycrystalline silicon, amorphous silicon, a silicon nitride film, and the like.

### <Formation of Adhesive Layer 10>

As illustrated in FIG. 42C, the adhesive layer 10 is formed on the entire outer circumference of the sacrificial layer on the upper surface of the adhesive layer 15. As the material of the adhesive layer 10, for example, an ultraviolet curable type, heat curable type, or curing reaction mechanism combined type sealing resin may be used. Examples of the sealing resin include epoxy-based, acrylic-based, silicone-based sealing resins, or modified resins thereof.

### <Attachment of Transparent Substrate 3>

Next, as illustrated in FIG. 42D, the transparent substrate 3 formed as described above is laminated and attached onto the sacrificial layer and the adhesive layer 10.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 42E. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 42F.

For example, the solid-state imaging element 1 according to the third mode can be manufactured by the seventh manufacturing method.

(Eighth Manufacturing Method)

An eighth manufacturing method will be described with reference to the accompanying drawings.

### <Formation of Transparent Substrate 3>

Since a method of forming the transparent substrate 3 in the present example is the same as that in the fifth example, the description thereof will be omitted (see FIG. 39).

### <Formation of Flattening Film 9>

The flattening film 9 may be formed before, after, or at the same time as the transparent substrate 3 is formed.

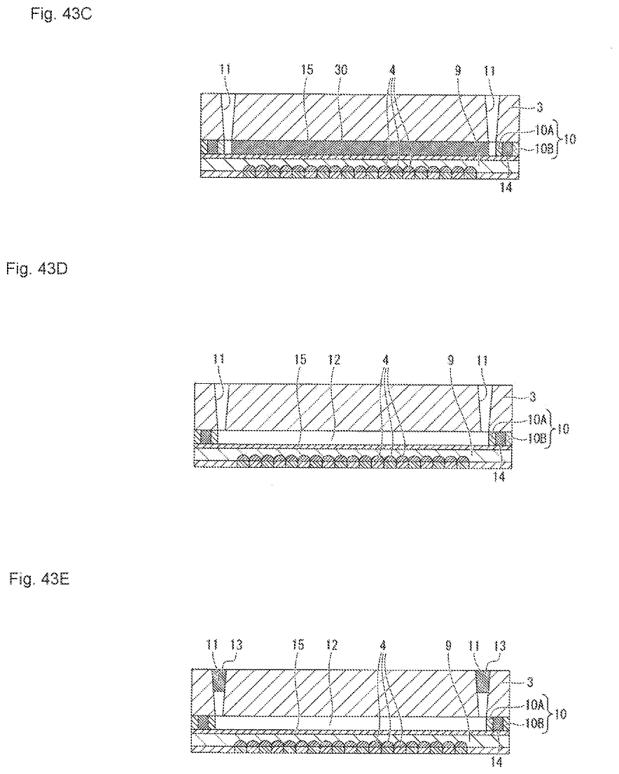

As illustrated in FIG. 43A, the flattening film 9 is formed on the upper surface (a mesh on the light incidence surface side) of the substrate 2 having the element formed thereon so as to completely cover the on-chip lens 4.

### <Formation of Adhesive Layer 15>

In addition, as illustrated in FIG. 43A, the adhesive layer 15 is formed on the flattening film 9. It is preferable that the adhesive layer 15 be formed of a resin material having a refractive index lower than the refractive index of the flattening film 9.

In the present mode, the adhesive layer 15 is formed using a resin adhesive. As the adhesive, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Formation of Sacrificial Layer>

The sacrificial layer is formed on the adhesive layer 15 as illustrated in FIG. 42A.

The sacrificial layer is formed in a region including the entire effective pixel region ARA1, a position capable of facing the bottom of the through-hole 11, and a portion of the part in which the adhesive layer 10 is formed. A portion of the sacrificial layer formed in the outer circumferential region ARA2 provided with the adhesive layer 10 is formed such that a portion provided with the adhesive layer 10 remains on the inner and outer circumferential sides thereof. The portion of the sacrificial layer on the outer circumferential side may be formed along the entire circumference in the circumferential direction along the outer circumferential region ARA2, may be formed on both right and left side portions, or may be intermittently formed along the circumferential direction.

The sacrificial layer is formed, for example, by first performing film formation on the lower surface of the transparent substrate 3 using polycrystalline silicon, amorphous silicon, silicon nitride, or the like by a CVD method or the like. Alternatively, a silicon substrate is attached to the lower surface of the transparent substrate 3 using anodic bonding or the like. Thereafter, unnecessary portions of the formed sacrificial layer are removed by etching to form the sacrificial layer. The unnecessary portion is a portion provided with the adhesive layer 10 on the outer circumferential side of the position facing the bottom of the through-hole 11.

Examples of the material of the silicon substrate include monocrystalline silicon, polycrystalline silicon, amorphous silicon, a silicon nitride film, and the like.

### <Formation of Adhesive Layer 10>

As illustrated in FIG. 42B, the adhesive layer 10 is formed on the entire outer circumference of the sacrificial layer on the upper surface of the flattening film 9.

At this time, the portion of the sacrificial layer which is positioned on the outer circumferential side is embedded in the adhesive layer 10 to configure the spacer 14. Then, the adhesive layer 10A is present at a position on the inner circumferential side of the portion of the sacrificial layer which is positioned on the outer circumferential side and on the outer circumferential side of a position capable of facing the position of the bottom of the through-hole 11. Further, an adhesive layer 10B is also present on the outer circumferential side of the portion of the sacrificial layer portion.

As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Attachment of Transparent Substrate 3>

Next, as illustrated in FIG. 43C, the transparent substrate 3 formed as described above is laminated and attached onto the sacrificial layer and the adhesive layer 10.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 43D. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 43E.

For example, the solid-state imaging element 1 according to the fourth mode can be manufactured by the eighth manufacturing method.

(Ninth Manufacturing Method)

A ninth manufacturing method will be described with reference to the accompanying drawings.

### <Formation of Transparent Substrate 3>

A sixth example of a method of forming the transparent substrate 3 will be described.

The transparent substrate 3 in the present example is configured by laminating a plurality of glass substrates.

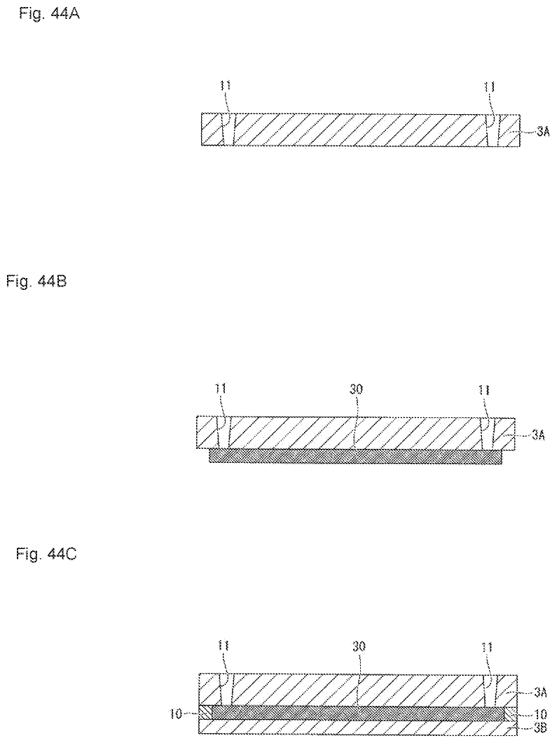

In the present example, as illustrated in FIG. 44C, a case where the transparent substrate 3 is configured by laminating two glass substrates, that is, an upper glass substrate 3A and a lower glass substrate 3B will be described.

In the sixth example, first, processing for forming the through-holes 11 in the thickness direction is performed on the upper glass substrate 3A, as illustrated in FIG. 44A. As described above, the through-hole 11 is formed at a position facing the outer circumferential region ARA2 and is opened in the thickness direction of the transparent substrate 3. The cross-sectional shape of the opening of the through-hole 11 and the number of the through-holes 11 are not particularly limited.

The processing for forming the through-holes 11 is executed by, for example, dry etching, wet etching, laser processing, or the like.

Next, as illustrated in FIG. 44B, the sacrificial layer is formed on the lower surface of the transparent substrate 3 in which the through-holes 11 are formed. The sacrificial layer is formed in a region including a position capable of facing the entire effective pixel region ARA1 and the lower surface of the transparent substrate 3 in which the through-holes 11 are formed. However, the sacrificial layer is formed such that a portion provided with the adhesive layer 10 remains at the position of the entire circumference on the outer circumference side of the sacrificial layer on the lower surface of the transparent substrate 3.

The sacrificial layer is formed, for example, by first attaching a silicon substrate to the lower surface of the transparent substrate 3 using anodic bonding or the like. Thereafter, unnecessary portions in the attached silicon substrate are removed by etching to form the sacrificial layer. The unnecessary portion is a portion provided with the adhesive layer 10 on the outer circumferential side of the position facing the bottom of the through-hole 11.

Examples of the material of the sacrificial layer include monocrystalline silicon, polycrystalline silicon, amorphous silicon, a silicon nitride film, and the like.

Next, as illustrated in FIG. 44C, the adhesive layer 10 is formed on the entire outer circumference of the sacrificial layer on the lower surface of the upper glass substrate 3A. As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

Next, as illustrated in FIG. 44C, the lower glass substrate 3B is attached to the lower surface of the upper glass substrate 3A by the adhesive layer 10.

Thereby, the transparent substrate 3 in the sixth example is formed.

### <Formation of Flattening Film 9>

The flattening film 9 may be formed before, after, or at the same time as the transparent substrate 3 is formed.

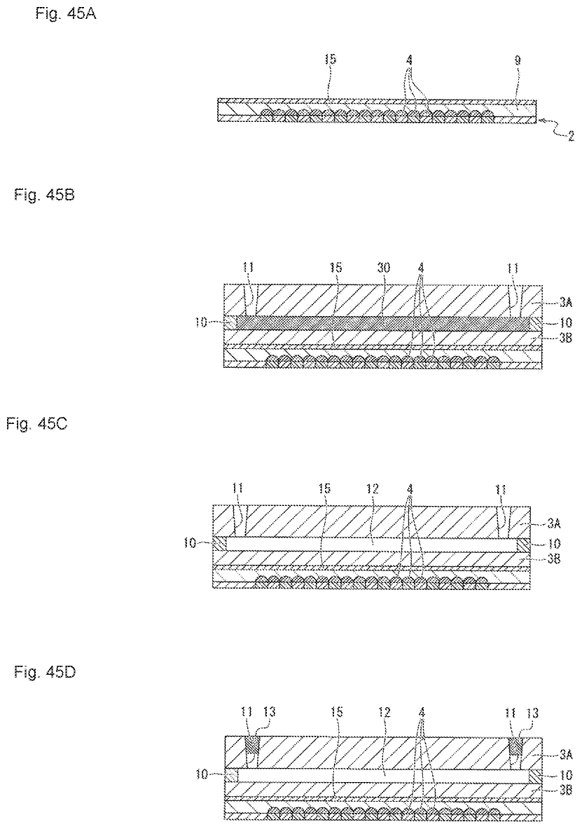

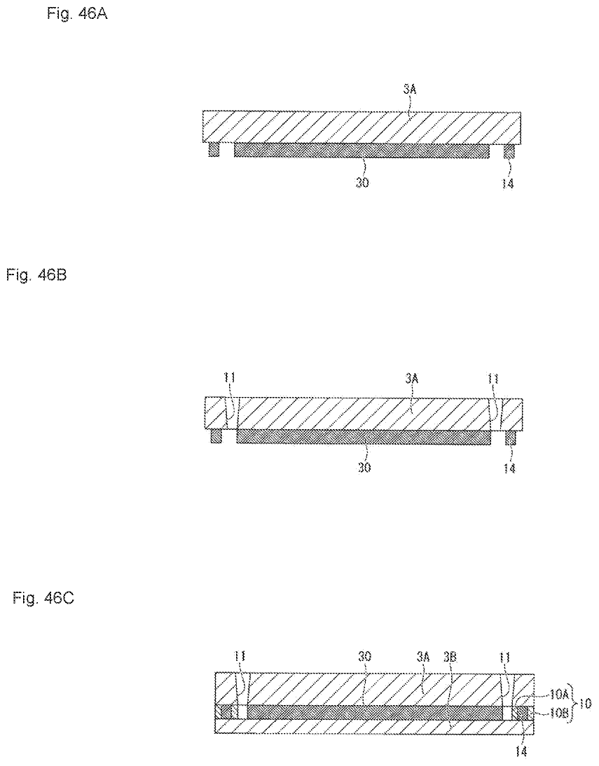

As illustrated in FIG. 45A, the flattening film 9 is formed on the upper surface (a mesh on the light incidence surface side) of the substrate 2 having the element formed thereon so as to completely cover the on-chip lens 4.

### <Formation of Adhesive Layer 15>

In addition, as illustrated in FIG. 45A, the adhesive layer 15 is formed on the flattening film 9. It is preferable that the adhesive layer 15 be formed of a resin material having a refractive index lower than the refractive index of the flattening film 9.

### <Formation of Adhesive Layer 10>

As illustrated in FIG. 45B, the adhesive layer 10 is formed on the flattening film 9. As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

The adhesive layer 10 is formed only in the outer circumferential region ARA2 on the flattening film 9.

### <Attachment of Transparent Substrate 3>

Next, as illustrated in FIG. 45B, the transparent substrate 3 formed as described above is laminated and attached onto the adhesive layer 10.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 45C. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 45D.

For example, the solid-state imaging element 1 according to the fifth mode can be manufactured by the ninth manufacturing method.

(Tenth Manufacturing Method)

A tenth manufacturing method will be described with reference to the accompanying drawings.

### <Formation of Transparent Substrate 3>

A seventh example of a method of forming the transparent substrate 3 will be described.

The transparent substrate 3 in the present example is configured by laminating a plurality of glass substrates, as illustrated in FIG. 46C.

In the present example, a case where the transparent substrate 3 is configured by laminating two glass substrates, that is, an upper glass substrate 3A and a lower glass substrate 3B will be described. Further, in the present manufacturing method, the spacer 14 is provided.

In the seventh example, first, the sacrificial layer is formed on the lower surface of the upper glass substrate 3A before the through-holes 11 are formed, as illustrated in FIG. 46A. The sacrificial layer is formed in a region including a position capable of facing the entire effective pixel region ARA1, the lower surface of the transparent substrate 3 in which the through-holes 11 are formed, and a portion of the part in which the adhesive layer 10 is formed. In the seventh example, a portion 14 of the sacrificial layer formed in the outer circumferential region ARA2 provided with the adhesive layer 10 is formed such that a portion provided with the adhesive layer 10 remains on the inner and outer circumferential sides thereof. The portion of the sacrificial layer on the outer circumferential side may be formed along the entire circumference in the circumferential direction along the outer circumferential region ARA2, may be formed on both right and left side portions, or may be intermittently formed along the circumferential direction.

The sacrificial layer is formed, for example, by first performing film formation on the lower surface of the upper glass substrate 3A using polycrystalline silicon, amorphous silicon, silicon nitride, or the like by a CVD method or the like. Alternatively, a silicon substrate is attached onto the lower surface of the upper glass substrate 3A by using anodic bonding or the like. Thereafter, unnecessary portions of the formed sacrificial layer are removed by etching to form the sacrificial layer. The unnecessary portion is a portion provided with the adhesive layer 10 on the outer circumferential side of the position facing the bottom of the through-hole 11.

Examples of the material of the silicon substrate include monocrystalline silicon, polycrystalline silicon, amorphous silicon, a silicon nitride film, and the like.

Next, processing for forming the through-holes 11 in the thickness direction is performed on the upper glass substrate 3A having the sacrificial layer formed thereon, as illustrated in FIG. 46B. As described above, the through-hole 11 is formed at a position capable of facing the outer circumferential region ARA2 and is opened in the thickness direction of the transparent substrate 3. At this time, the through-holes 11 are opened to penetrate the sacrificial layer as well.

The cross-sectional shape of the opening of the through-hole 11 and the number of the through-holes 11 are not particularly limited.

The processing for forming the through-holes 11 is executed by, for example, dry etching, wet etching, laser processing, or the like.

In the seventh example, a portion between the formed through-hole 11 and the sacrificial layer positioned on the outer circumferential side is exposed on the lower surface of the transparent substrate 3.

As illustrated in FIG. 46C, the adhesive layer 10 is formed on the entire outer circumference of the sacrificial layer on the lower surface of the upper glass substrate 3A.

At this time, the portion of the sacrificial layer which is positioned on the outer circumferential side is embedded in the adhesive layer 10 to configure the spacer 14. Then, the adhesive layer 10 is present at a position on the inner circumferential side of the portion of the sacrificial layer which is positioned on the outer circumferential side and on the outer circumferential side of a position capable of facing the position of the bottom of the through-hole 11. In addition, the adhesive layer 10 is also present on the outer circumferential side of the portion of the sacrificial layer located on the outer circumferential side.

The material of the adhesive layer 10 may be, for example, an ultraviolet curable type, a heat curable type, or a combination of these curing reaction mechanism type sealing resins. Examples of the sealing resin include epoxy-based, acrylic-based, silicone-based sealing resins, or modified resins thereof.

Next, as illustrated in FIG. 46C, the lower glass substrate 3B is attached to the lower surface of the upper glass substrate 3A by the adhesive layer 10.

Thereby, the transparent substrate 3 in the seventh example is formed.

### <Formation of Flattening Film 9>

The flattening film 9 may be formed before, after, or at the same time as the transparent substrate 3 is formed.

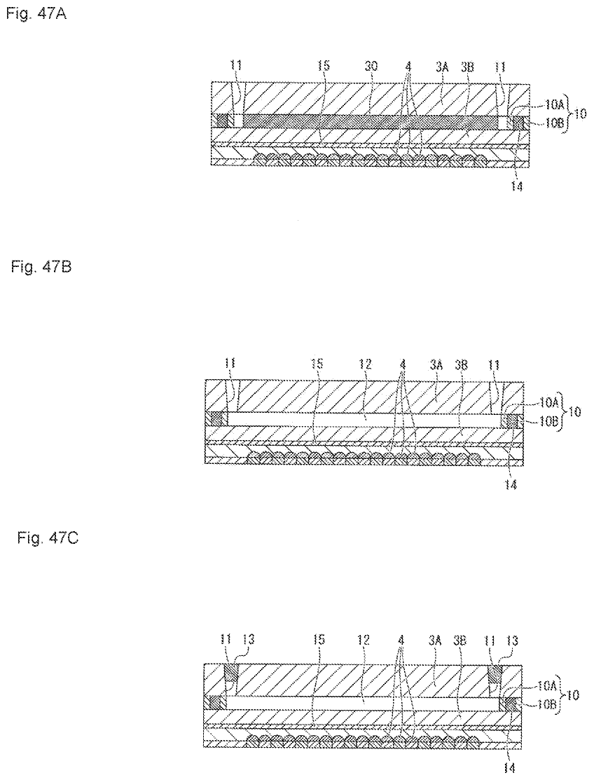

As illustrated in FIG. 47A, the flattening film 9 is formed on the upper surface (a mesh on the light incidence surface side) of the substrate 2 having the element formed thereon so as to completely cover the on-chip lens 4.

### <Formation of Adhesive Layer 15>

In addition, as illustrated in FIG. 47A, the adhesive layer 15 is formed on the flattening film 9. It is preferable that the adhesive layer 15 be formed of a resin material having a refractive index lower than the refractive index of the flattening film 9.

### <Formation of Adhesive Layer 10>

As illustrated in FIG. 47A, the adhesive layer 10 is formed on the flattening film 9. As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

The adhesive layer 10 is formed only in the outer circumferential region ARA2 on the flattening film 9.

### <Attachment of Transparent Substrate 3>

Next, as illustrated in FIG. 47A, the transparent substrate 3 formed as described above is laminated and attached onto the adhesive layer 10. At this time, the spacers 14 are embedded in the adhesive layer 10.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 47B. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing of the transparent substrate 3, the portion of the sacrificial layer which is positioned on the outer circumferential side embedded in the adhesive layer 10 remains without being etched by the sealing resin of the adhesive layer 10 positioned on the inner circumferential side, and becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 47C.

For example, the solid-state imaging element 1 according to the sixth mode can be manufactured by the tenth manufacturing method.

(Eleventh Manufacturing Method)

An eleventh manufacturing method will be described with reference to the accompanying drawings.

### <Formation of Transparent Substrate 3>

Since a method of forming the transparent substrate 3 is the same as the formation method in the first example, the description thereof will be omitted (see FIG. 31C).

### <Formation of Flattening Film 9>

The flattening film 9 may be formed before, after, or at the same time as the transparent substrate 3 is formed.

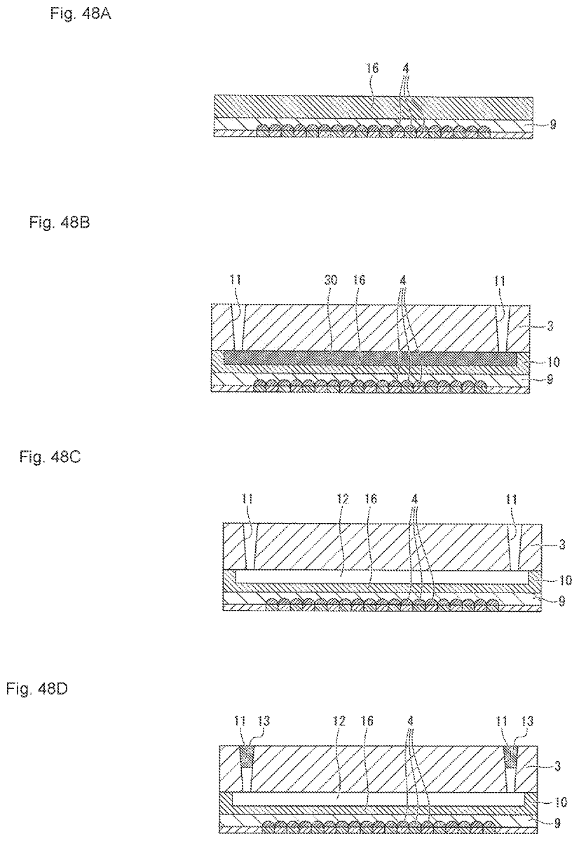

As illustrated in FIG. 48A, the flattening film 9 is formed on the upper surface (a mesh on the light incidence surface side) of the substrate 2 having the element formed thereon so as to completely cover the on-chip lens 4.

### <Formation of Adhesive Layer 10>

As illustrated in FIG. 48A, the adhesive layer 10 is formed on the flattening film 9. As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

The adhesive layer 10 is formed only in the outer circumferential region ARA2 on the flattening film 9.

### <Attachment of Transparent Substrate 3>

Next, as illustrated in FIG. 48B, the transparent substrate 3 formed as described above is laminated and attached onto the adhesive layer 10.

At this time, the sacrificial layer is embedded in the adhesive layer 10, but the portion 10 of the adhesive layer 10 on the outer circumferential side faces the side surface of the sacrificial layer.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 48C. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 48D.

For example, the solid-state imaging element 1 according to the seventh mode can be manufactured by the eleventh manufacturing method.

(Twelfth Manufacturing Method)

A twelfth manufacturing method will be described with reference to the accompanying drawings.

### <Formation of Transparent Substrate 3>

Since a method of forming the transparent substrate 3 is the same as the formation method in the first example, the description thereof will be omitted (see FIG. 31C).

### <Formation of Adhesive Layer 10>

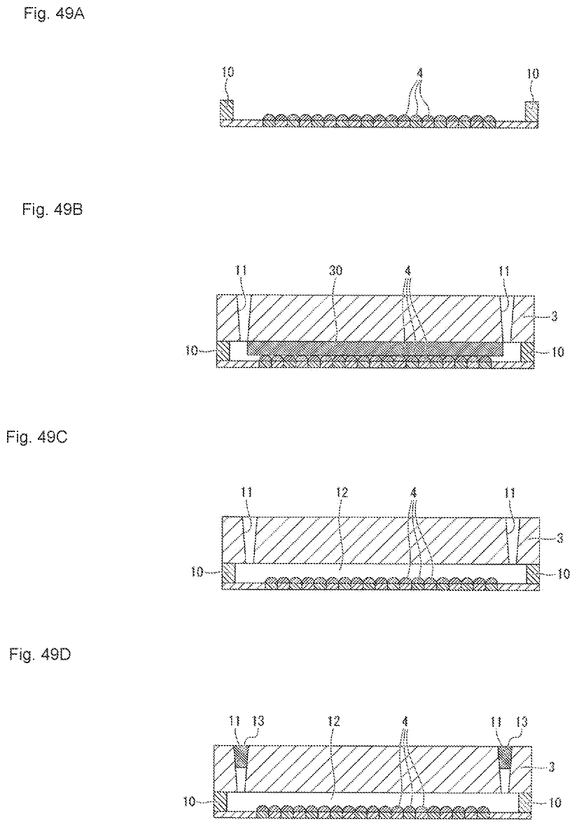

As illustrated in FIG. 49A, the adhesive layer 10 is formed on the upper surface (a mesh on the light incidence surface side) of the substrate 2 having the element formed thereon so as to surround the formation position of the on-chip lens 4 and the outer circumference of the position facing the through-hole 11. As the material of the adhesive layer 10, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Attachment of Transparent Substrate 3>

Next, as illustrated in FIG. 49B, the transparent substrate 3 formed as described above is laminated and attached onto the adhesive layer 10.

At this time, the sacrificial layer is positioned above the on-chip lens 4.

### <Formation of Rewiring>

After the transparent substrate 3 is attached, RDL, solder balls 6, and rewiring processing such as lead wiring are executed on the rear surface side of the substrate 2 having the element formed thereon. In this state, the sacrificial layer is present.

### <Processing for Forming Hollow Portion 12>

After the rewiring processing is terminated, etching is performed on the sacrificial layer through the through-holes 11 to remove the sacrificial layer as illustrated in FIG. 49C. Thereby, a cavity is formed at a position where the sacrificial layer is present. The cavity portion is the hollow portion 12. The hollow portion 12 is constituted by a cavity surrounded by the upper surface of the flattening film 9, the lower surface of the transparent substrate 3, and the inner circumferential surface of the adhesive layer 10.

The etching of the sacrificial layer is executed using, for example, a dry etching method. At this time, XeF₂, ClF₃, BrF₃, and the like can be exemplified as gas species used for dry etching.

In the etching processing, the portion of the sacrificial layer which is positioned on the outer circumferential side embedded in the adhesive layer 10 remains without being etched by the sealing resin of the adhesive layer 10 positioned on the inner circumferential side thereof, and the portion becomes the spacer 14.

### <Formation of Sealing Member 13>

The sealing member 13 may be or may not be formed.

When the sealing member 13 is formed, the through-hole 11 is closed and sealed with the sealing member 13 as illustrated in FIG. 49D.

For example, the solid-state imaging element 1 according to the eighth mode can be manufactured by the twelfth manufacturing method.

(Thirteenth Manufacturing Method)

A thirteenth manufacturing method will be described with reference to the accompanying drawings.

### <Formation of Transparent Substrate 3>

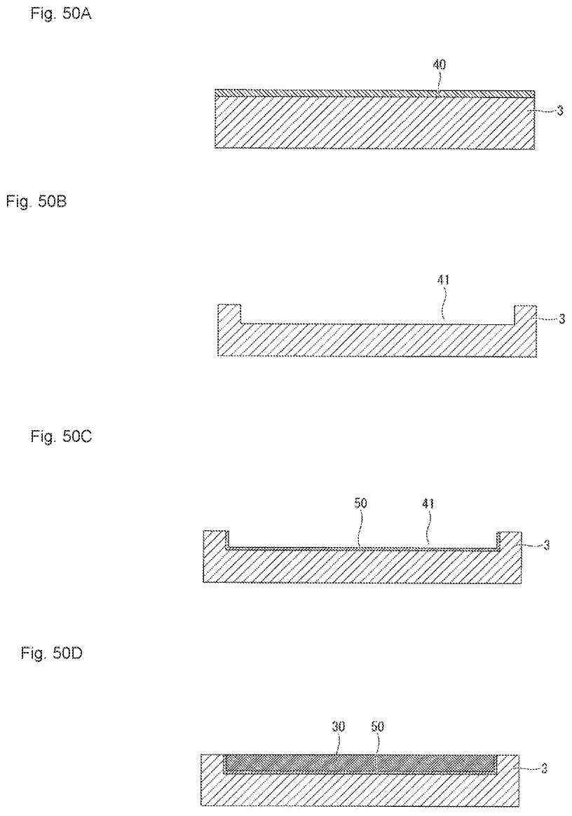

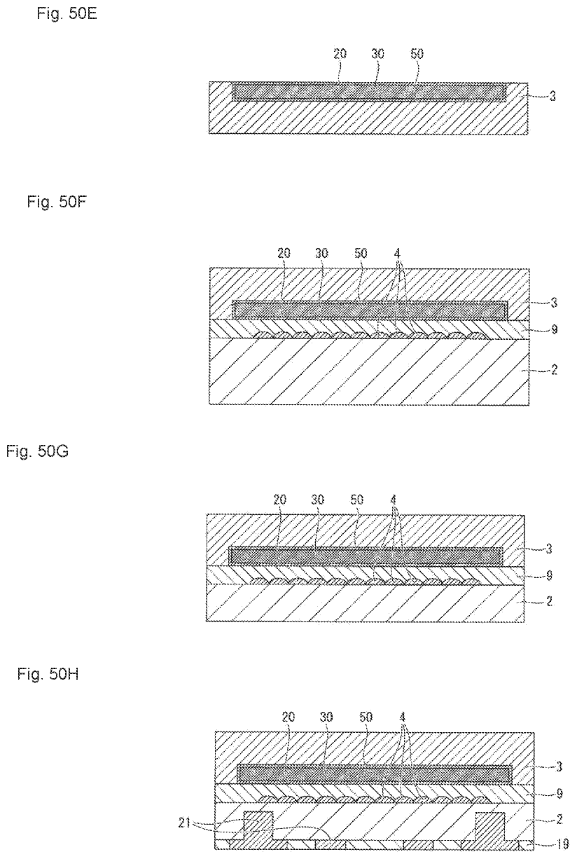

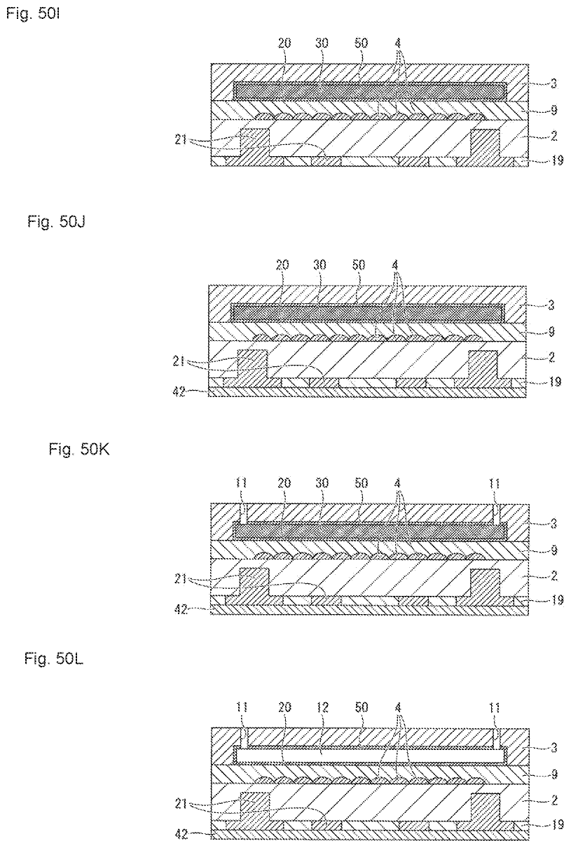

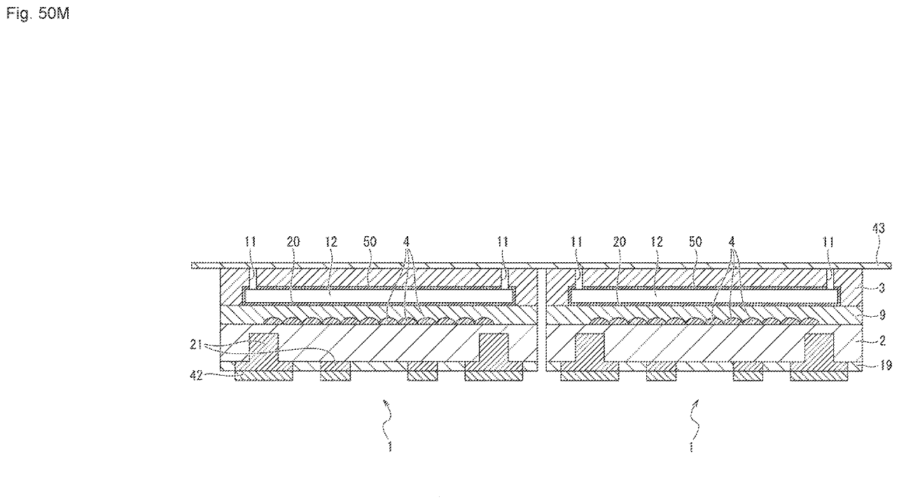

First, a mask 40 is formed on the upper surface of the transparent substrate 3 as illustrated in FIG. 50A.

Next, as illustrated in FIG. 50B, glass etching is performed on the central portion side of the transparent substrate 3 to form the concave portion 41. The glass etching may be wet or dry etching. Etching processing such as sandblasting may also be used. Thereafter, the mask is peeled off.

Next, as illustrated in FIG. 50C, a coating liquid for the low-refraction film 50 is applied into the concave portion 41 to form the low-refraction film 50 on the entire inner surface of the concave portion 41.

Next, as illustrated in FIG. 50D, the sacrificial layer is formed inside the concave portion 41.

The sacrificial layer is formed at a position capable of facing the entire effective pixel region ARA1.

The sacrificial layer is formed, for example, by first performing film formation inside the concave portion 41 using polycrystalline silicon, amorphous silicon, silicon nitride, or the like by a CVD method or the like. Alternatively, a silicon substrate is attached to the inside of the concave portion 41 by using anodic bonding or the like. Examples of the material of the silicon substrate include monocrystalline silicon, polycrystalline silicon, amorphous silicon, a silicon nitride film, and the like.

Next, as illustrated in FIG. 50E, a coating liquid for the low-refraction film 20 is applied onto the upper surface of the formed sacrificial layer to form the low-refraction film 20.

### <Formation of Smoothing Film>

In addition, as illustrated in FIG. 50F, a smoothing film is formed to cover the on-chip lens 4 of the substrate 2 having the element formed thereon.

In the present manufacturing method, the smoothing film is formed by, for example, a resin adhesive.

As the material of the adhesive, for example, an ultraviolet curable type, a heat curable type, or a combination of these curing reaction mechanism combined type sealing resin may be used. Examples of the sealing resin include epoxy-based, acrylic-based, silicone-based sealing resins, or modified resins thereof.

### <Processing for Attaching Transparent Substrate 3>

Next, as illustrated in FIG. 50F, the transparent substrate 3 is attached onto the smoothing film with the concave portion 41 side facing downward.

Next, as illustrated in FIG. 50G, the rear surface side of the substrate 2 having the element formed thereon is etched to thin the substrate 2 having the element formed thereon.

### <Formation of Rewiring>

Next, as illustrated in FIG. 50H, rear-surface electrodes, such as RDL (rewiring) and solder balls 6, and other wirings on the rear surface side are formed on the rear surface side of the substrate 2 having the element formed thereon.

Next, as illustrated in FIG. 50I, the transparent substrate 3 is etched to thin the transparent substrate 3.

Next, as illustrated in FIG. 50K, a metal 42 for laminating the rear-surface electrodes on the rear surface side of the substrate 2 having the element formed thereon is bonded.

### <Formation of Through-Hole 11>

Next, as illustrated in FIG. 50K, the through-holes 11 communicating with the concave portion 41 are formed in the transparent substrate 3.

The through-hole 11 is formed to communicate with the sacrificial layer at a position capable of facing the outer circumferential region ARA2.

The processing for forming the through-holes 11 is executed by, for example, dry etching, wet etching, laser processing, or the like.

### <Formation of Hollow Portion 12>

Next, as illustrated in FIG. 50L, the sacrificial layer is etched through the through-holes 11 to form the hollow portion 12.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13.

### <Individualization Processing>

In the case of a wafer shape constituted by a plurality of solid-state imaging elements 1, after the above-described processing is performed, a film 43 is attached, and dicing processing is executed to execute individualization, as illustrated in FIG. 50M.

This processing is the same for other manufacturing methods.

(Fourteenth Manufacturing Method)

A fourteenth manufacturing method will be described with reference to the accompanying drawings.

A basic configuration of the fourteenth manufacturing method is the same as that of the thirteenth manufacturing method. However, the fourteenth manufacturing method differs from the thirteenth manufacturing method in that, when the concave portion 41 is formed, the support portion 24 is formed in the concave portion 41.

### <Formation of Transparent Substrate 3>

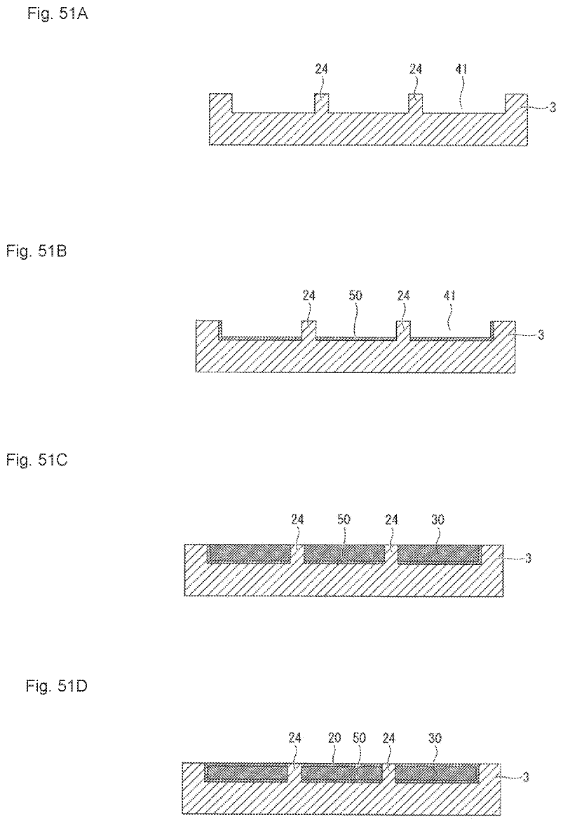

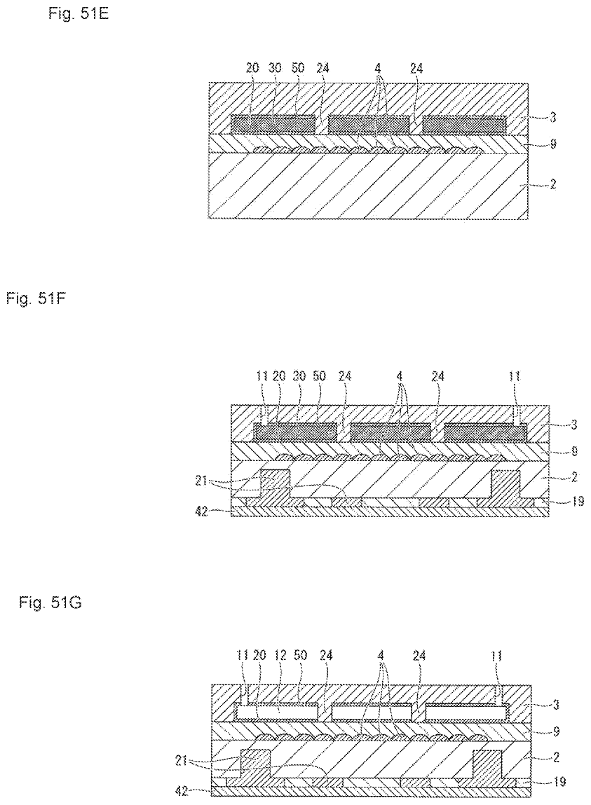

In the fourteenth manufacturing method, a mask is formed on the upper surface of the transparent substrate 3, and glass etching is performed on the central portion side of the transparent substrate 3 to form the concave portion 41 in the upper surface thereof. In the present manufacturing method, when the concave portion 41 is formed, the support portion 24 is formed in the concave portion 41 as illustrated in FIG. 51A. The upper surface of the support portion 24 is flush with the outer circumferential portion of the transparent substrate 3.

Next, the mask is peeled off. Next, as illustrated in FIG. 51B, a coating liquid for the low-refraction film 50 is applied into the concave portion 41 to form the low-refraction film 50 on the entire inner surface of the concave portion 41. It is preferable that the low-refraction film 50 be also formed on the side surface of the support portion 24.

Next, as illustrated in FIG. 51C, the sacrificial layer is formed inside the concave portion 41. The sacrificial layer is formed at a position capable of facing the entire effective pixel region ARA1. When the support portion 24 has a wall shape, the sacrificial layer is divided by the wall-like support portion 24.

Next, as illustrated in FIG. 51D, a coating liquid for the low-refraction film 20 is applied onto the upper surface of the formed sacrificial layer to form the low-refraction film 20.

### <Formation of Smoothing Film>

In addition, as illustrated in FIG. 51E, a smoothing film is formed to cover the on-chip lens 4 of the substrate 2 having the element formed thereon. In the present manufacturing method, the smoothing film is formed by, for example, the adhesive layer 10.

### <Processing for Attaching Transparent Substrate 3>

Next, as illustrated in FIG. 51E, the transparent substrate 3 is attached onto the smoothing film with the concave portion 41 side facing downward.

### <Rear-Surface Wiring Processing>

Next, the rear surface side of the substrate 2 having the elements formed thereon is etched to thin the substrate 2 having the elements formed thereon.

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

Next, the metal 42 for laminating the rear-surface electrodes on the rear surface side of the substrate 2 having the element formed thereon is bonded.

### <Formation of Through-Hole 11>

Next, as illustrated in FIG. 51F, the through-holes 11 communicating with the concave portion 41 are formed in the transparent substrate 3.

The through-hole 11 is formed at a position capable of facing the outer circumferential region ARA2 so as to communicate with all of the sacrificial layers divided by the support portion 24.

The processing for forming the through-holes 11 is executed by, for example, dry etching, wet etching, laser processing, or the like.

### <Formation of Hollow Portion 12>

Next, as illustrated in FIG. 51G, the sacrificial layer is etched through the through-holes 11 to form the hollow portion 12.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13.

For example, the solid-state imaging element 1 according to the tenth mode can be manufactured by the fourteenth manufacturing method.

(Fifteenth Manufacturing Method)

A fifteenth manufacturing method will be described with reference to the accompanying drawings.

A basic configuration of the fifteenth manufacturing method is the same as that of the fourteenth manufacturing method. However, the fifteenth manufacturing method differs from the fourteenth manufacturing method in that the support portion 24 formed in the concave portion 41 is constituted by a sacrificial layer.

### <Formation of Transparent Substrate 3>

First, a mask is formed on the upper surface of the transparent substrate 3.

Next, glass etching is performed on the central portion side of the transparent substrate 3 to form the concave portion 41.

Next, the mask is peeled off.

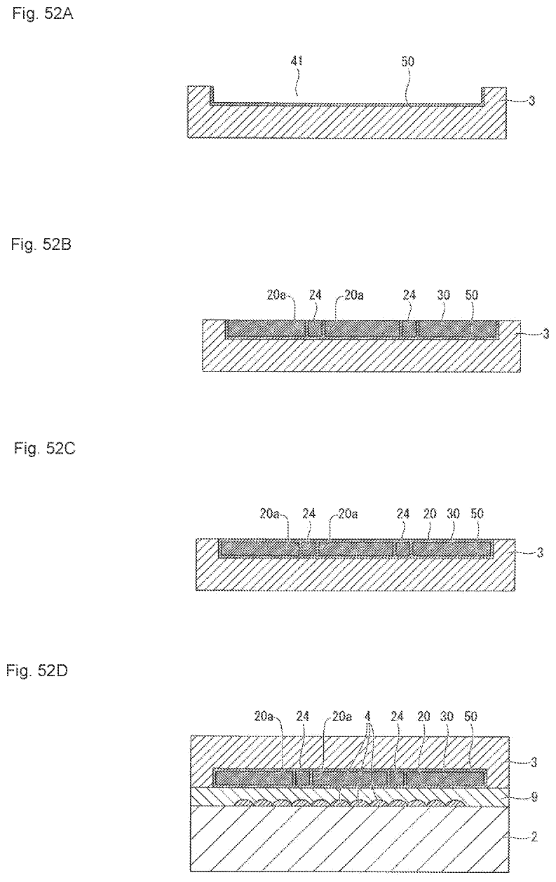

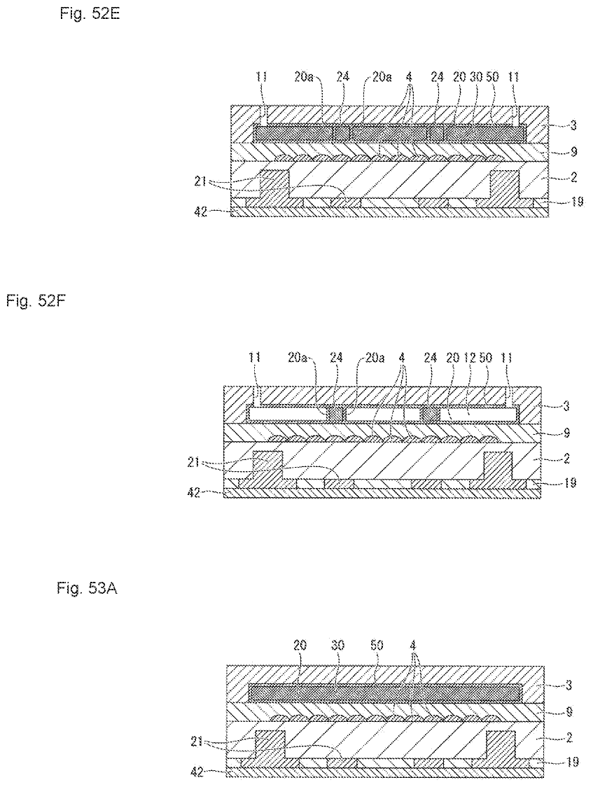

Next, as illustrated in FIG. 52A, a coating liquid for the low-refraction film 50 is applied into the concave portion 41 to form the low-refraction film 50 on the entire inner surface of the concave portion 41.

Next, as illustrated in FIG. 52B, the sacrificial layer is formed inside the concave portion 41.

The sacrificial layer is formed at a position capable of facing the entire effective pixel region ARA1.

When the sacrificial layer is formed, stopper patterning processing is executed to form a low-refraction film 20a on the side surface of the portion of the sacrificial layer serving as the support portion 24.

Next, as illustrated in FIG. 52C, a coating liquid for the low-refraction film 20 is applied onto the upper surface of the formed sacrificial layer to form the low-refraction film 20.

### <Formation of Smoothing Film>

In addition, as illustrated in FIG. 52D, a smoothing film is formed to cover the on-chip lens 4 of the substrate 2 having the element formed thereon.

In the present manufacturing method, the smoothing film is formed by, for example, a resin adhesive.

### <Processing for Attaching Transparent Substrate 3>

Next, as illustrated in FIG. 52D, the transparent substrate 3 is attached onto the smoothing film with the concave portion 41 side facing downward.

Next, the rear surface side of the substrate 2 having the element formed thereon is etched to thin the substrate 2 having the element formed thereon.

### <Rear-Surface Wiring Processing>

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

Next, the metal 42 for laminating the rear-surface electrodes on the rear surface side of the substrate 2 having the element formed thereon is bonded.

### <Formation of Through-Hole 11>

Next, as illustrated in FIG. 52E, the through-holes 11 communicating with the concave portion 41 are formed in the transparent substrate 3.

The through-hole 11 is formed at a position capable of facing the outer circumferential region ARA2 so as to communicate with all of the sacrificial layers divided by the support portion 24.

The processing for forming the through-holes 11 is executed by, for example, dry etching, wet etching, laser processing, or the like.

### <Formation of Hollow Portion 12>

Next, as illustrated in FIG. 52F, the sacrificial layer is etched through the through-holes 11 to form the hollow portion 12.

The etching of the sacrificial layer is executed using, for example, a dry etching method. At this time, XeF₂, ClF₃, BrF₃, and the like can be exemplified as gas species used for dry etching.

At this time, the portion of the sacrificial layer serving as the support portion 24 is protected by the low-refraction film 50 and remains in the hollow portion 12 without being etched.

### <Formation of Sealing Member 13>

The sealing member 13 may be or may not be formed.

When the sealing member 13 is formed, the through-hole 11 is closed and sealed with the sealing member 13.

For example, the solid-state imaging element 1 according to the eleventh mode can be manufactured by the fifteenth manufacturing method.

(Sixteenth Manufacturing Method)

A sixteenth manufacturing method will be described with reference to the accompanying drawings.

A basic configuration of the sixteenth manufacturing method is the same as that of the thirteenth manufacturing method. However, the sixteenth manufacturing method differs from the thirteenth manufacturing method in terms of the formation of the through-holes 11.

### <Formation of Transparent Substrate 3>

Similarly to the thirteenth manufacturing method, glass etching is performed on the central portion side of the upper surface of the transparent substrate 3 to form the concave portion 41.

A coating liquid for the low-refraction film 50 is applied into the concave portion 41 to form the low-refraction film 50 on the entire inner surface of the concave portion 41.

Next, the sacrificial layer is formed inside the concave portion 41. The sacrificial layer is formed at a position capable of facing the entire effective pixel region ARA1.

Next, a coating liquid for the low-refraction film 20 is applied onto the upper surface of the formed sacrificial layer to form the low-refraction film 20.

### <Formation of Smoothing Film>

In addition, similarly to the thirteenth manufacturing method, a smoothing film is formed to cover the on-chip lens 4 of the substrate 2 having the element formed thereon. In the present manufacturing method, the smoothing film is formed by, for example, the adhesive layer 10.

### <Processing for Attaching Transparent Substrate 3>

Next, the transparent substrate 3 is attached onto the smoothing film with the concave portion 41 side facing downward.

### <Rear-Surface Wiring Processing>

Next, the rear surface side of the substrate 2 having the elements formed thereon is etched to thin the substrate 2 having the elements formed thereon.

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

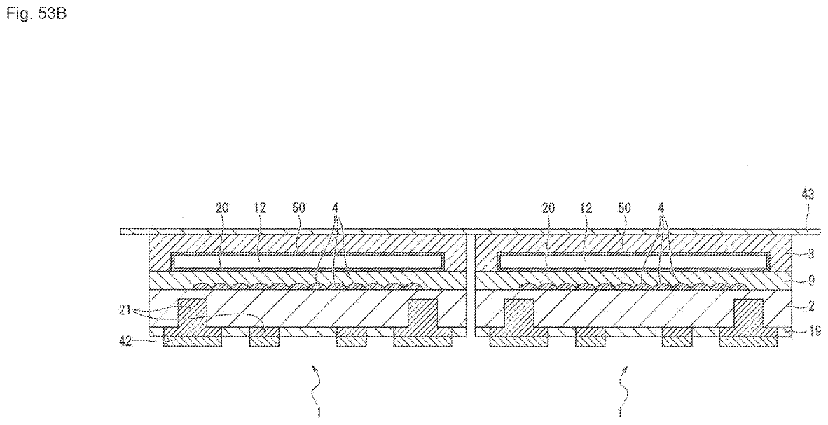

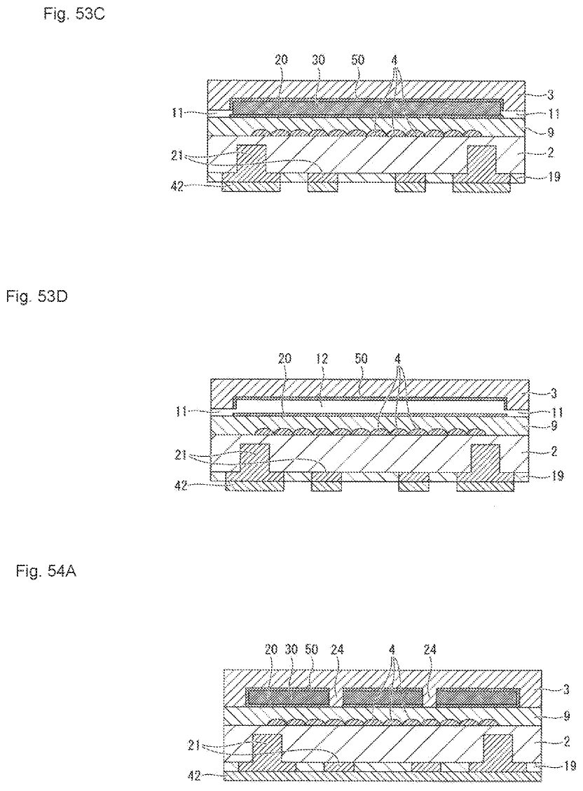

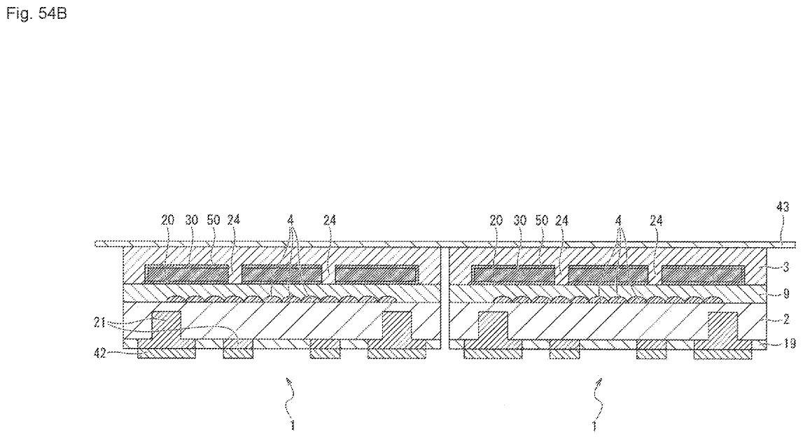

Next, the metal 42 for laminating the rear-surface electrodes on the rear surface side of the substrate 2 having the element formed thereon is bonded (see FIG. 53A).

### <Individualization Processing>

As illustrated in FIG. 53B, the film 43 is attached to a wafer shape constituted by a plurality of solid-state imaging elements 1, and dicing processing is executed to execute individualization.

### <Formation of Through-Hole 11>

Next, as illustrated in FIG. 53C, the through-holes 11 communicating with the concave portion 41 are formed in the side wall of the transparent substrate 3 for each individualized solid-state imaging element 1. The through-hole 11 is formed at a position capable of facing the outer circumferential region ARA2 so as to communicate with the sacrificial layer.

The processing for forming the through-holes 11 is executed by, for example, dry etching, wet etching, laser processing, or the like.

### <Formation of Hollow Portion 12>

Next, as illustrated in FIG. 53D, the sacrificial layer is etched through the through-holes 11 to form the hollow portion 12 for each individualized solid-state imaging element 1.

### <Formation of Sealing Member 13>

The sealing member 13 may be or may not be formed.

When the sealing member 13 is formed, the through-hole 11 is closed and sealed with the sealing member 13.

For example, the solid-state imaging element 1 according to the twelfth mode can be manufactured by the sixteenth manufacturing method.

(Seventeenth Manufacturing Method)

A seventeenth manufacturing method will be described with reference to the accompanying drawings.

A basic configuration of the seventeenth manufacturing method is the same as that of the fourteenth manufacturing method. However, the seventeenth manufacturing method differs from the fourteenth manufacturing method in terms of the formation position of the through-hole 11.

### <Formation of Transparent Substrate 3>

The transparent substrate 3 is formed in the same manner as in the fourteenth manufacturing method.

That is, first, glass etching is performed on the central portion side of the upper surface of the transparent substrate 3 to form the concave portion 41. When the concave portion 41 is formed, the support portion 24 is formed in the concave portion 41.

Next, a coating liquid for the low-refraction film 50 is applied into the concave portion 41 to form the low-refraction film 50 on the entire inner surface of the concave portion 41. It is preferable that the low-refraction film 50 be also formed on the side surface of the support portion 24.

Next, the sacrificial layer is formed inside the concave portion 41. The sacrificial layer is formed at a position capable of facing the entire effective pixel region ARA1. When the support portion 24 has a wall shape, the sacrificial layer is divided by the wall-like support portion 24.

Next, a coating liquid for the low-refraction film 20 is applied onto the upper surface of the formed sacrificial layer to form the low-refraction film 20.

### <Formation of Smoothing Film>

In addition, a smoothing film is formed to cover the on-chip lens 4 of the substrate 2 having the element formed thereon.

In the present manufacturing method, the smoothing film is formed by, for example, the adhesive layer 10.

### <Processing for Attaching Transparent Substrate 3>

Next, the transparent substrate 3 is attached onto the smoothing film with the concave portion 41 side facing downward.

Next, the rear surface side of the substrate 2 having the elements formed thereon is etched to thin the substrate 2 having the elements formed thereon.

### <Rear-Surface Wiring Processing>

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

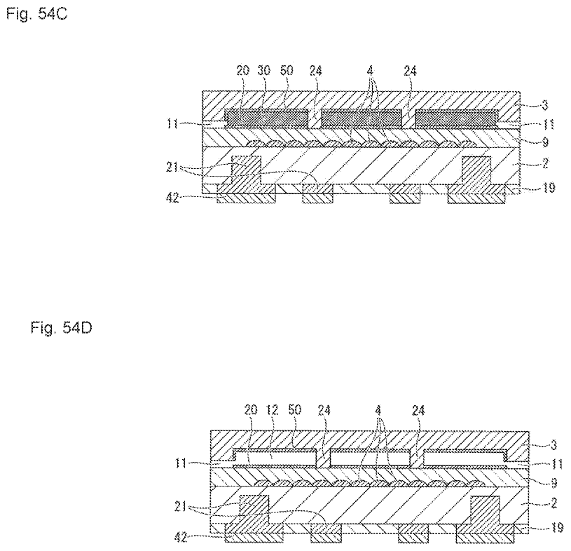

Next, the metal 42 for laminating the rear-surface electrodes on the rear surface side of the substrate 2 having the element formed thereon is bonded (see FIG. 54A).

### <Individualization Processing>

Next, as illustrated in FIG. 54B, the film 43 is attached to a wafer shape constituted by a plurality of solid-state imaging elements 1, and dicing processing is executed to execute individualization.

### <Formation of Through-Hole 11>

Next, as illustrated in FIG. 54C, the through-holes 11 communicating with the concave portion 41 are formed in the side surface of the transparent substrate 3 for each individualized solid-state imaging element 1.

The through-hole 11 is formed at a position capable of facing the outer circumferential region ARA2 so as to communicate with all of the sacrificial layers divided by the support portion 24. The processing for forming the through-holes 11 is executed by, for example, dry etching, wet etching, laser processing, or the like.

### <Formation of Hollow Portion 12>

Next, as illustrated in FIG. 54D, the sacrificial layer is etched through the through-holes 11 to form the hollow portion 12 for each individualized solid-state imaging element 1.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13.

For example, the solid-state imaging element 1 according to the thirteenth mode can be manufactured by the seventeenth manufacturing method.

(Eighteenth Manufacturing Method)

An eighteenth manufacturing method will be described with reference to the accompanying drawings.

A basic configuration of the eighteenth manufacturing method is the same as that of the fifteenth manufacturing method. However, the eighteenth manufacturing method differs from the fifteenth manufacturing method in that the support portion 24 for forming the concave portion 41 of the through-hole 11 is constituted by a sacrificial layer.

### <Formation of Transparent Substrate 3>

The transparent substrate 3 is formed in the same manner as in the fifteenth manufacturing method.

That is, first, glass etching is performed on the central portion side of the upper surface of the transparent substrate 3 to form the concave portion 41.

Next, a coating liquid for the low-refraction film 50 is applied into the concave portion 41 to form the low-refraction film 50 on the entire inner surface of the concave portion 41.

Next, the sacrificial layer is formed inside the concave portion 41. The sacrificial layer is formed at a position capable of facing the entire effective pixel region ARA1.

When the sacrificial layer is formed, stopper patterning processing is executed to form the low-refraction film 50 on the side surface of the portion of the sacrificial layer serving as the support portion 24.

Next, a coating liquid for the low-refraction film 20 is applied onto the upper surface of the formed sacrificial layer to form the low-refraction film 20.

### <Formation of Smoothing Film>

In addition, a smoothing film is formed to cover the on-chip lens 4 of the substrate 2 having the element formed thereon.

In the present manufacturing method, the smoothing film is formed by, for example, the adhesive layer 10.

### <Processing for Attaching Transparent Substrate 3>

Next, the transparent substrate 3 is attached onto the smoothing film with the concave portion 41 side facing downward.

Next, the rear surface side of the substrate 2 having the elements formed thereon is etched to thin the substrate 2 having the elements formed thereon.

### <Rear-Surface Wiring Processing>

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

Next, a metal for laminating the rear-surface electrodes on the rear surface side of the substrate 2 having the element formed thereon is bonded.

### <Individualization Processing>

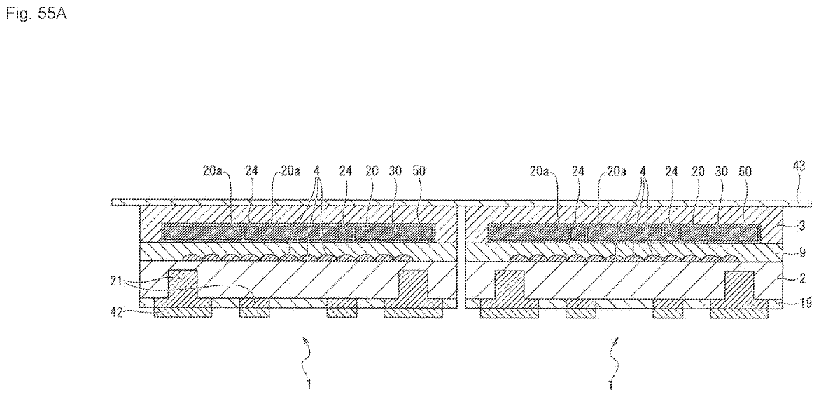

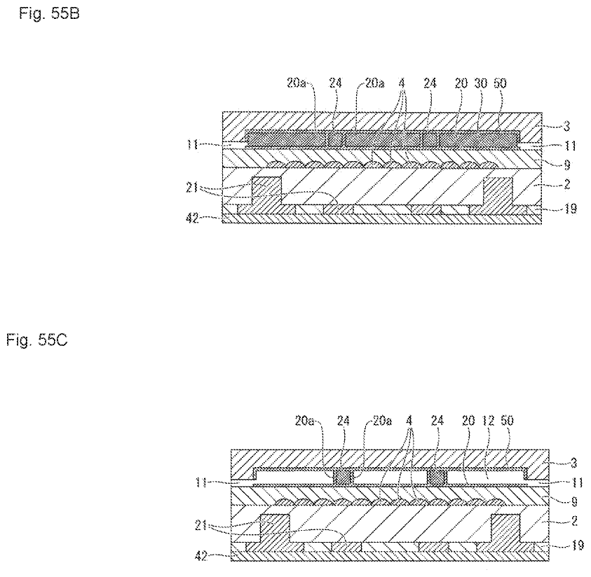

The film 43 is attached to a wafer shape constituted by a plurality of solid-state imaging elements 1, and dicing processing is executed to execute individualization (see FIG. 55A).

### <Formation of Through-Hole 11>

Next, as illustrated in FIG. 55B, the through-holes 11 communicating with the concave portion 41 are formed in the side surface of the transparent substrate 3 for each individualized solid-state imaging element 1.

At this time, the through-hole 11 is formed at a position capable of facing the outer circumferential region ARA2 so as to communicate with all of the sacrificial layers divided by the support portion 24. The processing for forming the through-holes 11 is executed by, for example, dry etching, wet etching, laser processing, or the like.

### <Formation of Hollow Portion 12>

Next, as illustrated in FIG. 55C, the sacrificial layer is etched through the through-holes 11 to form the hollow portion 12 for each individualized solid-state imaging element 1.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13.

For example, the solid-state imaging element 1 according to the fourteenth mode can be manufactured by the eighteenth manufacturing method.

(Nineteenth Manufacturing Method)

A nineteenth manufacturing method will be described with reference to the accompanying drawings.

A basic configuration of the nineteenth manufacturing method is the same as that of the seventeenth manufacturing method. However, the nineteenth manufacturing method differs from the seventeenth manufacturing method in that the through-holes 11 are formed before the individualization is performed.

### <Formation of Transparent Substrate 3>

The transparent substrate 3 is formed in the same manner as in the fourteenth manufacturing method.

That is, first, glass etching is performed on the central portion side of the upper surface of the transparent substrate 3 to form the concave portion 41. When the concave portion 41 is formed, the support portion 24 is formed in the concave portion 41.

Next, a coating liquid for the low-refraction film 50 is applied into the concave portion 41 to form the low-refraction film 50 on the entire inner surface of the concave portion 41. It is preferable that the low-refraction film 50 be also formed on the side surface of the support portion 24.

Next, the sacrificial layer is formed inside the concave portion 41. The sacrificial layer is formed at a position capable of facing the entire effective pixel region ARA1. When the support portion 24 has a wall shape, the sacrificial layer is divided by the wall-like support portion 24.

Next, a coating liquid for the low-refraction film 20 is applied onto the upper surface of the formed sacrificial layer to form the low-refraction film 20.

### <Formation of Smoothing Film>

In addition, a smoothing film is formed to cover the on-chip lens 4 of the substrate 2 having the element formed thereon.

In the present manufacturing method, the smoothing film is formed by, for example, the adhesive layer 10.

### <Processing for Attaching Transparent Substrate 3>

Next, the transparent substrate 3 is attached onto the smoothing film with the concave portion 41 side facing downward.

Next, the rear surface side of the substrate 2 having the elements formed thereon is etched to thin the substrate 2 having the elements formed thereon.

### <Rear-Surface Wiring Processing>

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

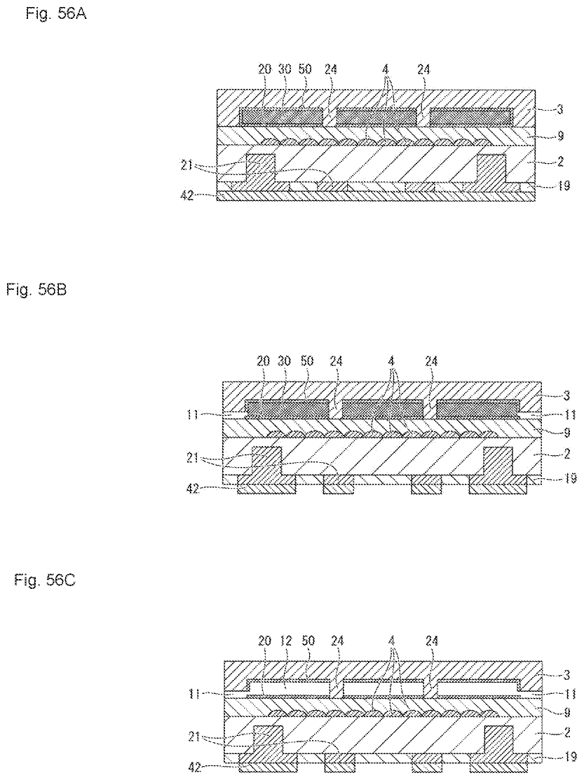

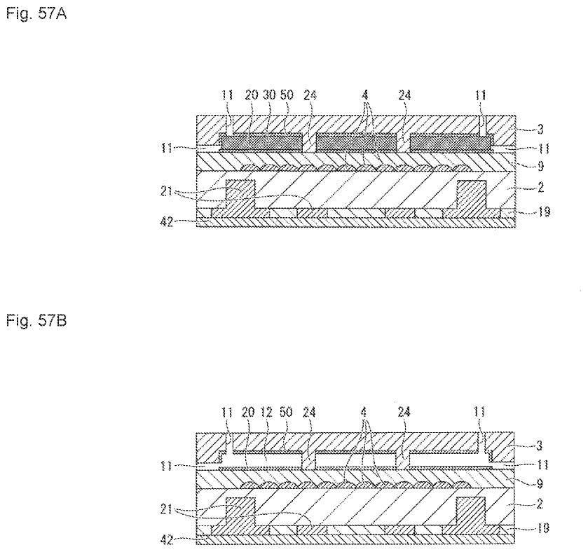

Next, a metal for laminating the rear-surface electrodes on the rear surface side of the substrate 2 having the element formed thereon is bonded (see FIG. 56A).

### <Formation of Through-Hole 11>

Next, as illustrated in FIG. 56B, the through-holes 11 communicating with the concave portion 41 are formed in the side surface of the transparent substrate 3 for each solid-state imaging element 1.

The through-hole 11 is formed at a position capable of facing the outer circumferential region ARA2 so as to communicate with all of the sacrificial layers divided by the support portion 24. The processing for forming the through-holes 11 is executed by, for example, dry etching, wet etching, laser processing, or the like.

### <Formation of Hollow Portion 12>

Next, as illustrated in FIG. 56C, the sacrificial layer is etched through the through-holes 11 to form the hollow portion 12.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13.

### <Individualization Processing>

In the case of a wafer shape constituted by a plurality of solid-state imaging elements 1, after the above-described processing is performed, a film is attached, and dicing processing is executed to execute individualization.

Here, in all of the manufacturing methods, the plurality of solid-state imaging elements 1 may be manufactured in units of wafers or in units of chips.

For example, the solid-state imaging element 1 according to the thirteenth mode can be manufactured by the nineteenth manufacturing method.

(Twentieth Manufacturing Method)

A twentieth manufacturing method will be described with reference to the accompanying drawings.

A basic configuration of the twentieth manufacturing method is the same as that of the nineteenth manufacturing method. However, the twentieth manufacturing method differs from the nineteenth manufacturing method in terms of the formation position of the through-hole 11.

### <Formation of Transparent Substrate 3>

The transparent substrate 3 is formed in the same manner as in the fourteenth manufacturing method.

That is, first, glass etching is performed on the central portion side of the upper surface of the transparent substrate 3 to form the concave portion 41. When the concave portion 41 is formed, the support portion 24 is formed in the concave portion 41.

Next, a coating liquid for the low-refraction film 50 is applied into the concave portion 41 to form the low-refraction film 50 on the entire inner surface of the concave portion 41. It is preferable that the low-refraction film 50 be also formed on the side surface of the support portion 24.

Next, the sacrificial layer is formed inside the concave portion 41. The sacrificial layer is formed at a position capable of facing the entire effective pixel region ARA1. When the support portion 24 has a wall shape, the sacrificial layer is divided by the wall-like support portion 24.

Next, a coating liquid for the low-refraction film 20 is applied onto the upper surface of the formed sacrificial layer to form the low-refraction film 20.

### <Formation of Smoothing Film>

In addition, a smoothing film is formed to cover the on-chip lens 4 of the substrate 2 having the element formed thereon.

In the present manufacturing method, the smoothing film is formed by, for example, the adhesive layer 10.

### <Processing for Attaching Transparent Substrate 3>

Next, the transparent substrate 3 is attached onto the smoothing film with the concave portion 41 side facing downward.

Next, the rear surface side of the substrate 2 having the elements formed thereon is etched to thin the substrate 2 having the elements formed thereon.

### <Rear-Surface Wiring Processing>

Next, rear-surface electrodes, such as RDL (rewiring) and solder balls 6, and other wirings on the rear surface side are formed on the rear surface side of the substrate 2 having the element formed thereon.

Next, the transparent substrate 3 is etched to thin the transparent substrate 3.

Next, the metal for laminating the rear-surface electrodes on the rear surface side of the substrate 2 having the element formed thereon is bonded (see FIG. 56A).

### <Formation of Through-Hole 11>

Next, as illustrated in FIG. 57A, the through-holes 11 communicating with the concave portion 41 are formed.

However, in the present manufacturing method, as illustrated in FIG. 57A, the through-hole 11 is formed at a position capable of facing the outer circumferential region ARA2 so as to communicate with all of the sacrificial layers divided by the support portion 24.

In the present manufacturing method, the through-holes 11 are formed in the plate thickness direction and also formed on the side surface side of the transparent substrate 3. The processing for forming the through-holes 11 is executed by, for example, dry etching, wet etching, laser processing, or the like.

### <Formation of Hollow Portion 12>

Next, as illustrated in FIG. 57B, the sacrificial layer is etched through the through-holes 11 to form the hollow portion 12.

The etching of the sacrificial layer is executed using, for example, a dry etching method. At this time, XeF₂, ClF₃, BrF₃, and the like can be exemplified as gas species used for dry etching.

### <Formation of Sealing Member 13>

The sealing member 13 may be or may not be formed.

When the sealing member 13 is formed, the through-hole 11 is closed and sealed with the sealing member 13.

### <Individualization Processing>

In the case of a wafer shape constituted by a plurality of solid-state imaging elements 1, after the above-described processing is performed, a film is attached, and dicing processing is executed to execute individualization.

For example, the solid-state imaging element 1 of the fifteenth mode can be manufactured by the twentieth manufacturing method.

Here, in all of the manufacturing methods, the plurality of solid-state imaging elements 1 may be manufactured in units of wafers or in units of chips.

(Operations and Others)

In general, flare occurs due to a diffraction phenomenon occurring when light incident a pixels is reflected by the on-chip lenses 4 (microlenses) that are periodically disposed, and occurs due to reflection of incident light at various angles, such as reflection approximate to perpendicularity and reflection in a distant direction, and occurs incidence on a pixel distant from a pixel on which incident light is to be incident.

In a case where the hollow portion 12 is not formed as in the present disclosure, flare remarkably occurs due to, for example, a light diffraction phenomenon caused by the periodicity of the on-chip lens 4.

On the other hand, in the present disclosure, it is possible to suppress the occurrence of flare caused by the light diffraction phenomenon by providing the hollow portion 12 above the on-chip lens 4.

Further, according to the present disclosure, the through-holes 11 are provided, and thus the hollow portion 12 has a hollow portion structure in which moisture is less likely to be trapped.

Further, in the present disclosure, a smoothing film is formed above the on-chip lens 4 even when the hollow portion 12 is provided above the on-chip lens 4. For this reason, even when the thickness of the transparent substrate 3 is reduced so that the transparent substrate 3 is easily bent, the transparent substrate 3 is prevented from coming into contact with the on-chip lens 4 due to the bending of the transparent substrate 3. As a result, it is possible to suppress impairment of the function of the on-chip lens 4.

Further, even when the through-holes 11 are provided but closed by the sealing member 13, it is possible to prevent pixel deterioration due to dust entering the hollow portion 12 through the through-holes 11 and deterioration of reliability due to moisture entering the hollow portion 12 through the through-holes 11.

Here, in a case where a black pigment is added to the sealing member 13, flare is suppressed even at the position of the through-hole 11, and a flare suppressing function can be enhanced. That is, a black pigment such as carbon black, titanium black, iron oxide, copper-chromium composite oxide, or copper-chromium-zinc composite oxide may be added to the sealing member 13. By adding a black pigment in these resins, flare due to light reflected from a microlens, a wiring layer, or the like is suppressed, and the image quality of the solid-state imaging element 1 is improved.

Further, in the method of manufacturing the solid-state imaging element 1 of the present disclosure, by providing a sacrificial layer at the formation position of the hollow portion 12, the hollow portion 12 can be formed either before or after the rewiring processing, and the hollow portion 12 can be formed even after the individualization processing.

That is, according to the present disclosure, even with a structure finally having the hollow portion 12, damage caused by a wafer process is protected by the sacrificial layer. As a result, the degree of freedom in choosing a manufacturing process is improved. Further, since the space of the hollow portion 12 can be finely adjusted depending on the thickness of the sacrificial layer, it is possible to reliably secure a space for the hollow portion 12 and achieve a reduction in height. In this manner, it is possible to finely adjust the thickness of the hollow portion 12 and achieve a function of stably forming a cavity. Thereby, it is possible to achieve miniaturization of the solid-state imaging element 1.

For example, in an embodiment of the present disclosure, when forming a hollow layer of a cavity-type solid-state imaging element 1, a sacrificial layer is formed to protect damage caused by a wafer process. Further, the sacrificial layer is etched and removed using the through-holes 11 after the formation of rewiring, and thus it is possible to increase mechanical strength at the time of forming a rewiring layer, reliably secure a cavity space, and achieve a reduction in height.

Thus, in the present disclosure, the cavity-type solid-state imaging element 1 can be packaged in a chip size, and a stable cavity space can be secured. That is, by forming a sacrificial layer and realizing a hollow structure, mechanical strength in the manufacturing process of the solid-state imaging element 1 is increased, thereby improving a yield and reducing the cost.

Here, electronic equipment using the solid-state imaging element 1 of the present disclosure can be configured to include an optical system, an imaging device, and a signal processing circuit.

Further, in a case where the side surface of the hollow portion 12 is formed by the adhesive layer 10, the spacers 14 are provided in the adhesive layer 10 to contribute to increasing the mechanical strength of the sidewalls constituting the hollow portion 12. At this time, the spacers 14 can be easily formed by being formed at the time of forming the lower surface of the transparent substrate 3 so as to protrude from the transparent substrate 3 during manufacture, or by using a portion of the sacrificial layer as the spacers 14.

Further, in a case where the low-refraction film 50 is provided, the low-refraction film 50 acts as an antireflection film and a protective film. As a result, even when the hollow portion 12 is provided, deterioration of image quality can be prevented.

In addition, even with a structure finally having the hollow portion 12, the sacrificial layer is provided at the formation position of the hollow portion 12 as described above, and thus rigidity during manufacture is secured, whereby it is possible to suppress the occurrence of cracks and the like even when the thickness of the transparent substrate 3 is reduced. Further, in a case where the support portion 24 is provided in the hollow portion 12, the bending of the transparent substrate 3 can be suppressed even after a hollow portion structure is formed, and thus the flatness of the transparent substrate 3 can be secured, and it is possible to suppress deterioration in image quality due to bending of the transparent substrate 3 even when the hollow portion 12 is provided.

Note that the operations and effects described in the present specification are merely exemplary and are not limited, and other effects described in the present specification may be achieved.

The present disclosure can also be configured as follows.

Others

(1)

A package including:

a flattening film covering an on-chip lens formed on a light incidence side of a substrate having an element formed thereon;
a transparent substrate formed on the light incidence side of the flattening film;
a hollow portion formed in a region overlapping the on-chip lens when seen in a plan view with respect to at least one of between the flattening film and the transparent substrate and inside the transparent substrate; and
a through-hole making the hollow portion communicate with the outside.

According to this configuration, by providing the hollow portion above the on-chip lens, it is possible to suppress the occurrence of flare caused by a light diffraction phenomenon. That is, flare caused by reflected light from a microlens, a wiring layer, and the like is suppressed, and the image quality of the package is improved.

In addition, the through-hole is provided, and thus the hollow portion has a hollow portion structure in which moisture is less likely to be trapped.

A smoothing film is formed above the on-chip lens even when the hollow portion is provided above the on-chip lens. For this reason, even when the thickness of the transparent substrate is reduced so that the transparent substrate is easily bent, the transparent substrate is prevented from coming into contact with the on-chip lens due to the bending of the transparent substrate. As a result, it is possible to suppress impairment of the function of the on-chip lens 4.

(2)

The package according to (1), further including:

a sealing member closing the through-hole.

According to this configuration, by closing the through-hole with the sealing member, it is possible to prevent pixel deterioration due to dust entering the hollow portion through the through-hole and deterioration of reliability due to moisture entering the hollow portion through the through-hole.

(3)

The package according to (2), wherein the sealing member is formed of a material to which a black pigment is added.

According to this configuration, by adding a black pigment to the sealing member, flare is suppressed even at the position of the through-hole, and a flare suppressing function can be enhanced.

(4)

The package according to any one of (1) to (3), wherein the hollow portion is formed between the flattening film and the transparent substrate,

the transparent substrate is laminated on the light incidence side of the flattening film via an adhesive layer positioned on an outer circumference of the hollow portion, and
the adhesive layer includes a spacer.

According to this configuration, in a case where the side surface of the hollow portion is formed by the adhesive layer, the spacer is provided in the adhesive layer to contribute to increasing the mechanical strength of the sidewalls constituting the hollow portion.

Note that the spacer can be easily formed by being formed at the time of forming the lower surface of the transparent substrate so as to protrude from the transparent substrate during manufacture, or by using a portion of the sacrificial layer as the spacer.

(5)

The package according to any one of (1) to (4), wherein the hollow portion is formed between the flattening film and the transparent substrate, and a columnar or wall-like support portion formed of a light transmissive material and extending in a thickness direction of the transparent substrate is provided in the hollow portion.

According to this configuration, even when the hollow portion is formed and the thickness of the transparent substrate is reduced, the bending of the transparent substrate can be further suppressed. That is, the bending of the transparent substrate can be suppressed, the flatness of the transparent substrate can be secured, and it is possible to suppress deterioration in image quality due to bending of the transparent substrate even when the hollow portion is provided.

(6)

The package according to any one of (1) to (5), wherein a low-refraction film formed of a material having a refractive index lower than that of the flattening film is formed on at least a surface of the flattening film out of a surface of the flattening film on the transparent substrate side and a surface of the transparent substrate in which the hollow portion is formed.

According to this configuration, it is possible to further suppress flare.

(7)

The package according to any one of (1) to (6), wherein the through-hole is formed in the transparent substrate.

According to this configuration, it is possible to more reliably form the through-hole.

(8)

The package according to any one of (1) to (7), wherein the through-hole extends in a direction intersecting a thickness direction of the transparent substrate.

According to this configuration, for example, a through-hole may not be formed in the upper surface of the transparent substrate.

(9)

A package manufacturing method, the method including: forming a flattening film covering an on-chip lens of a substrate having an element formed thereon;

laminating a transparent substrate on the light incidence side of the flattening film via a sacrificial layer and an adhesive layer disposed on an outer circumference of the sacrificial layer;
forming a through-hole making the sacrificial layer communicate with the outside; and
etching the sacrificial layer through the through-hole to form a hollow portion after the transparent substrate is laminated.

According to this configuration, by providing a sacrificial layer at the formation position of the hollow portion, the hollow portion can be formed either before or after the rewiring processing, and the hollow portion can be formed even after the individualization processing.

In addition, even with a structure finally having the hollow portion, damage caused by a wafer process is protected by the sacrificial layer. As a result, the degree of freedom in choosing a manufacturing process is improved. In addition, since the space of the hollow portion can be finely adjusted depending on the thickness of the sacrificial layer, it is possible to reliably secure a space for the hollow portion and achieve a reduction in height. In this manner, it is possible to finely adjust the thickness of the hollow portion and achieve a function of stably forming a cavity. Thereby, it is possible to achieve miniaturization of the package.

(10)

A package manufacturing method, the method including: forming a flattening film covering an on-chip lens formed on a light incidence side of a substrate having an element formed thereon;

forming a concave portion in a surface of the transparent substrate which is capable of facing the on-chip lens;
forming a sacrificial layer in the concave portion; laminating the transparent substrate on the light incidence side of the flattening film with the sacrificial layer facing the flattening film;
forming a through-hole making the sacrificial layer communicate with the outside; and
etching the sacrificial layer through the through-hole to form a hollow portion after the transparent substrate is laminated.

According to this configuration, by providing a sacrificial layer at the formation position of the hollow portion, the hollow portion can be formed either before or after the rewiring processing, and the hollow portion can be formed even after the individualization processing.

In addition, even with a structure finally having the hollow portion, damage caused by a wafer process is protected by the sacrificial layer. As a result, the degree of freedom in choosing a manufacturing process is improved. In addition, since the space of the hollow portion can be finely adjusted depending on the thickness of the sacrificial layer, it is possible to reliably secure a space for the hollow portion and achieve a reduction in height. In this manner, it is possible to finely adjust the thickness of the hollow portion and achieve a function of stably forming a cavity. Thereby, it is possible to achieve miniaturization of the package.

(11)

A package manufacturing method, the method including:

forming a flattening film covering an on-chip lens formed on a light incidence side of a substrate having an element formed thereon;
laminating a transparent substrate on the light incidence side of the flattening film;
forming the laminated transparent substrate by laminating a plurality of glass substrates;
sealing a sacrificial layer between any glass substrates constituting the plurality of glass substrates;
forming a through-hole making the sacrificial layer communicating with the outside; and
etching the sacrificial layer through the through-hole to form a hollow portion after the transparent substrate is laminated.

According to this configuration, by providing a sacrificial layer at the formation position of the hollow portion, the hollow portion can be formed either before or after the rewiring processing, and the hollow portion can be formed even after the individualization processing.

In addition, even with a structure finally having the hollow portion, damage caused by a wafer process is protected by the sacrificial layer. As a result, the degree of freedom in choosing a manufacturing process is improved. In addition, since the space of the hollow portion can be finely adjusted depending on the thickness of the sacrificial layer, it is possible to reliably secure a space for the hollow portion and achieve a reduction in height. In this manner, it is possible to finely adjust the thickness of the hollow portion and achieve a function of stably forming a cavity. Thereby, it is possible to achieve miniaturization of the package.

(12)

The package manufacturing method according to any one of (9) to (11), wherein the through-hole is closed with a sealing member after the hollow portion is formed.

According to this configuration, by closing the through-hole with the sealing member, it is possible to prevent pixel deterioration due to dust entering the hollow portion through the through-hole and deterioration of reliability due to moisture entering the hollow portion through the through-hole.

(13)

The package manufacturing method according to any one of (9) to (12), wherein the through-hole is formed after the transparent substrate is laminated on the light incidence side of the flattening film.

According to this configuration, it is possible to adjust the formation of the through-hole.

(14)

The package manufacturing method according to any one of (9) to (13), wherein the sacrificial layer is etched after forming a rewiring on a rear surface side of the substrate on which the element is formed.

According to this configuration, even with a structure finally having the hollow portion, it is possible to secure the rigidity at the time of forming the rewiring.

(15)

The package manufacturing method according to any one of (9) to (14), wherein a spacer protruding toward the adhesive layer is formed on a surface of the transparent substrate which abuts on the adhesive layer.

According to this configuration, in a case where the side surface of the hollow portion is formed by the adhesive layer, the spacer is provided in the adhesive layer to contribute to increasing the mechanical strength of the sidewalls constituting the hollow portion.

Note that the spacer can be easily formed by being formed at the time of forming the lower surface of the transparent substrate so as to protrude from the transparent substrate during manufacture, or by using a portion of the sacrificial layer as the spacer.

(16)

The package manufacturing method according to any one of (9) to (15), wherein a low-refraction film formed of a material having a refractive index lower than that of the flattening film is formed on at least one of a surface of the flattening film and a surface of the transparent substrate which abuts on the sacrificial layer. According to this configuration, it is possible to further suppress the occurrence of flare.

(17)

The package manufacturing method according to any one of (9) to (16), wherein a support portion protruding into the sacrificial layer from a surface of the transparent substrate which abuts on the sacrificial layer is provided, and the support portion is formed on the surface of the transparent substrate before the sacrificial layer is formed.

(18)

The package manufacturing method according to any one of (9) to (16) wherein a support portion protruding into the sacrificial layer from a surface of the transparent substrate which abuts on the sacrificial layer is provided, and the support portion contains a material of the sacrificial layer.

According to this configuration, it is possible to suppress bending of the transparent substrate even when the hollow portion is formed.

(19)

The package manufacturing method according to any one of (9) to (18), wherein the through-hole is formed to extend in a direction intersecting a thickness direction of the transparent substrate.

According to this configuration, the degree of freedom in forming the through-hole is improved.

(20) The package manufacturing method according to any one of (9) to (19), wherein the through-hole is formed on an outer circumferential side of a region overlapping the entire on-chip lens when seen in a plan view.

It is possible to reduce the influence of the through-hole on a pixel.

(21)

The package according to any one of (1) to (6), wherein a side wall of the hollow portion is constituted by an adhesive layer, and the through-hole is formed in the adhesive layer.

(22)

The package according to any one of (1) to (8), wherein the hollow portion is sealed between the flattening film and the transparent substrate, and the side surface of the hollow portion is constituted by an adhesive layer that connects the smoothing film and the transparent substrate,

(23)

The package according to any one of (1) to (8), wherein the hollow portion is constituted by a concave portion formed in a lower surface of the transparent substrate and a smoothing film,

(24)

The package according to any one of (1) to (8), wherein the hollow portion is sealed within the transparent substrate, and the transparent substrate is constituted by a plurality of layers of glass substrates, and the hollow portion is formed between any adjacent glass substrates.

(25)

The package according to (4), wherein the spacer is formed of the same material as the transparent substrate and is integrated with the transparent substrate.

(26)

The package according to (5), wherein the support portion is formed of the same material as the transparent substrate and is integrated with the transparent substrate.

(27)

The package according to (8), wherein the through-hole is formed in a side surface of the glass substrate.

(28)

The package manufacturing method according to (14), wherein processing for etching the sacrificial layer through the through-hole to form the hollow portion is performed after the rewiring processing.

(29)

The package manufacturing method according to any one of (9) to (20), wherein the through-hole is formed after the transparent substrate is laminated.

(30)

The package manufacturing method according to any one of (9) to (20), wherein the through-hole is formed before the transparent substrate is laminated.

(31)

The package manufacturing method according to (17), wherein the support portion is formed integrally with the transparent substrate.

(32)

The package manufacturing method according to (19), wherein the through-hole is formed in a side surface of the transparent substrate.

The scope of the present disclosure is not limited to the illustrated and described exemplary embodiment, but includes all embodiments that provide equivalent effects intended by the present disclosure. In addition, the scope of the present disclosure is not limited to combinations of features of the invention defined by the claims, but can be defined by any combination of specific features among all disclosed features.

### REFERENCE SIGNS LIST

1 Solid-state imaging element (package)
2 Substrate having element formed
3 Transparent substrate
3A Upper glass substrate
3B Lower glass substrate
4 On-chip lens
9 Flattening film
10 Adhesive layers
10A Portion on inner circumferential side
10B Portion on outer circumferential side
11 Through-hole
12 Hollow portion
13 Sealing member
14 Spacer
14 Sacrificial layer
15 Adhesive layer
20, 50 Low-refraction film
20a Low-refraction film
24 Support portion
41 Concave portion
ARA1 Effective pixel region
ARA2 Outer circumferential region

1. A package comprising:
a flattening film covering an on-chip lens formed on a light incidence side of a substrate having an element formed thereon;
a transparent substrate formed on the light incidence side of the flattening film;
a hollow portion formed in a region overlapping the on-chip lens when seen in a plan view with respect to at least one of between the flattening film and the transparent substrate and inside the transparent substrate; and
a through-hole making the hollow portion communicate with the outside.

2. The package according to claim 1, further comprising a sealing member closing the through-hole.

3. The package according to claim 2, wherein the sealing member is formed of a material to which a black pigment is added.

4. The package according to claim 1, wherein the hollow portion is formed between the flattening film and the transparent substrate,
the transparent substrate is laminated on the light incidence side of the flattening film via an adhesive layer positioned on an outer circumference of the hollow portion, and
the adhesive layer includes a spacer.

5. The package according to claim 1, wherein the hollow portion is formed between the flattening film and the transparent substrate, and
a columnar or wall-like support portion formed of a light transmissive material and extending in a thickness direction of the transparent substrate is provided in the hollow portion.

6. The package according to claim 1, wherein a low-refraction film formed of a material having a refractive index lower than that of the flattening film is formed on at least a surface of the flattening film out of a surface of the flattening film on the transparent substrate side and a surface of the transparent substrate in which the hollow portion is formed.

7. The package according to claim 1, wherein the through-hole is formed in the transparent substrate.

8. The package according to claim 1, wherein the through-hole extends in a direction intersecting a thickness direction of the transparent substrate.

9. A package manufacturing method, the method comprising:
forming a flattening film covering an on-chip lens formed on a light incidence side of a substrate having an element formed thereon;
laminating a transparent substrate on the light incidence side of the flattening film via a sacrificial layer and an adhesive layer disposed on an outer circumference of the sacrificial layer;
forming a through-hole making the sacrificial layer communicate with the outside; and
etching the sacrificial layer through the through-hole to form a hollow portion after the transparent substrate is laminated.

10. A package manufacturing method, the method comprising:
forming a flattening film covering an on-chip lens formed on a light incidence side of a substrate having an element formed thereon;
forming a concave portion in a surface of the transparent substrate which is capable of facing the on-chip lens;
forming a sacrificial layer in the concave portion;
laminating the transparent substrate on the light incidence side of the flattening film with the sacrificial layer facing the flattening film;
forming a through-hole making the sacrificial layer communicate with the outside; and
etching the sacrificial layer through the through-hole to form a hollow portion after the transparent substrate is laminated.

11. A package manufacturing method, the method comprising:
forming a flattening film covering an on-chip lens formed on a light incidence side of a substrate having an element formed thereon;
laminating a transparent substrate on the light incidence side of the flattening film;
forming the laminated transparent substrate by laminating a plurality of glass substrates;
sealing a sacrificial layer between any glass substrates constituting the plurality of glass substrates;
forming a through-hole making the sacrificial layer communicate with the outside; and
etching the sacrificial layer through the through-hole to form a hollow portion after the transparent substrate is laminated.

12. The package manufacturing method according to claim 9, wherein the through-hole is closed with a sealing member after the hollow portion is formed.

13. The package manufacturing method according to claim 9, wherein the through-hole is formed after the transparent substrate is laminated on the light incidence side of the flattening film.

14. The package manufacturing method according to claim 9, wherein the sacrificial layer is etched after forming a rewiring on a rear surface side of the substrate.

15. The package manufacturing method according to claim 9, wherein a spacer protruding toward the adhesive layer is formed on a surface of the transparent substrate which abuts on the adhesive layer.

16. The package manufacturing method according to claim 9, wherein a low-refraction film formed of a material having a refractive index lower than that of the flattening film is formed on at least one of a surface of the flattening film and a surface of the transparent substrate which abuts on the sacrificial layer.

17. The package manufacturing method according to claim 9, wherein a support portion protruding into the sacrificial layer from a surface of the transparent substrate which abuts on the sacrificial layer is provided, and the support portion is formed on the surface of the transparent substrate before the sacrificial layer is formed.

18. The package manufacturing method according to claim 9, wherein a support portion protruding into the sacrificial layer from a surface of the transparent substrate which abuts on the sacrificial layer is provided, and the support portion contains a material of the sacrificial layer.

19. The package manufacturing method according to claim 9, wherein the through-hole is formed to extend in a direction intersecting a thickness direction of the transparent substrate.

20. The package manufacturing method according to claim 9, wherein the through-hole is formed on an outer circumferential side of a region overlapping the entire on-chip lens when seen in a plan view.
